(19) United States
(12) Patent Application Publication
(10) Pub. No.: US 2023/0033081 A1
(43) Pub. Date: Feb. 2, 2023

(54) COMPOUND AND APPLICATION THEREOF

(71) Applicant: GUANGDONG AGLAIA OPTOELECTRONIC MATERIALS CO., LTD, Foshan, Guangdong (CN)

(72) Inventors: Liangliang YAN, Foshan (CN); Lei DAI, Foshan (CN); Lifei CAI, Foshan (CN)

(73) Assignee: GUANGDONG AGLAIA OPTOELECTRONIC MATERIALS CO., LTD, Foshan, Guangdong (CN)

(21) Appl. No.: 17/776,926

(22) PCT Filed: Sep. 19, 2020
(86) PCT No.: PCT/CN2020/116335

§ 371 Date: May 13, 2022

(30) Foreign Application Priority Data
Nov. 25, 2019 (CN) 201911161573.1

(51) Int. Cl. C07F 15/00; H01L 51/00

(52) U.S. Cl. CPC C07F 15/0033; H01L 51/0085

(57) ABSTRACT

The present invention relates to a compound and an application thereof. The compound has a structure as shown in Formula I. The compound provided by the present invention has the advantages of being low in sublimation temperature, good in photo-stability and electrical stability, high in luminous efficiency, long in service life, and high in color saturation and the like, and can be applied to an organic light emitting device, particularly as a red luminous phosphorescent material, and has the possibility of being applied to the AMOI ED industry.

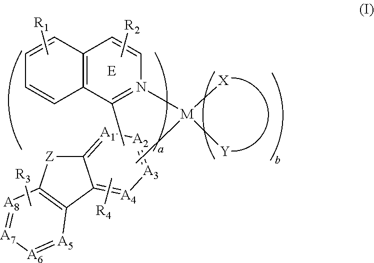

### TECHNICAL FIELD

The present invention relates to the technical field of organic electroluminescence, and especially relates to an organic luminescent material suitable for organic light-emitting devices, in particular to a compound and an application thereof in an organic light-emitting device.

### BACKGROUND

At present, the organic light-emitting device (OLED), as a new generation of display technology, has achieved more and more attention in the aspect of display and lighting technology and has wide application prospect. But, compared with the demands for market application, the luminous efficiency, driving voltage, service life and other properties of the OLED device still need to be strengthened and improved.

Generally, the basic structure of OLED device is to sandwich various functions of organic functional material films between metal electrodes, just like a sandwiched structure. Driven by electric current, holes and electrons are injected from cathode and anode, and then compounded on a light-emitting layer after moving a certain distance, then released in a form of light or heat, thus producing the light emission of OLED. However, organic functional materials are core components of the organic light-emitting device. The material heat stability, photochemical stability, electrochemical stability, quantum yield, film-forming stability, crystallinity, color saturation and the like are the major indicators to influence the performances of the device.

Generally, organic functional materials include fluorescent materials and phosphorescent materials. Fluorescent materials are usually small organic materials, and only utilize 25% singlet state for emitting light generally and thus, have lower luminous efficiency. Due to spin-orbit coupling caused by heavy atoms effect, phosphorescent materials can further utilize 75% triplet exciton energy besides the 25% singlet state and thus, have improved luminous efficiency. But compared with fluorescent materials, phosphorescent materials are put into use relatively late; meanwhile, heat stability, service life, color saturation and the like of the materials are to be improved, which is a challenging topic. Currently, people have developed various kinds of compounds as phosphorescent materials. For example, the invention patent CN107973823 has disclosed a category of quinolines iridium compounds; but color saturation and device performances of the compounds, in particular to luminous efficiency and service life of the device are to be improved; the invention patent CN106459114 has disclosed a category of iridium compounds coordinated by a R-dione dentate, but such kind of compounds have high sublimation temperature, poor color saturation, and particularly, the device performance is unsatisfactory and to be further improved.

### SUMMARY

One of the objectives of the present invention provides a phosphorescent compound; and such kind of compound has the advantages of high photo-stability and electrical stability, good color saturation, high luminous efficiency, long service life of device, and thus, can be applied to an organic light emitting device. The present invention is particularly used as a red luminous dopant, and can be applied to the AMOI ED industry.

A compound, having a structural formula as shown in Formula I:

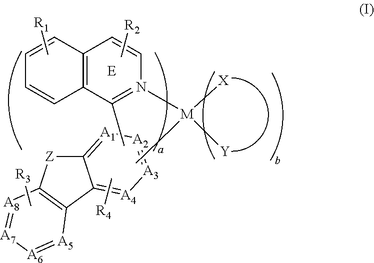

where one of A1-A4 is a C—C bond and linked with a ring E; one is a C-M bond and linked with a metal M, one is CR₄, and the other one is CR₀ or N; one of A5-A8 is CR₃, and the other three independently represent CR₀ or N; the M is a metal having an atomic weight greater than 40;

where R₀-R₄ are independently selected from hydrogen, deuterium, halogen, substituted or unsubstituted C1-C10 alkyl, substituted or unsubstituted C3-C20 cycloalkyl, substituted or unsubstituted C1-C10 heteroalkyl, substituted or unsubstituted C6-C30 aralkyl, substituted or unsubstituted C1-C10 alkoxy, substituted or unsubstituted C6-C30 aryloxy, amino, substituted or unsubstituted C3-C30 silicyl, substituted or unsubstituted C6-C30 aryl, substituted or unsubstituted C1-C8 heteroaryl, cyano, nitrile, isonitrile or phosphino; and where at least one of R₁ and R₂ is substituted or unsubstituted C3-C20 cycloalkyl,

where Z is independently selected from O, S, Se, C(R)₂, Si(R)₂, NR, BR and POR; R is independently selected from substituted or unsubstituted C1-C10 alkyl or alkoxy, substituted or unsubstituted C2-C30 cycloalkyl, substituted or unsubstituted C6-C30 aryl, substituted or unsubstituted C1-C18 heteroaryl; where the substitution refers to a substitution by deuterium, F, Cl, Br, C1-C4 alkyl, C1-C4 alkoxy, C3-C6 cycloalkyl, amido substituted by C1-C4 alkyl, cyano, nitrile, isonitrile or phosphino; where the substitution refers to a single substitution to a maximum number of substitutions;

where X—Y is a monoanionic bidentate ligand, where the sum of a and b is equal to a valence state of the metal M.

Preferably, the X—Y is a type-GO, or CN ligand; the M is one of metals Os, Ir, Pt, Pd, Ru, Rh and Au.

As a preferred compound, having a structure having the following Formula II:

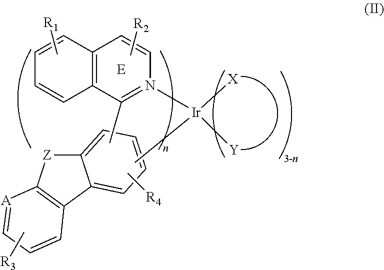

where n is a positive integer of 1-2; A is CR₀ or N; R₀-R₄ are independently selected from hydrogen, deuterium, substituted or unsubstituted C1-C8 alkyl, substituted or unsubstituted C1-C8 heteroalkyl, substituted or unsubstituted C3-C20 cycloalkyl, substituted or unsubstituted C1-C8 aralkyl, substituted or unsubstituted C3-C30 silicyl, C1-C4 alkyl substituted or unsubstituted C1-C8 aryl or heteroaryl; and where at least one of R₁ and R₂ is substituted or unsubstituted C3-C20 cycloalkyl; where the substitution refers to a substitution by deuterium, F, Cl, Br, C1-C4 alkyl, C1-C4 alkoxy, C3-C6 cycloalkyl, amido substituted by C1-C4 alkyl, cyano, nitrile, isonitrile or phosphino; the substitution refers to a single substitution to a maximum number of substitutions.

As a preferred compound, where R₁ is substituted or unsubstituted C3-C20 cycloalkyl.

As a preferred compound, where R₂ is substituted or unsubstituted C3-C20 cycloalkyl.

As a preferred compound, where R₁ and R₂ are substituted or unsubstituted C3-C20 cycloalkyl.

As a preferred compound, where the substitution is D, particularly preferably, C1-C4 alkyl substituted by D partially or completely.

As a preferred compound, where the substitution is F, particularly preferably, C1-C4 alkyl substituted by F partially or completely.

As a preferred compound, where the substitution is C3-C6 cycloalkyl.

As a preferred compound, where the Z is O, S, NR, C(R)₂; and the R is independently selected from substituted or unsubstituted C1-C8 alkyl.

As a preferred compound, where the R₄ is not H, particularly preferably, the R4 substituent is positioned adjacent to or opposite to a metal-C bond (C-M bond).

As a preferred compound, X—Y is different from a left ligand.

As a preferred compound, X—Y A is a 1,3-dione compound.

As a preferred compound, being one of the following compounds:

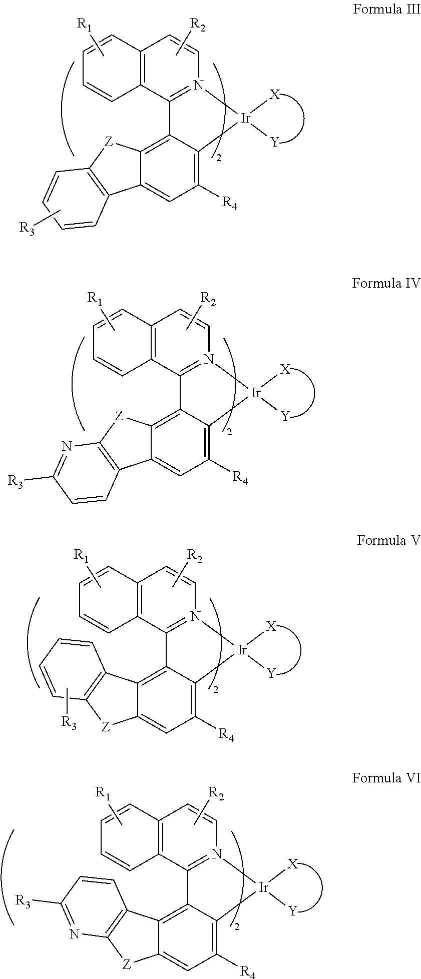

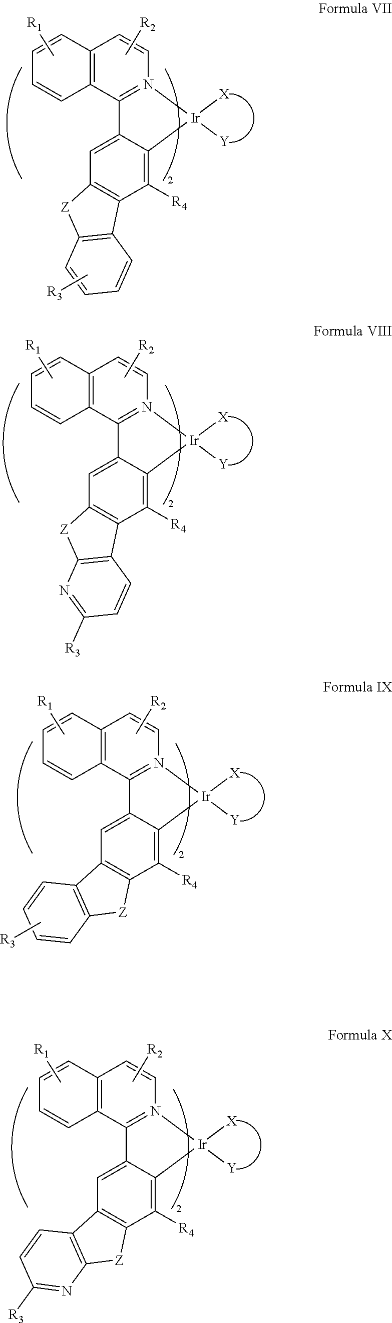

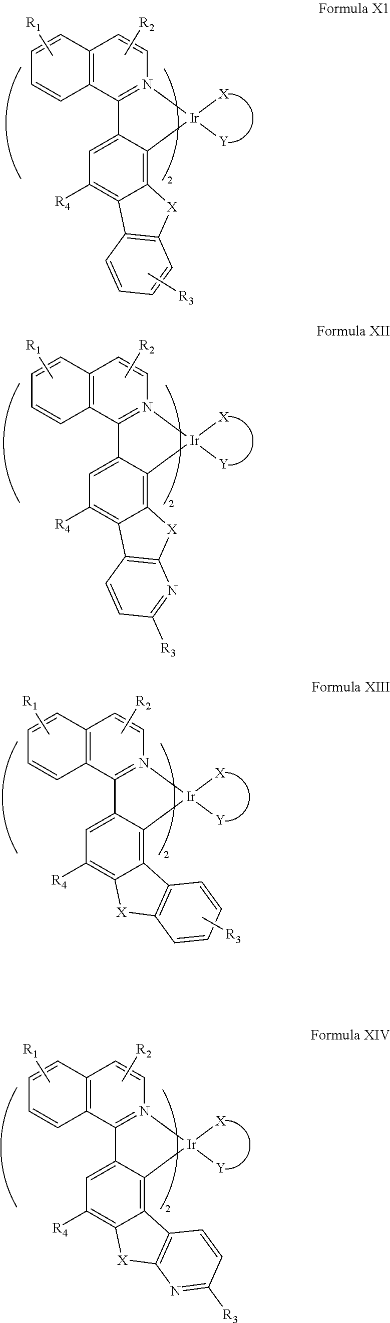

Preferably, Z is O; R₁_R₄ are independently selected from hydrogen, deuterium, substituted or unsubstituted C1-C4 alkyl, substituted or unsubstituted C3-C20 cycloalkyl, substituted or unsubstituted C1-C8 aralkyl, C1-C4 alkyl substituted or unsubstituted C1-C8 aryl or heteroaryl; and where at least one of R₁ and R₂ is substituted or unsubstituted C3-C20 cycloalkyl; where the substitution refers to a substitution by deuterium, F, Cl, Br, C1-C4 alkyl, C1-C4 alkoxy, C3-C6 cycloalkyl, amido substituted by C1-C4 alkyl, cyano, nitrile, isonitrile or phosphino; the substitution refers to a single substitution to a maximum number of substitutions.

R₃_R₄ are independently selected from hydrogen, deuterium, substituted or unsubstituted C1-C4 alkyl, substituted or unsubstituted C3-C20 cycloalkyl, phenyl substituted C1-C4 alkyl, C1-C4 alkyl substituted phenyl; and where the substitution refers to a substitution by deuterium, F, Cl, Br, C1-C4 alkyl, C1-C4 alkoxy, C3-C6 cycloalkyl, amido substituted by C1-C4 alkyl, cyano, nitrile, isonitrile or phosphino.

As a preferred compound, being one of the following compounds:

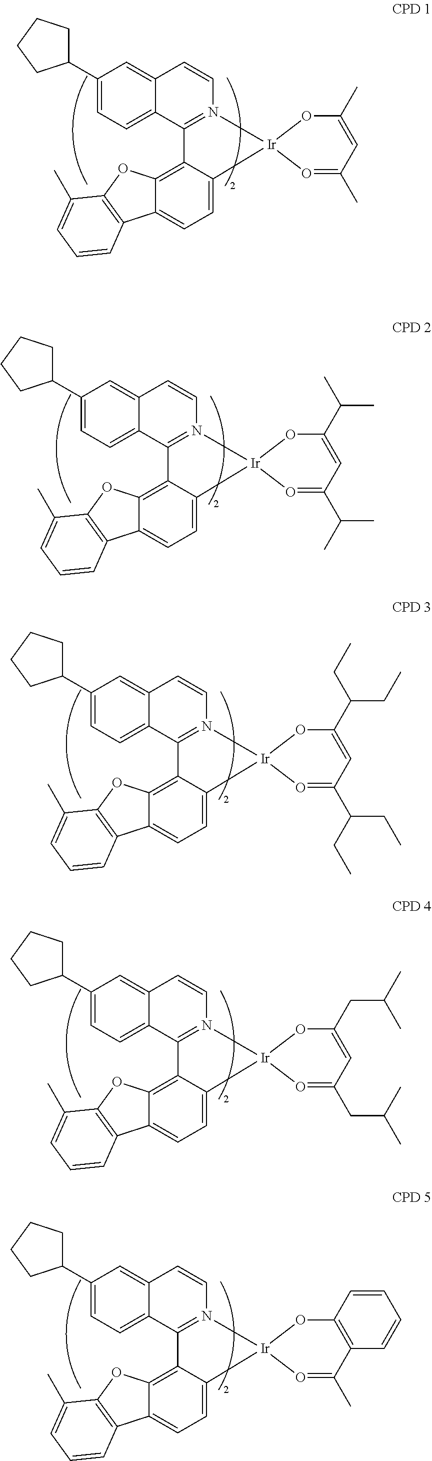

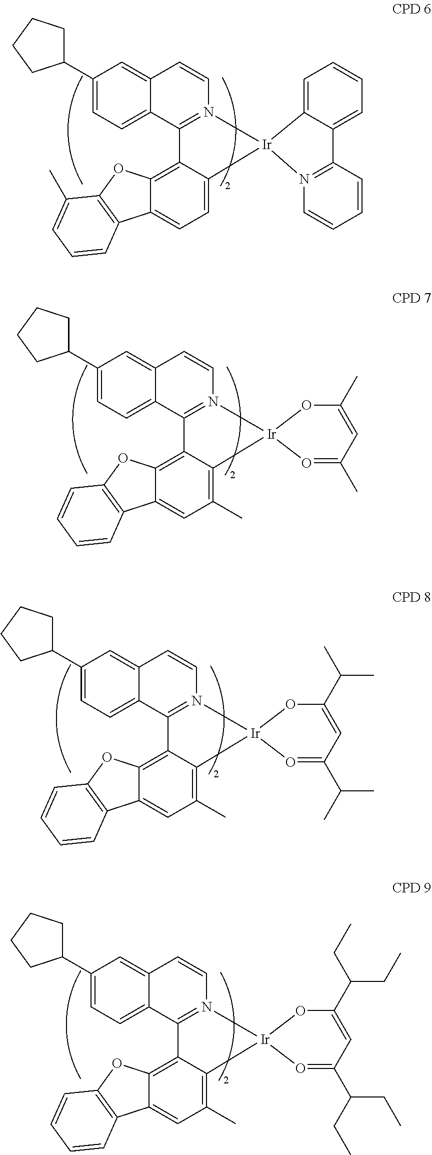

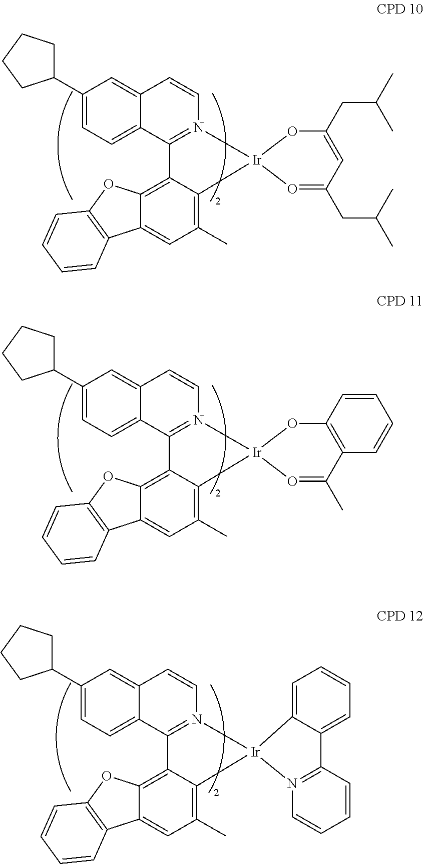

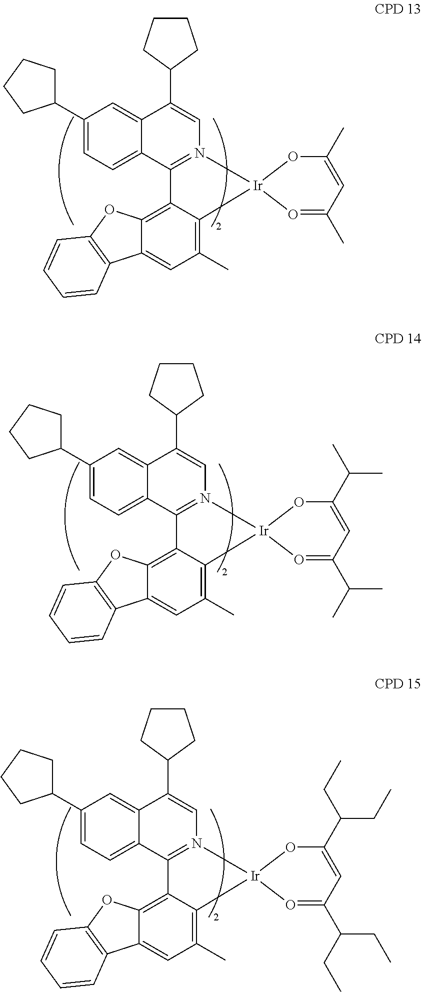

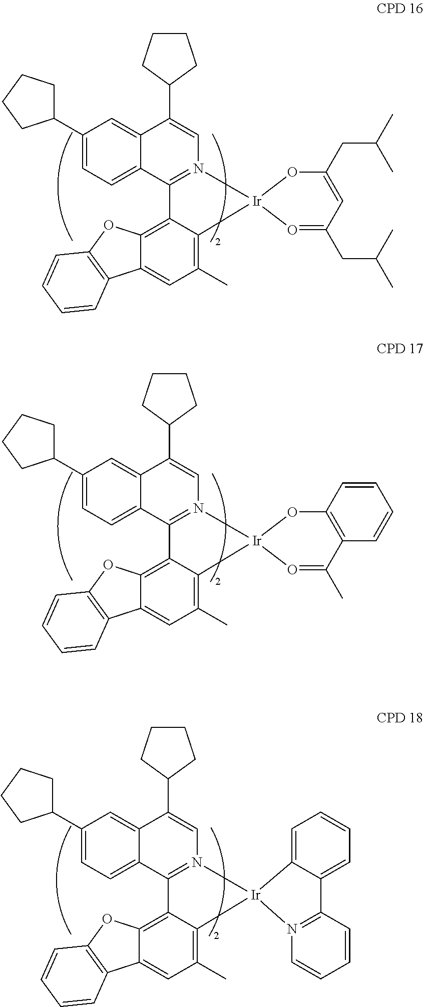

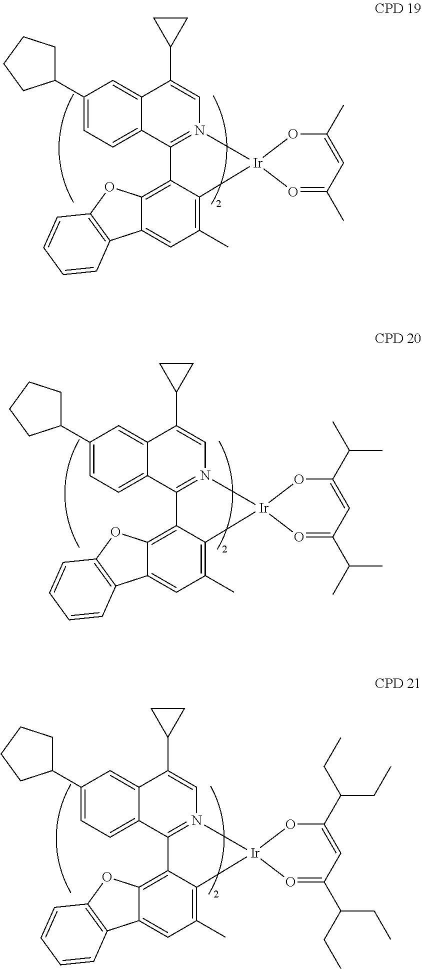

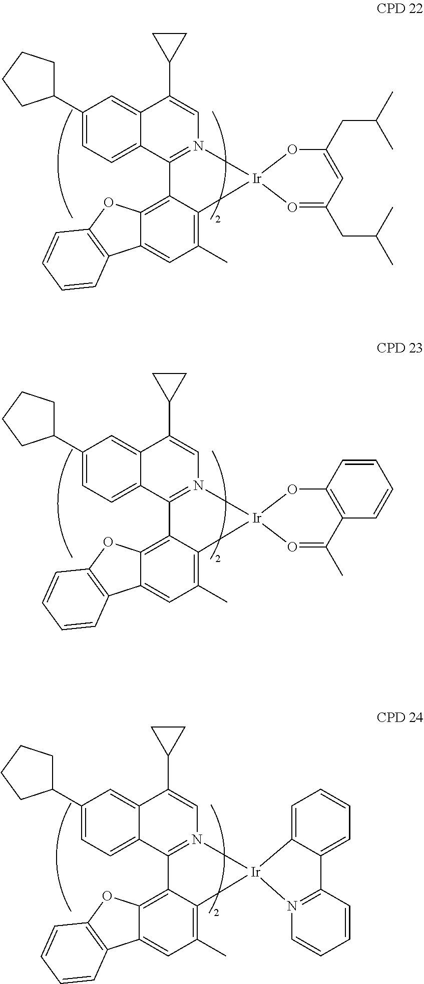

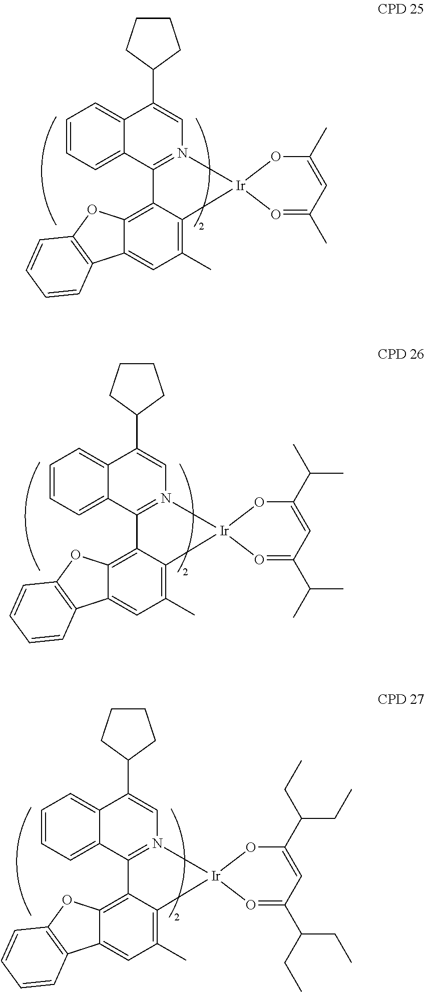

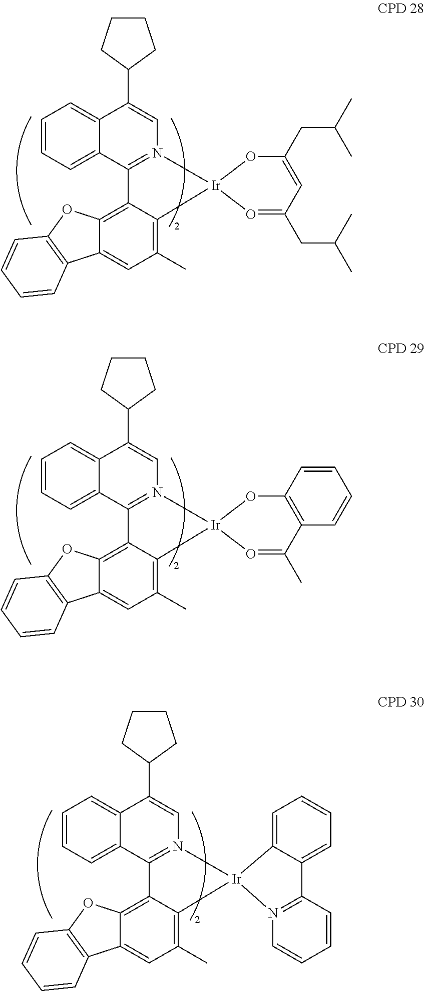

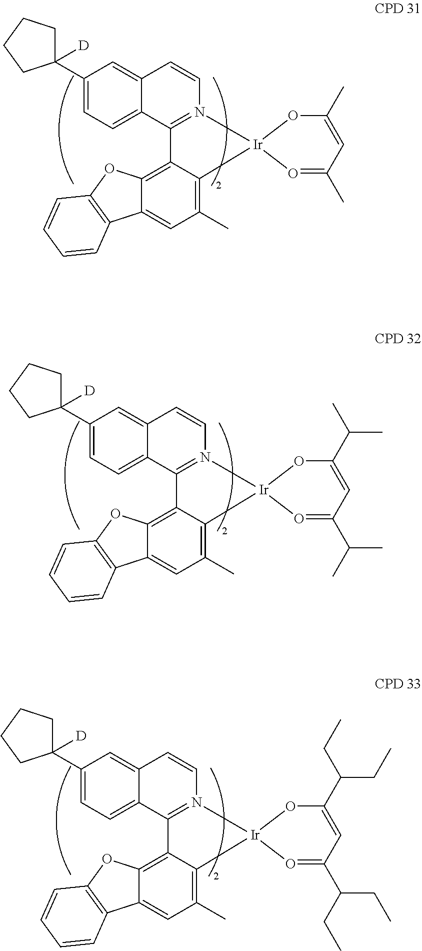

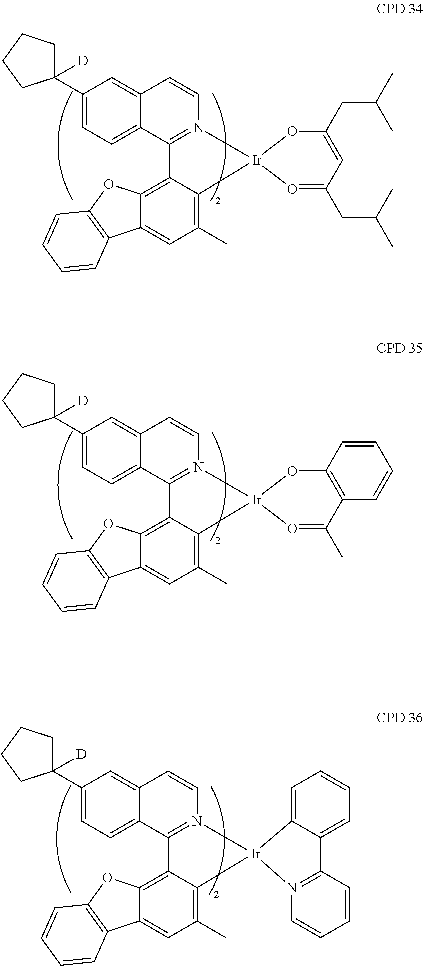

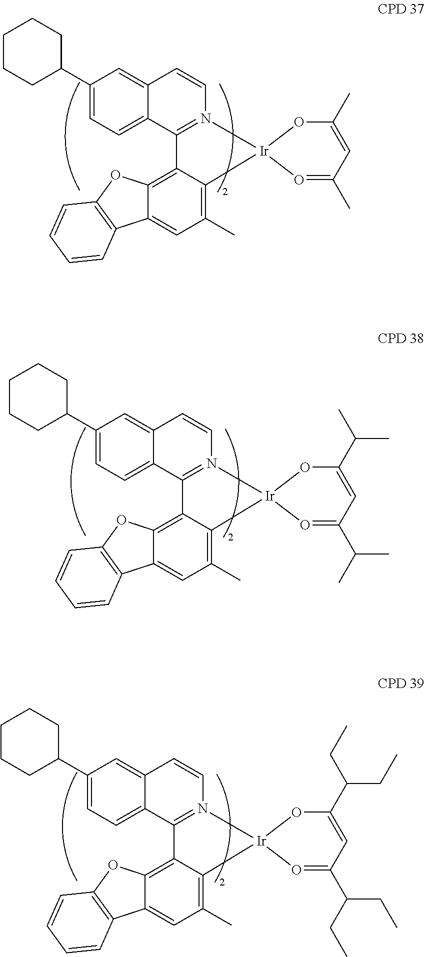

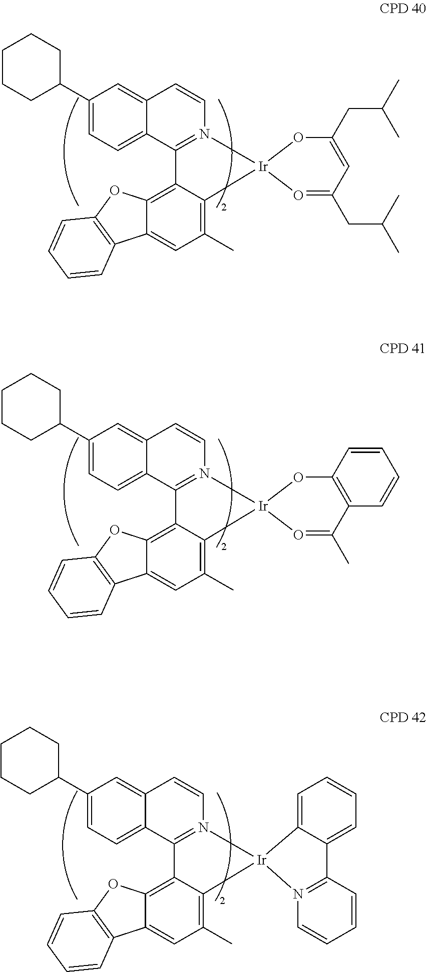

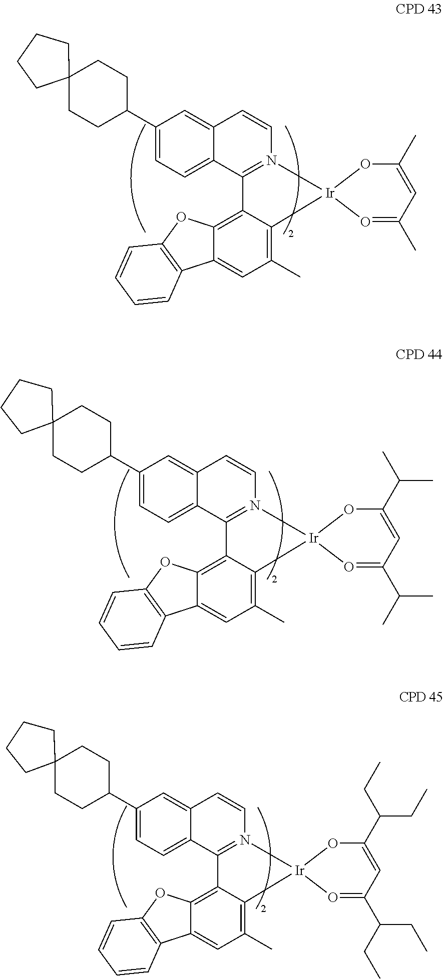

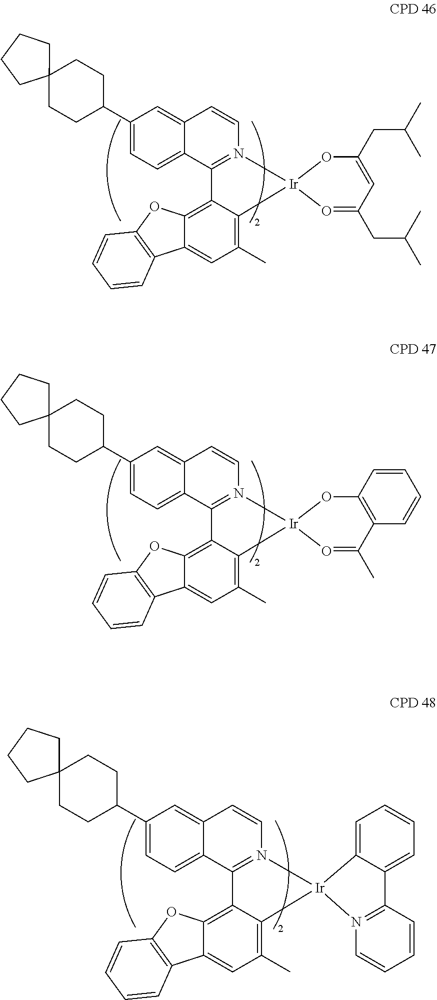

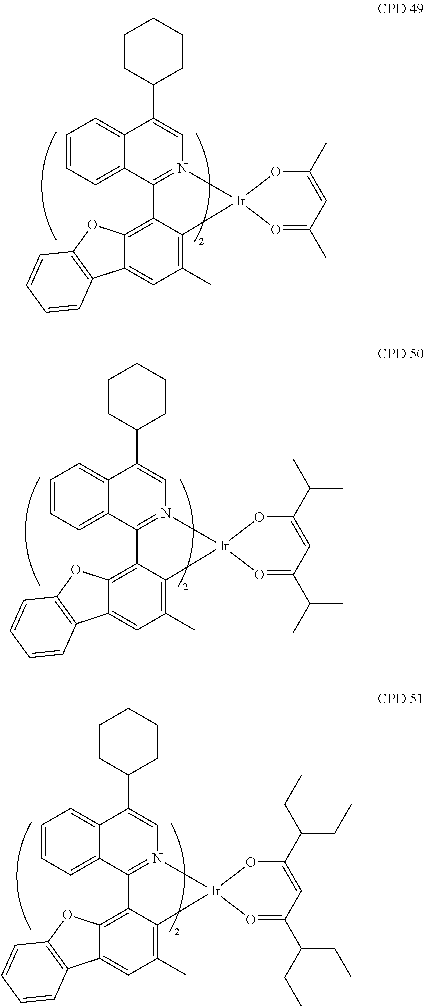

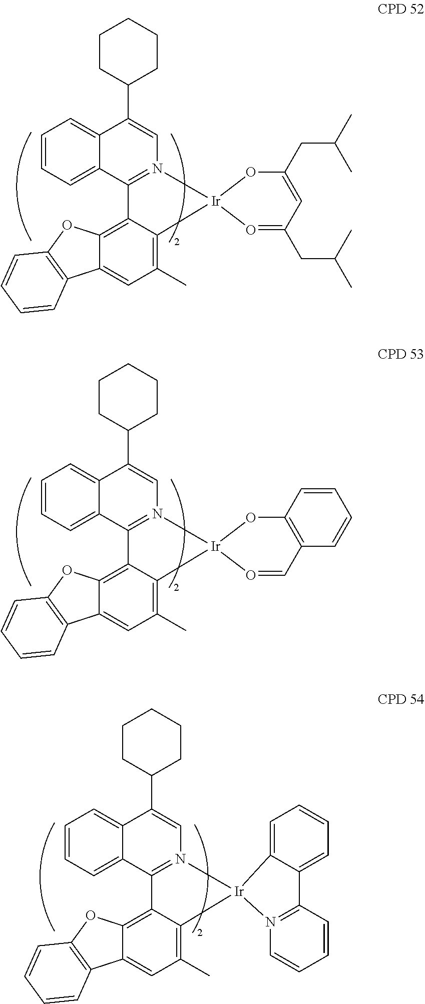

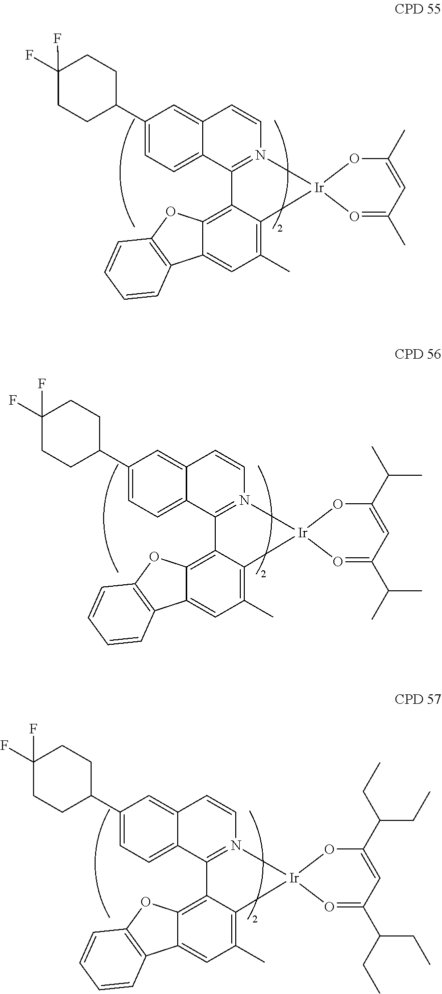

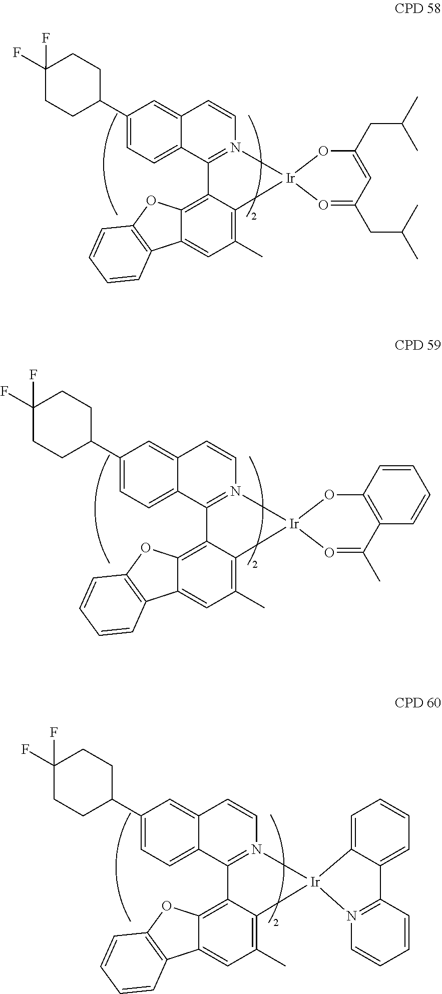

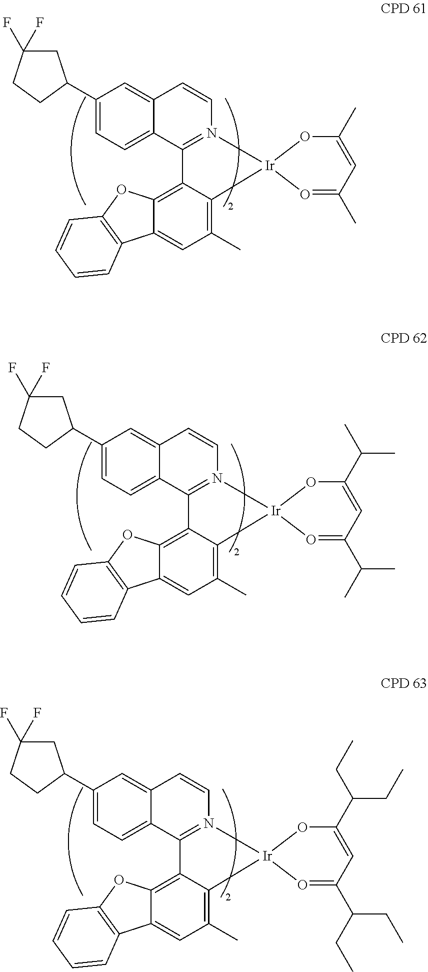

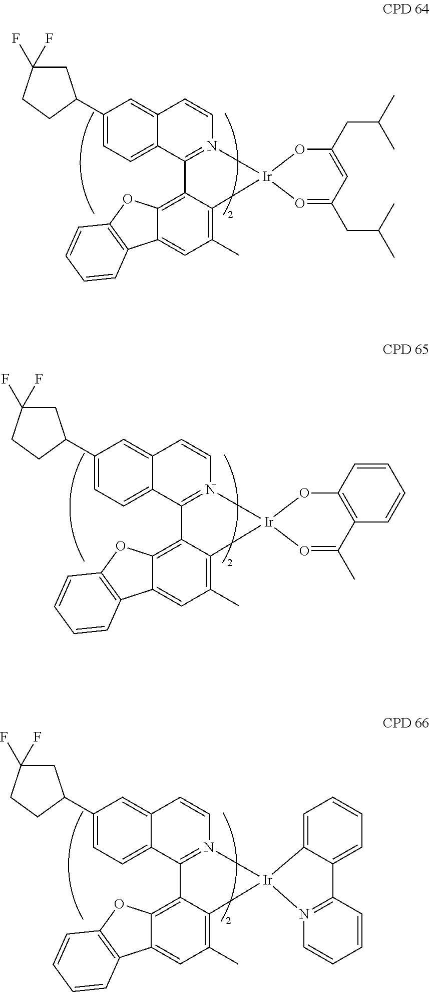

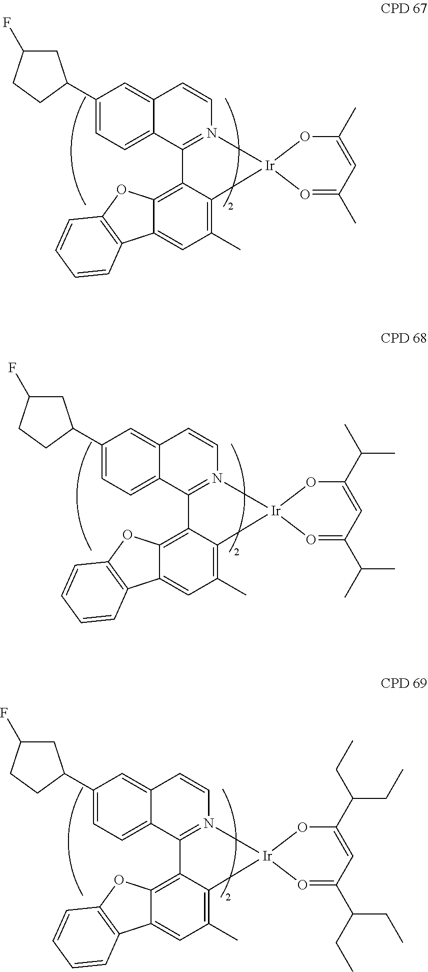

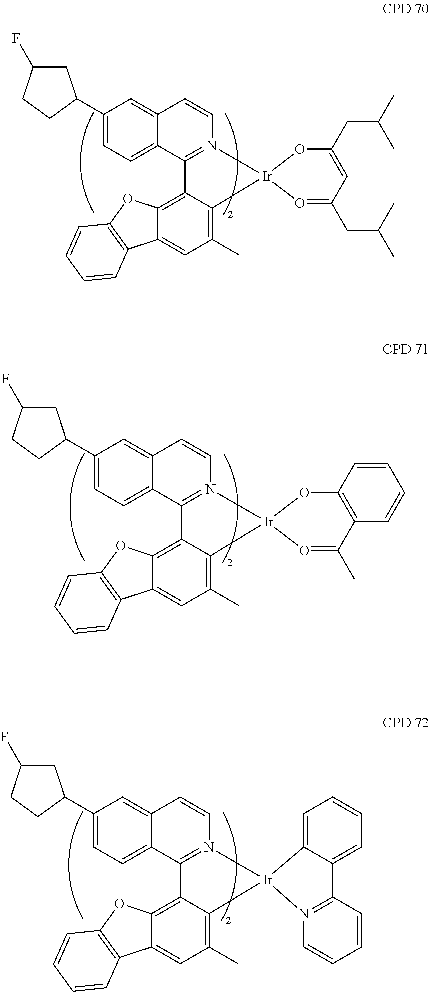

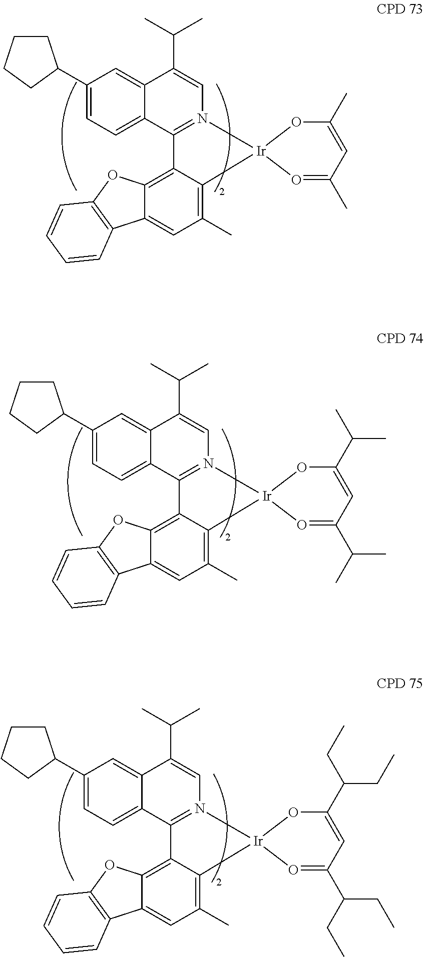

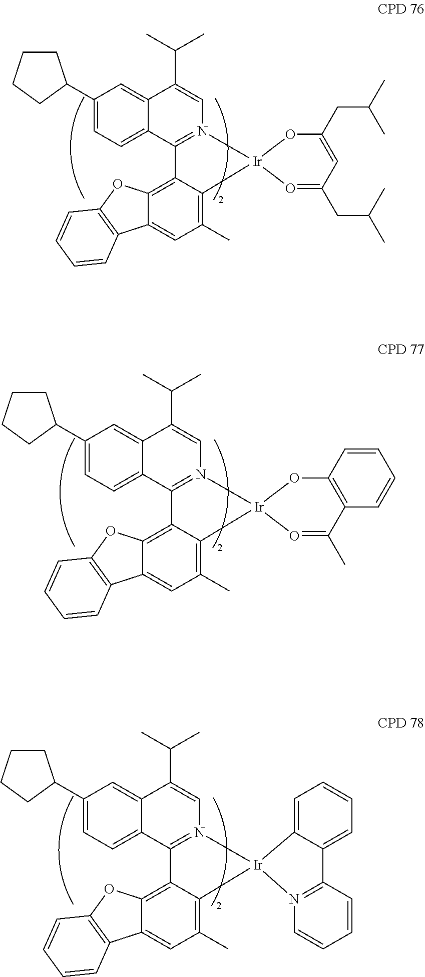

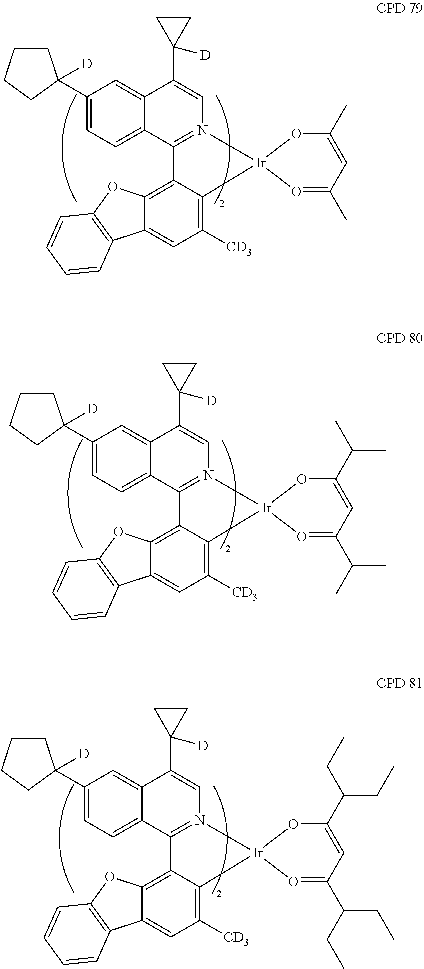

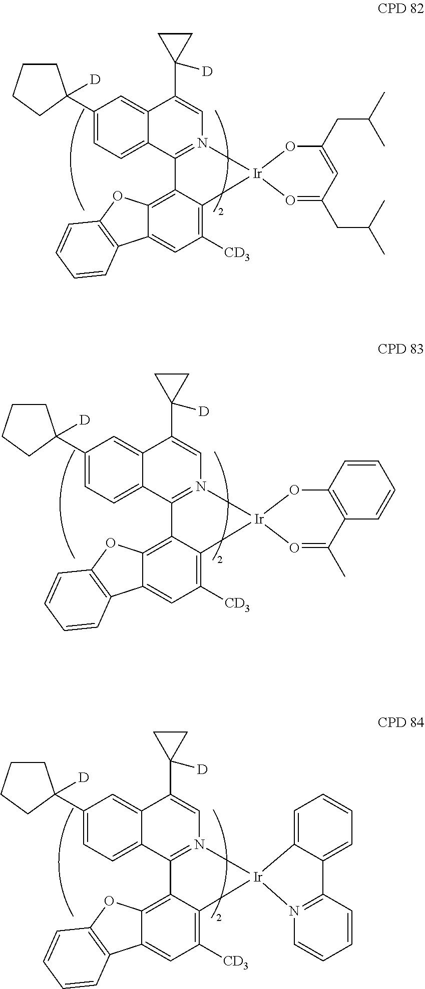

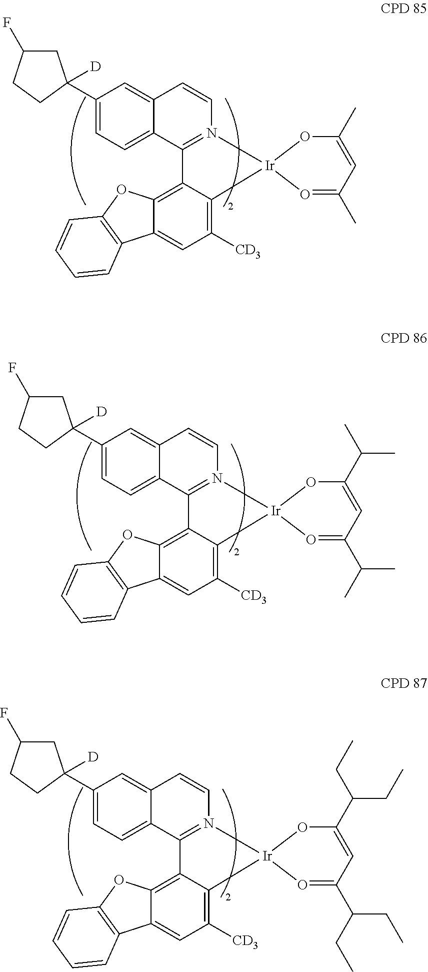

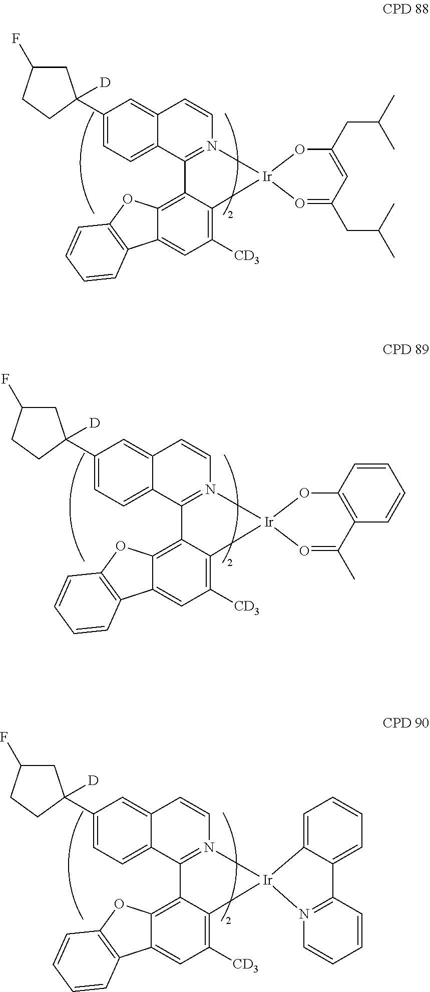

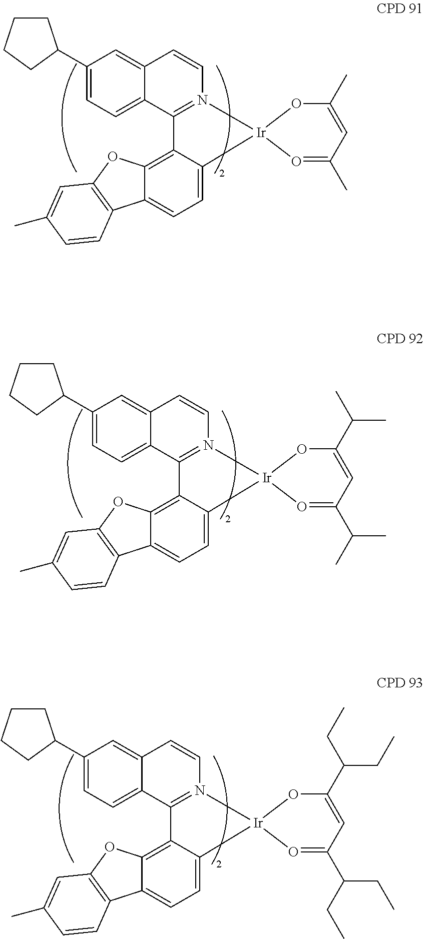

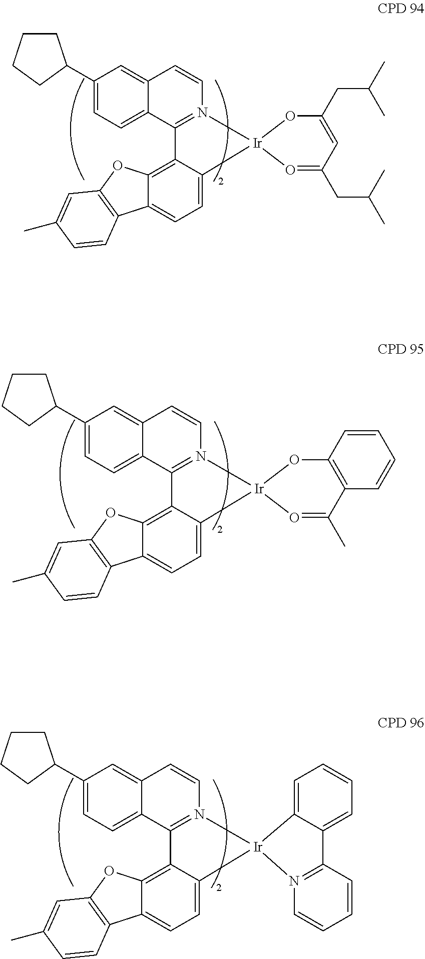

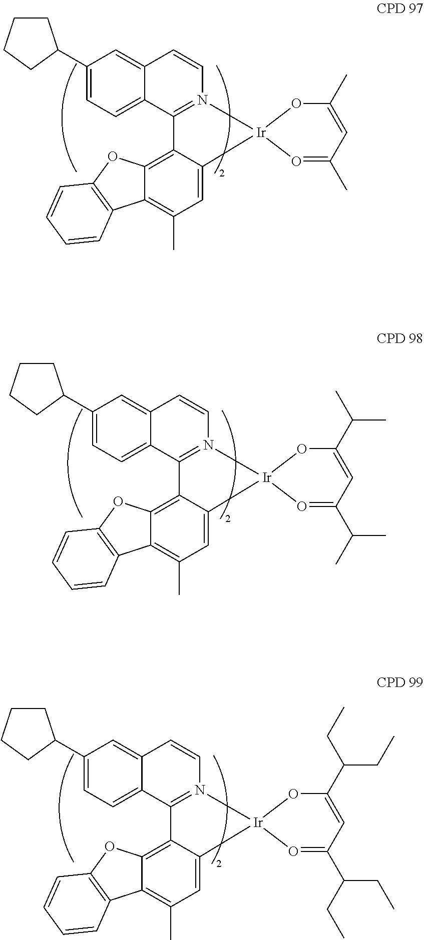

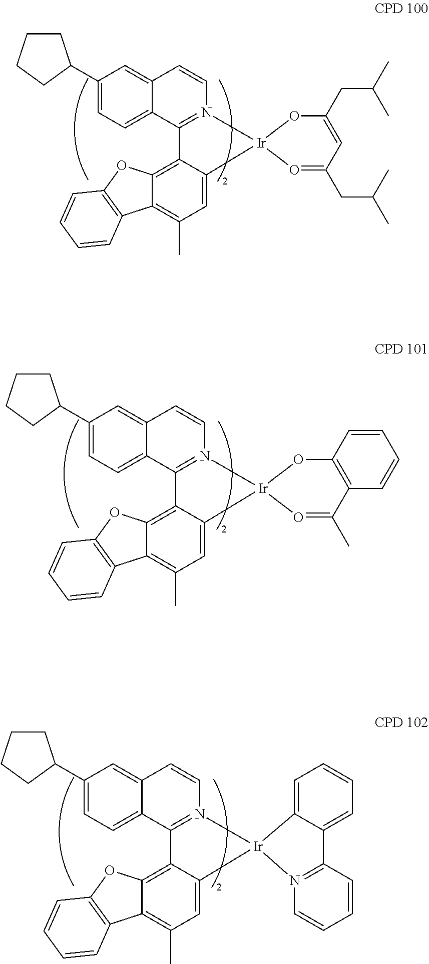

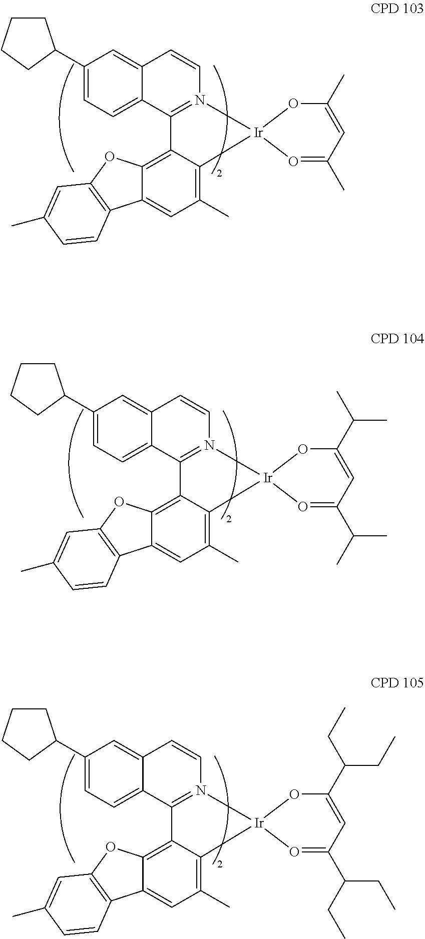

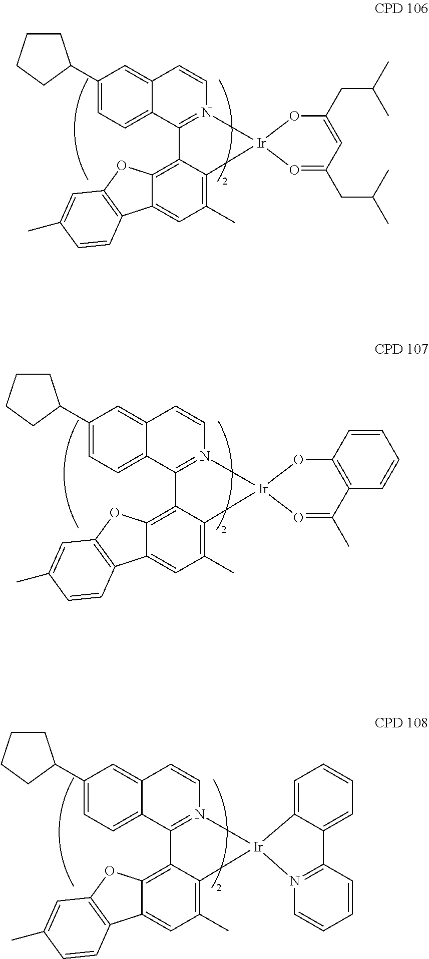

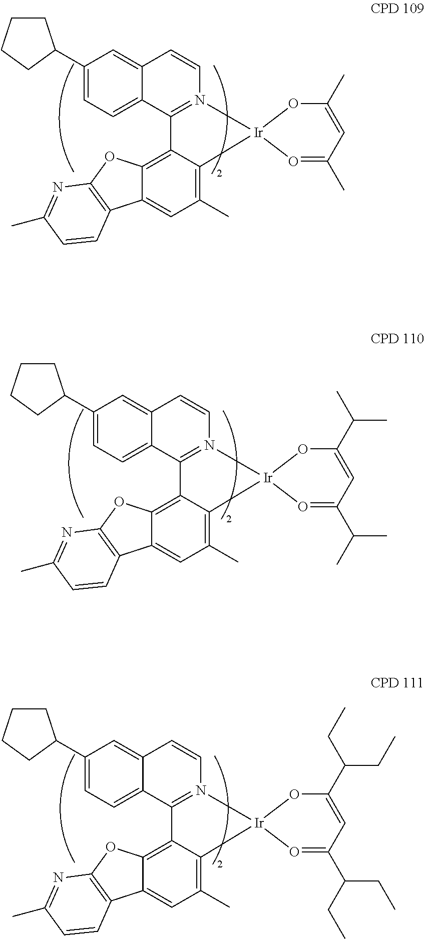

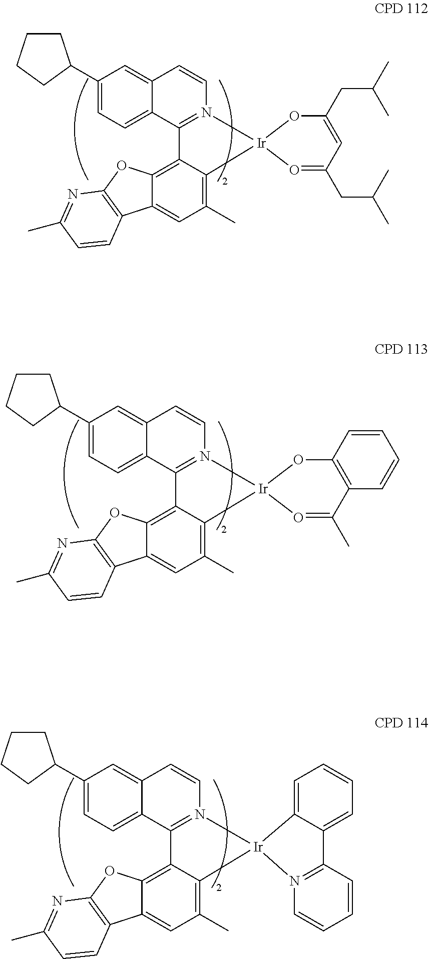

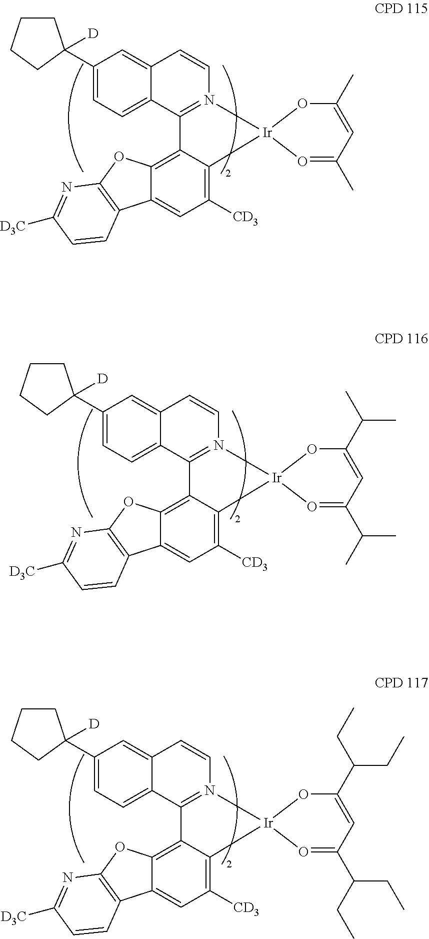

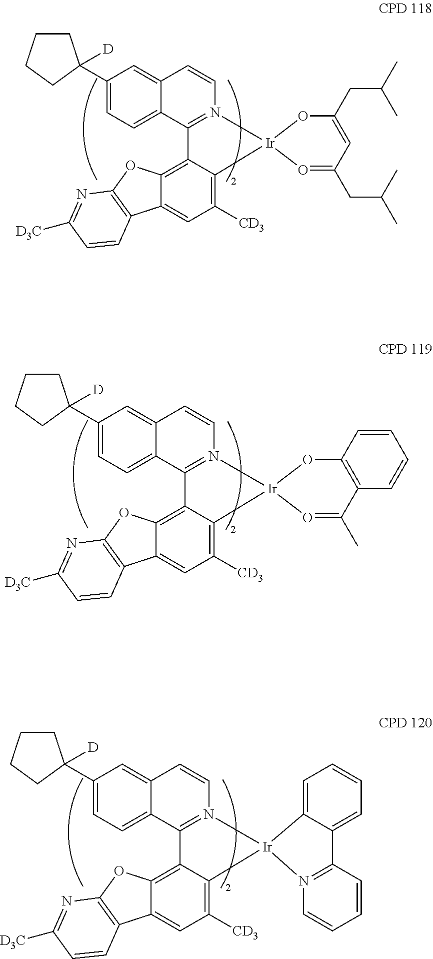

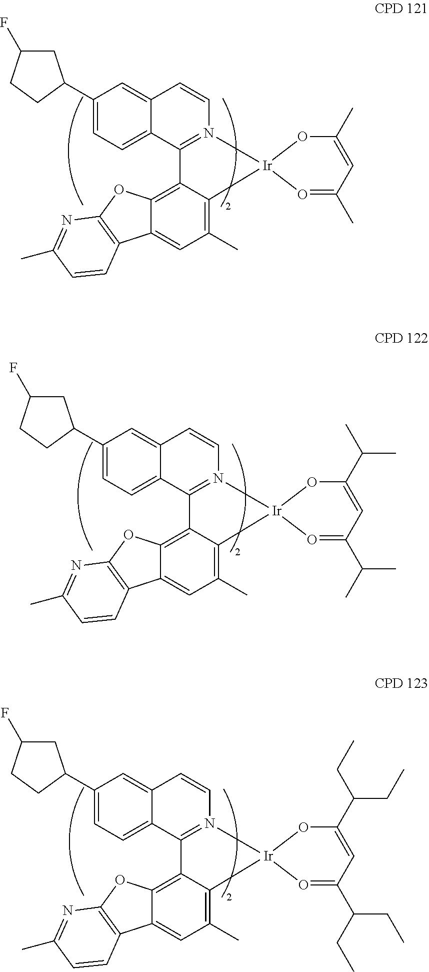

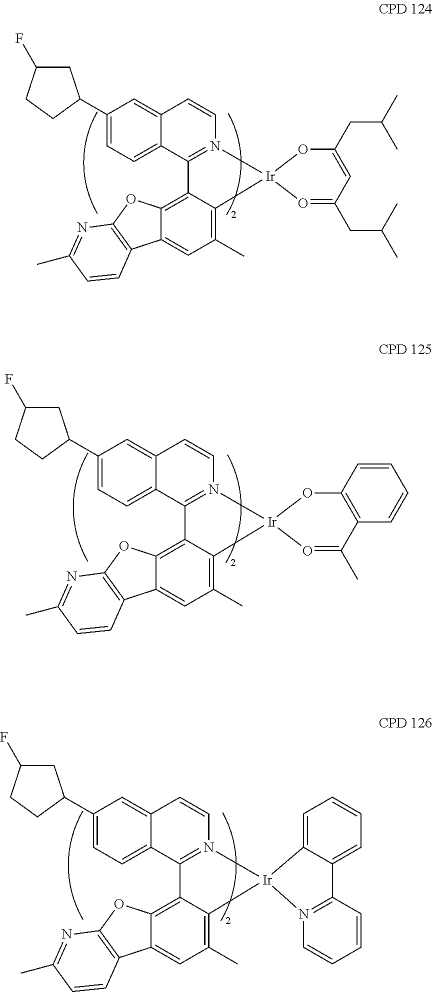

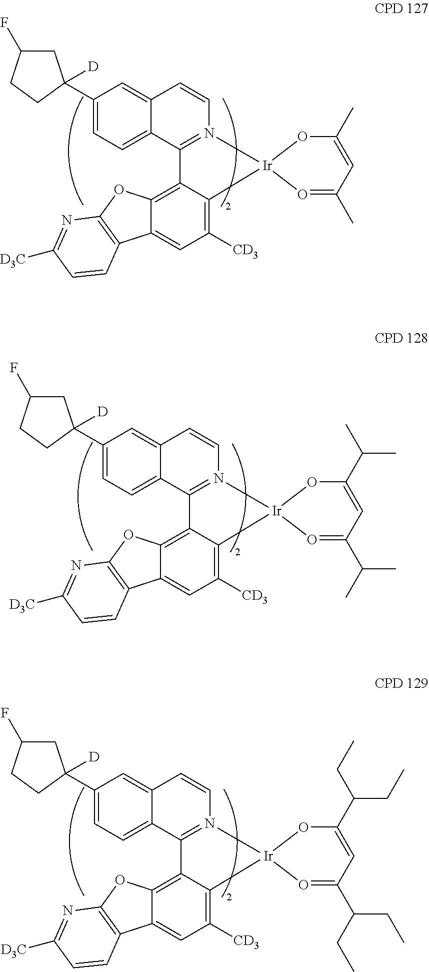

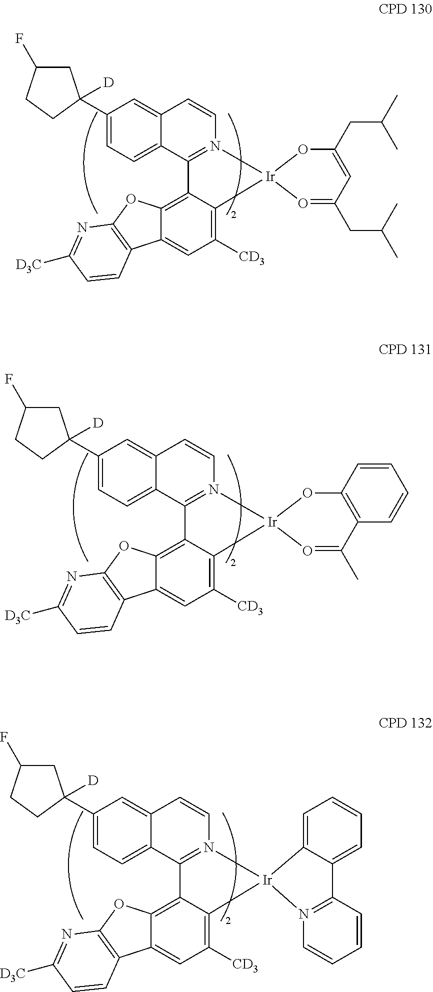

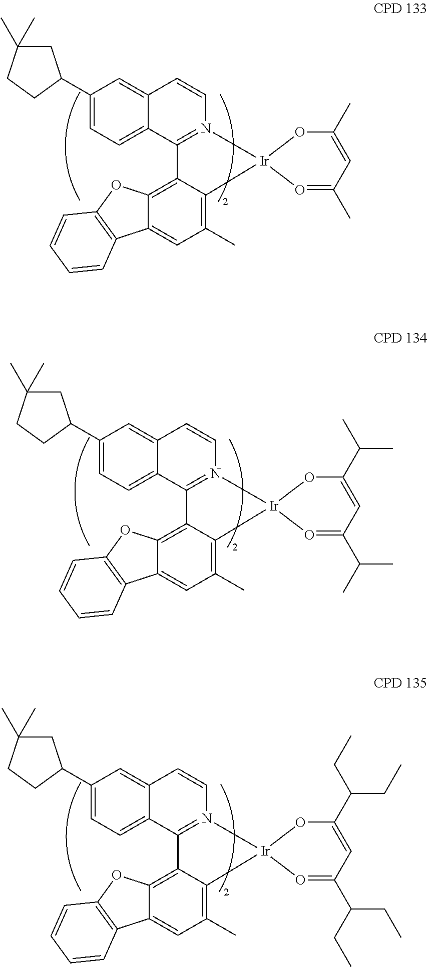

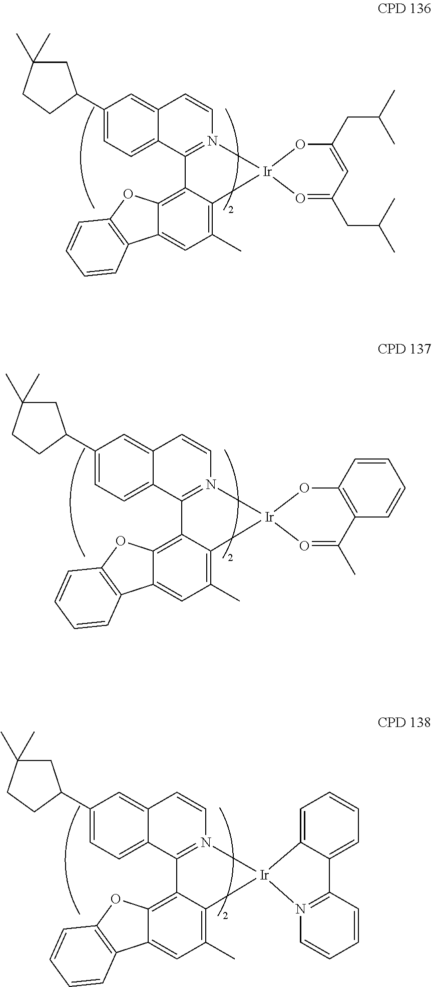

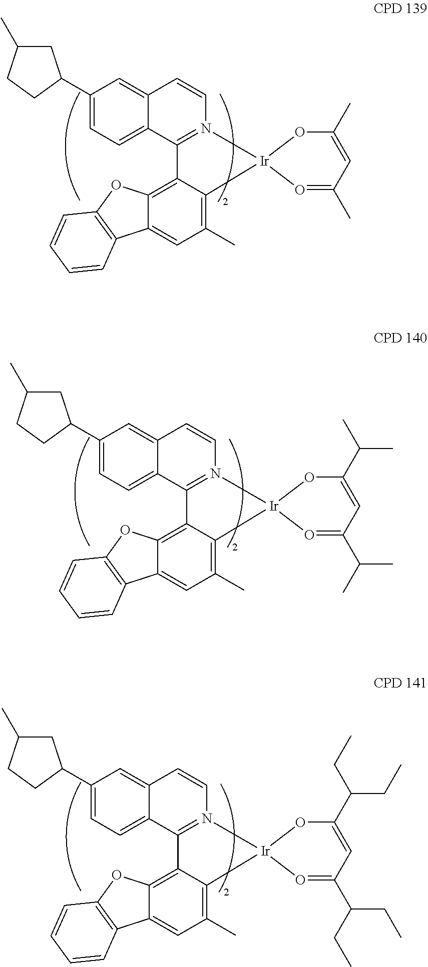

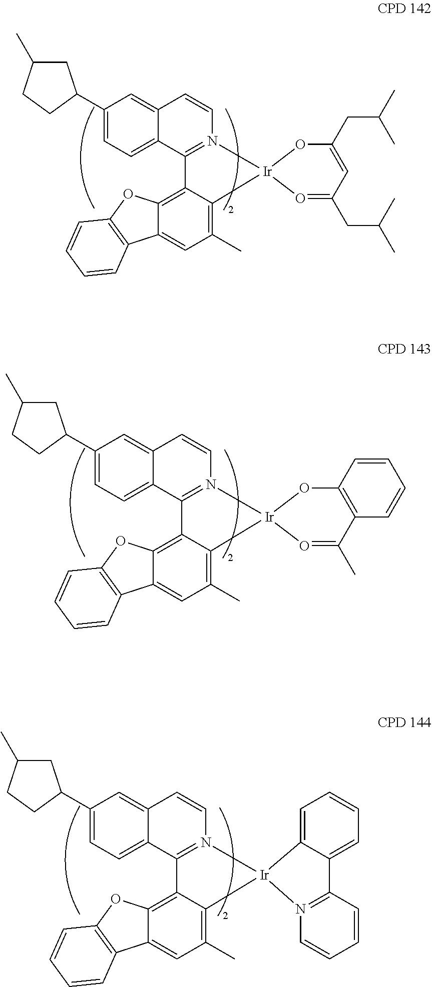

One of the objectives of the present invention is further to provide an OLED phosphorescent material containing the above compound.

One of the objectives of the present invention is to provide an OLED device containing the above compound.

The material of the present invention has the advantages of lower sublimation temperature, high photo-stability and electrical stability, good color saturation, high luminous efficiency, long service life of device. Moreover, the material of the present invention can convert a triplet state into light when used as a phosphorescent material. Therefore, the material of the present invention can enhance the luminous efficiency of OLED, thus reducing energy consumption.

### DETAILED DESCRIPTION OF EMBODIMENTS

The following examples are merely to facilitate the understanding of the present invention, but are not construed as specifically limiting the scope of the present invention.

Raw materials, solvents and the like related in the compound synthesis of the present invention are purchased from Alfa, Acros and other suppliers known well by a person skilled in the art.

### Example 1 (Synthesis of CPD 7/9/12)

Synthesis of the Shared Intermediate Compound B:

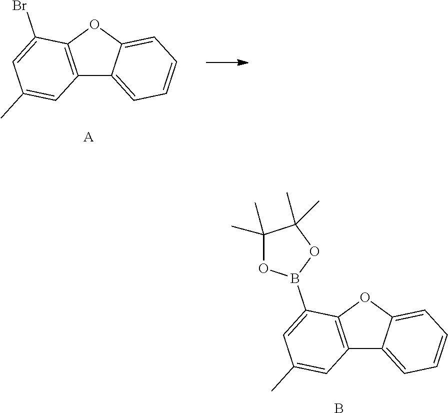

the compound A (98 g, 375.3 mmol, 1.0 eq), bis(pinacolato)diboron (114.3 g, 450.3 mmol, 1.2 eq), Pd(dppf)Cl2 (5.49 g, 7.51 mmol, 0.02 eq), KOAc (73.67 g, 750.6 mmol, 2.0 eq), and dioxane (1 L) were successively added to a 3 L three-necked flask, vacuumized and replaced with nitrogen for 3 times, then heated up to 100° C. around in an oil bath and stirred for 16 h; sampling was performed, and completion of the reaction of the raw material A was monitored by TLC. The system was cooled to room temperature, and transferred to a 1 L single-necked flask in batches for rotary evaporation to remove a large number of dioxane, and added with toluene (600 ml), and heated to be dissolved, then added with deionized water for washing for 3 times (200 ml/times), subjected to liquid separation; the organic phase was sieved by a silica gel filter (200-300 meshes, 50 g) and eluted with 100 ml toluene. The organic phase was concentrated to be 150 ml around, then added with 300 ml n-hexane, and stirred at room temperature for crystallization for 4 h. The crystallized organic phase was filtered, and filter cake was eluted with 80 ml n-hexane; the obtained product was dried to obtain 90.8 g of an off-white solid compound B with a yield of 78.5%. Mass spectrometry: 309.2 (M+H), 1H NMR (400 MHz, CDCl3) δ 7.93 (d, J=7.7 Hz, 1H), 7.86 (s, 1H), 7.75 (s, 1H), 7.57 (d, J=8.2 Hz, 1H), 7.46 (t, J=7.7 Hz, 1H), 7.36 (t, J=7.4 Hz, 1H), 2.31 (s, 3H), 1.14 (s, 12H).

Synthesis of a Shared Ligand Compound 1:

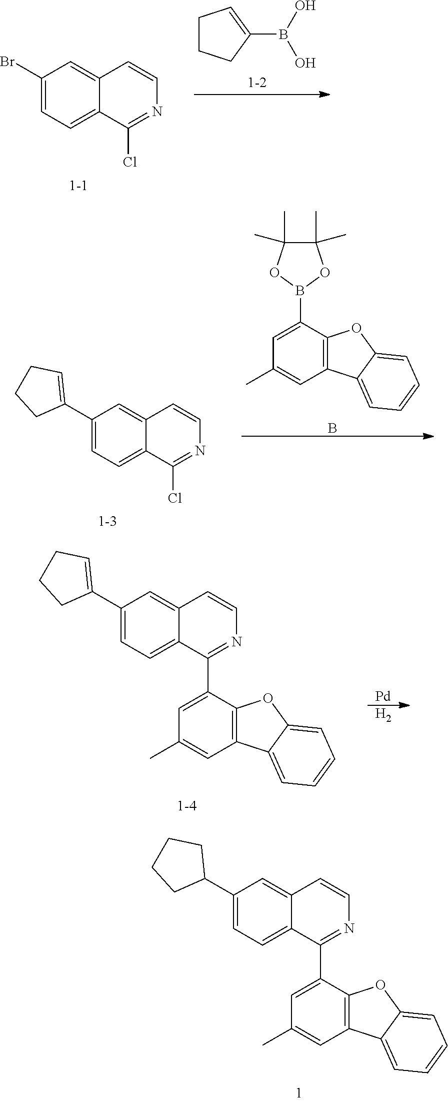

Synthesis of the Compound 1-3:

The compound 1-1 (25 g, 103.09 mmol, 1.0 eq), compound 1-2 (13.85 g, 123.71 mmol, 1.2 eq), Pd-132 (1.46 g, 2.06 mmol, 0.02 eq), k3PO4 (43.77 g, 206.19 mmol, 2.0 eq), and toluene (375 ml) were successively added to a 1 L three-necked flask, vacuumized and replaced with nitrogen for 3 times, then heated up to 60° C. around in an oil bath and stirred for 16 h; sampling was performed, and basic completion of the reaction of the raw material 1-1 was monitored by TLC. The system was cooled to room temperature, and ethyl acetate (300 ml) was added to a reaction flask, then deionized water was added for washing for 3 times (150 ml/times), and liquid separation was performed, and the organic phase was subjected to concentrated under reduced pressure into a solid. The coarse product was subjected to column chromatography isolation (EA:Hex=1:10); and the obtained product was dried to obtain 18.4 g of an off-white compound 1-3 with a yield of 77.7%. Mass spectrometry: 230.1 (M+H)

Synthesis of the Compound 1-4:

The compound 1-3 (18.02 g, 78.46 mmol, 1.24 eq), compound B (19.5 g, 63.27 mmol, 1.0 eq), Pd-132 (0.45 g, 0.632 mmol, 0.01 eq), Na2CO3 (13.41 g, 126.5 mmol, 2.0 eq), tetrahydrofuran (180 ml) and deionized water (90 ml) were successively added to a 500 ml three-necked flask, vacuumized and replaced with nitrogen for 3 times, then heated up to 60° C. around in an oil bath and stirred for 2 h; sampling was performed, and basic completion of the reaction of the raw material 1-3 was monitored by TLC. The system was cooled to room temperature, and ethyl acetate (300 ml) was added to a reaction flask, then deionized water was added for washing for 3 times (150 ml/times), and liquid separation was performed, and the organic phase was subjected to concentrated under reduced pressure into a solid. The coarse product was recrystallized with toluene/methanol (coarse product:toluene:methanol=1:5:40); and the obtained product was dried to obtain 17.1 g of a white compound 1-4 with a yield of 72%. Mass spectrometry: 376.2 (M+H)

Synthesis of the Compound 1:

The compound 1-4 (17 g, 45.28 mmol, 1.0 eq), 10% palladium on carbon (7.23 g, 6.79 mmol, 0.15 eq), and a mixed solvent of tetrahydrofuran (34 ml) and ethanol (51 ml) was successively added to a 250 ml single-necked flask; H2 was fed to the reaction flask, then heated up to 60° C. around in an oil bath and stirred for 24 h; sampling was performed, and basic completion of the reaction of the raw material 1-4 was monitored by TLC. The system was cooled to room temperature; reaction liquid was filtered directly, and filtrate was collected, concentrated and dried. The coarse product was subjected to column chromatography isolation (EA:Hex=1:8); and the obtained product was dried to obtain 14.63 g of an off-white compound 1 with a yield of 85.6%. Mass spectrometry: 378.2 (M+H), 1H NMR (400 MHz, CDCl3) δ 8.65 (d, J=5.7 Hz, 1H), 7.94 (d, J=7.4 Hz, 1H), 7.86 (s, 1H), 7.72 (d, J=7.9 Hz, 2H), 7.69-7.56 (m, 2H), 7.52 (s, 1H), 7.44-7.25 (m, 3H), 2.96 (s, 1H), 2.31 (s, 3H), 1.96 (s, 2H), 1.72 (t, J=25.0 Hz, 6H).

Synthesis of a Shared Intermediate Compound 2:

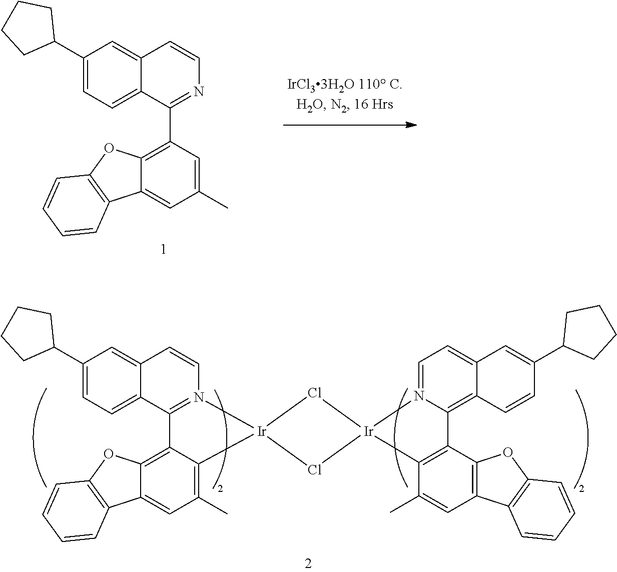

The compound 1 (22.6 g, 0.06 mol, 3.0 eq), and IrCl₃ 3H₂O (7.04 g, 0.02 mol, 1.0 eq) were placed to a flask, and added to 2-ethoxyethanol (133.4 ml) and deionized water (66.7 ml); the mixed solution was stirred for reflux for 16 h at 110° C. under the protection of N₂. The system was cooled to room temperature, then filtered; filter residue was dried successively by methanol (100 ml*3) and n-hexane (100 ml*3) to obtain a compound 3 (25.26 g, 64.5%). The obtained compound was directly put into the next step without purification.

Synthesis of CPD 7

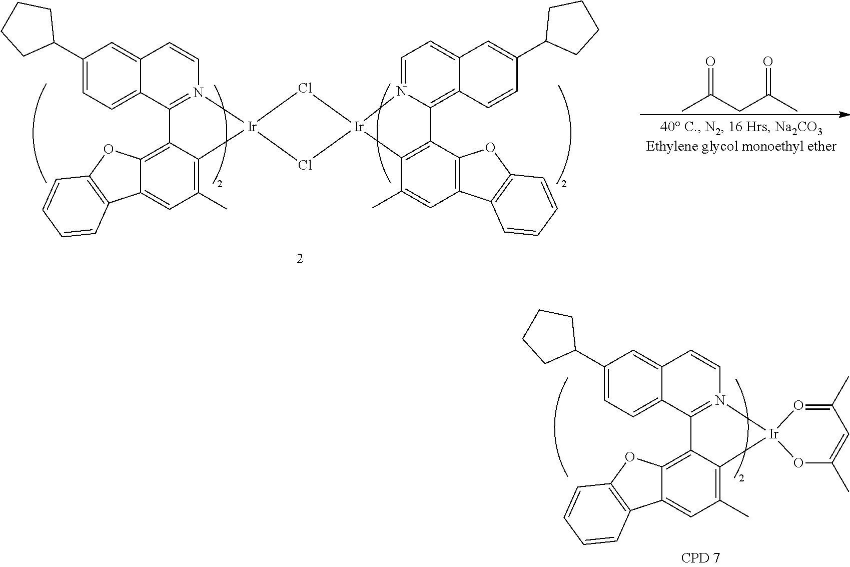

The compound 2 (5.88 g, 3 mmol, 1.0 eq) was dissolved into ethylene glycol monoethyl ether (30 ml), and successively added with anhydrous sodium carbonate (6.36 g, 60 mmol, 20.0 eq) and diacetone (3 g, 30 mmol, 10.0 eq), at the end of the addition, the mixed solution was stirred for 16 h at 40° C. under the protection of N₂, and then cooled to room temperature. 2 g diatomite and 300 ml dichloromethane were added to the reaction liquid, then the mixed solution was filtered with diatomite and silica gel; the obtained filtrate was subjected to rotary removal of dichloromethane, and 40 ml isopropanol was added to residual liquid to separate out a red solid for filtering. The solid was beaten with ethyl acetate to obtain a target compound CPD 7 (3.92 g, 62.6%). 3.92 g of CPD 7 coarse product was sublimated and purified to obtain a sublimated product CPD 7 (2.98 g, 76.2%). Mass spectrometry: 1045.35 (M+H)

Synthesis of CPD 9

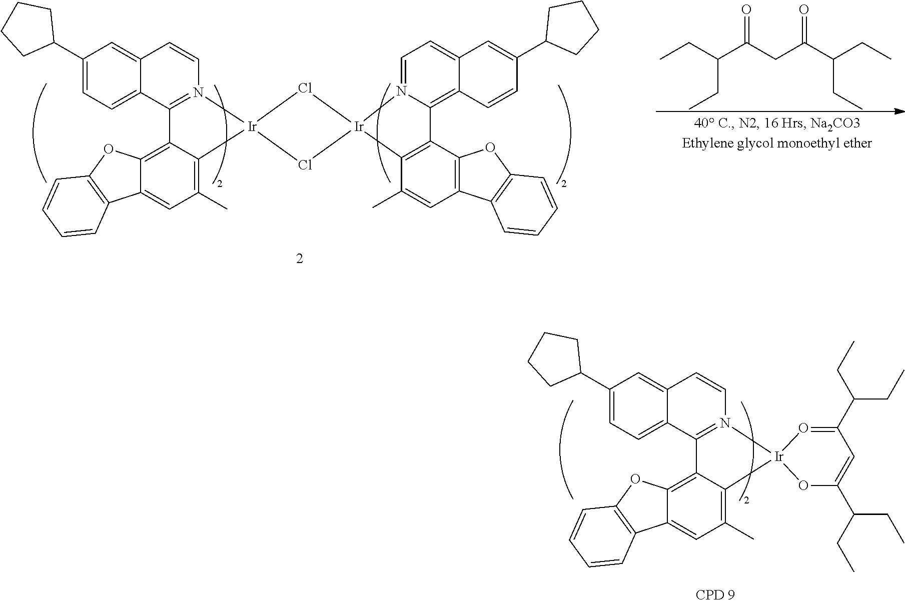

The compound 3 (5.88 g, 3 mmol, 1.0 eq) was dissolved into ethylene glycol monoethyl ether (30 ml), and successively added with anhydrous sodium carbonate (6.36 g, 60 mmol, 20.0 eq) and 3,7-diethyl-4,6-nonyldione (6.36 g, 30 mmol, 10.0 eq), at the end of the addition, the mixed solution was stirred for 16 h at 40° C. under the protection of N₂, and then cooled to room temperature. 2 g diatomite and 300 ml dichloromethane were added to the reaction liquid, then the mixed solution was filtered with diatomite and silica gel; the obtained filtrate was subjected to rotary removal of dichloromethane, and 40 ml isopropanol was added to residual liquid to separate out a red solid for filtering. The solid was beaten with ethyl acetate to obtain a target compound CPD 9 (4.09 g, 58.9%). 4.09 g of CPD 9 coarse product was sublimated and purified to obtain a sublimated product CPD 9 (2.96 g, 72.3%). Mass spectrometry: 1157.47 (M+H)

Synthesis of CPD 12

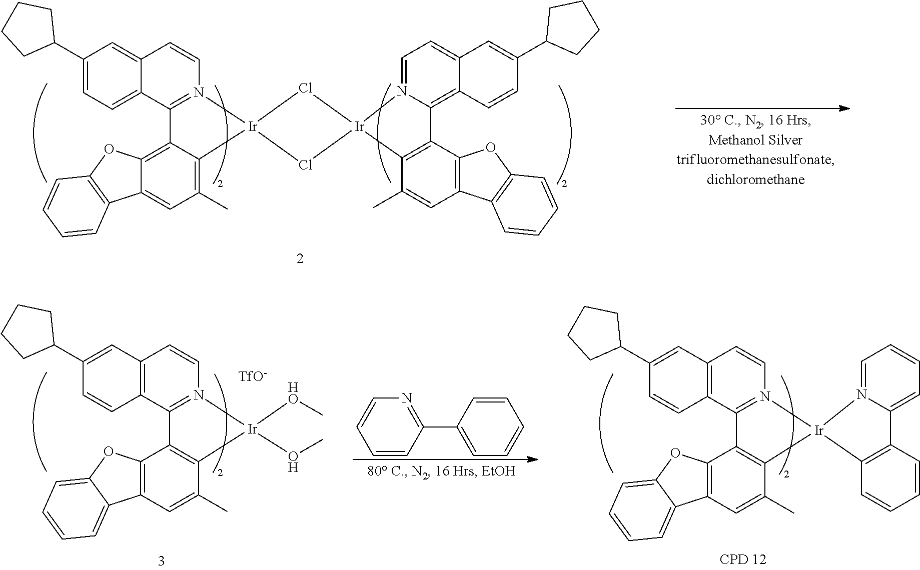

Synthesis of the Compound 3:

The compound 2 (19.6 g, 0.01 mol, 1.0 eq) was dissolved into DCM (500 ml), and successively added with silver trifluoromethanesulfonate (5.25 g, 0.02 mol, 2.0 eq) and methanol (50 ml), at the end of the addition, the mixed solution was stirred for 16 h at 30° C. under the protection of N₂. Insoluble solid in the reaction liquid was removed with silica gel and diatomite; then filtrate was subjected to rotary drying to obtain the compound 3 (22.6 g); the obtained product was directly put into the next reaction.

Synthesis of CPD 12:

The compound 3 (3.47 g, 3 mmol, 1.0 eq) and 2-phenylpyridine (1.4 g, 9 mmol, 3.0 eq) were dissolved into absolute ethyl alcohol (100 ml), at the end of the addition, the mixed solution was stirred under reflux for 16 h at 80° C. under the protection of N2, and then cooled to room temperature. The cooled mixed solution was filtered; filter residue was washed for 3 times with methanol and n-hexane successively. The obtained product was dried to obtain a target compound CPD 12 (1.74 g, 52.8%). 1.74 g of CPD 12 coarse product was sublimated and purified to obtain a sublimated product CPD 12 (1.16 g, 66.4%). Mass spectrometry: 1100.37 (M+H)

### Example 2 (Synthesis of CPD 31/33/36)

Synthesis of a Shared Intermediate Compound 5:

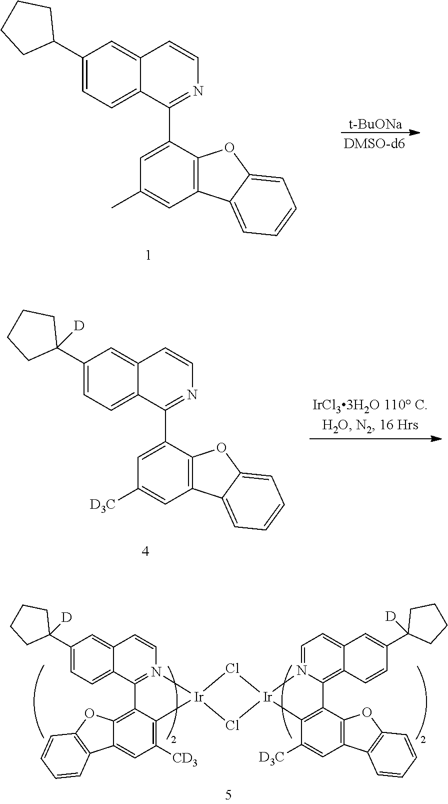

Synthesis of the Compound 4:

The compound 1 (14.3 g, 37.88 mmol, 1.0 eq), sodium tert-butoxide (10.92 g, 113.65 mmol, 3 eq), and DMSO-d6 (172 ml) were successively added to a 250 ml single-necked flask, vacuumized and replaced with nitrogen for 3 times, then heated up to 75° C. around in an oil bath and stirred for 24 h. The system was cooled to room temperature, added with heavy water (35 ml) and stirred for 10 min to separate out yellow solid; then added with deionized water (350 ml) and stirred for 10 min, and subjected to suction filtration to collect a yellow solid. The solid was dissolved with ethyl acetate (450 ml), and added with deionized water for washing for 3 times (200 ml/times), and subjected to liquid separation; aqueous phases were combined and extracted once with a little amount of ethyl acetate; then organic phases were combined, concentrated and dried. The coarse product was subjected to column chromatography isolation (EA:Hex=1:8); and the obtained product was dried to obtain 12.8 g of a white solid compound 4 with a yield of 88.6%. Mass spectrometry: 382.5 (M+H), 1H NMR (400 MHz, CDCl3) δ 8.65 (d, J=5.7 Hz, 1H), 7.94 (d, J=7.4 Hz, 1H), 7.86 (s, 1H), 7.72 (d, J=7.9 Hz, 2H), 7.69-7.56 (m, 2H), 7.52 (s, 1H), 7.44-7.25 (m, 3H), 1.99 (m, 2H), 1.89-1.58 (m, 6H).

Synthesis of the Compound 5: The compound 5 (30.34 g, 77.3%) was obtained by reference to the synthesis of the compound 2 and post-treatment conditions. The obtained compound was directly put into the next step without purification.

Synthesis of CPD 31:

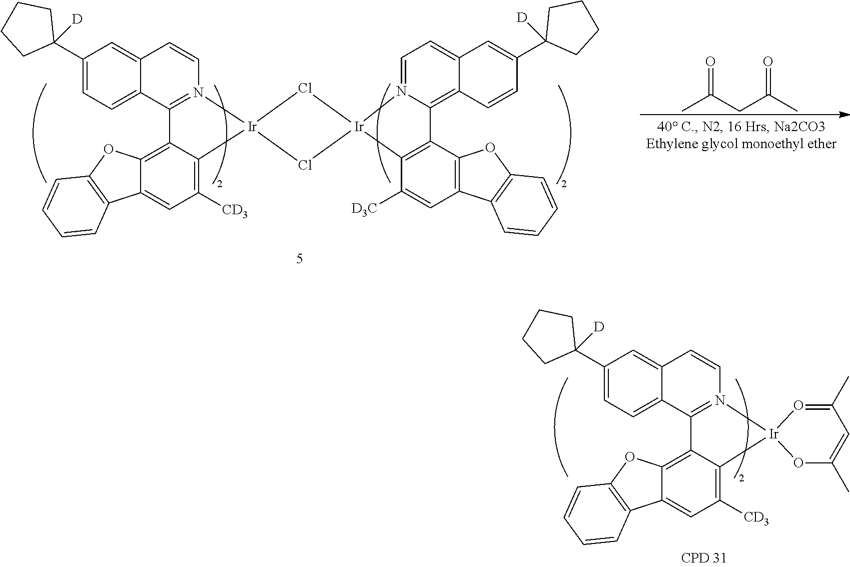

The target compound CPD 31 (2.82 g, 81.2%) was obtained according to the same synthesis and purification method of CPD 7. 2.82 g of CPD 31 coarse product were sublimated and purified to obtain a sublimated product CPD 31 (1.93 g, 68.4%). Mass spectrometry: 1041.4 (M+H)

Synthesis of CPD 33:

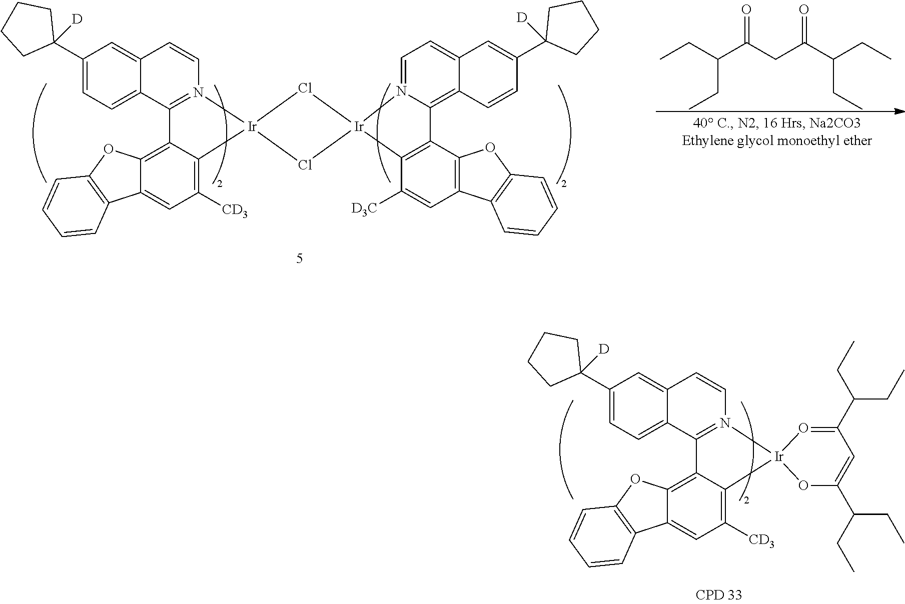

The target compound CPD 33 (3.37 g, 79.5%) was obtained according to the same synthesis and purification method of CPD 9. 3.37 g of CPD 33 coarse product were sublimated and purified to obtain a sublimated product CPD 33 (2.55 g, 75.6%). Mass spectrometry: 1165.5 (M+H)

Synthesis of CPD 36:

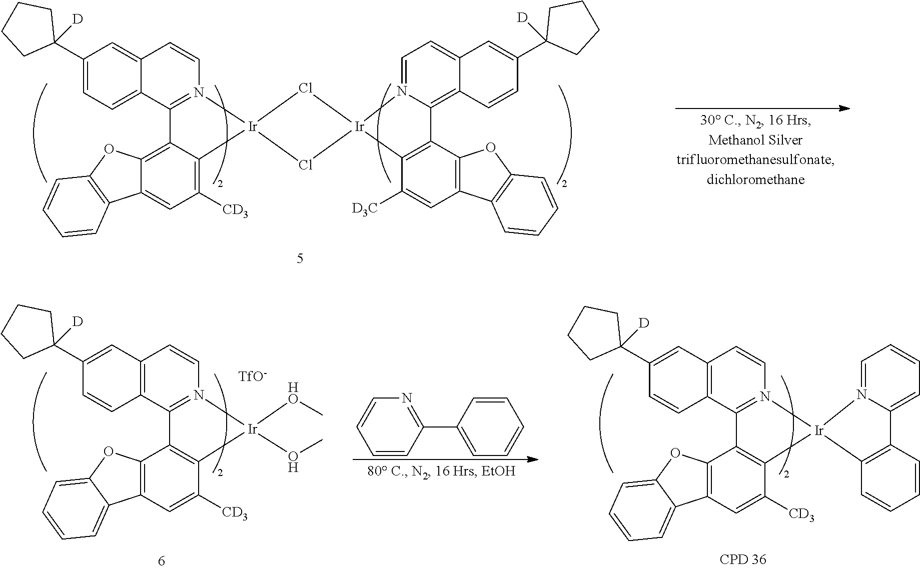

The target compound CPD 36 (4.37 g, 45.6%) was obtained according to the same synthesis and purification method of CPD 12.4.37 g of CPD 36 coarse product were sublimated and purified to obtain a sublimated product CPD 36 (2.89 g, 66.1%).

Mass spectrometry: 1108.4 (M+H)

### Example 3 (Synthesis of CPD 61/63/66)

Synthesis of a Shared Intermediate Compound 7:

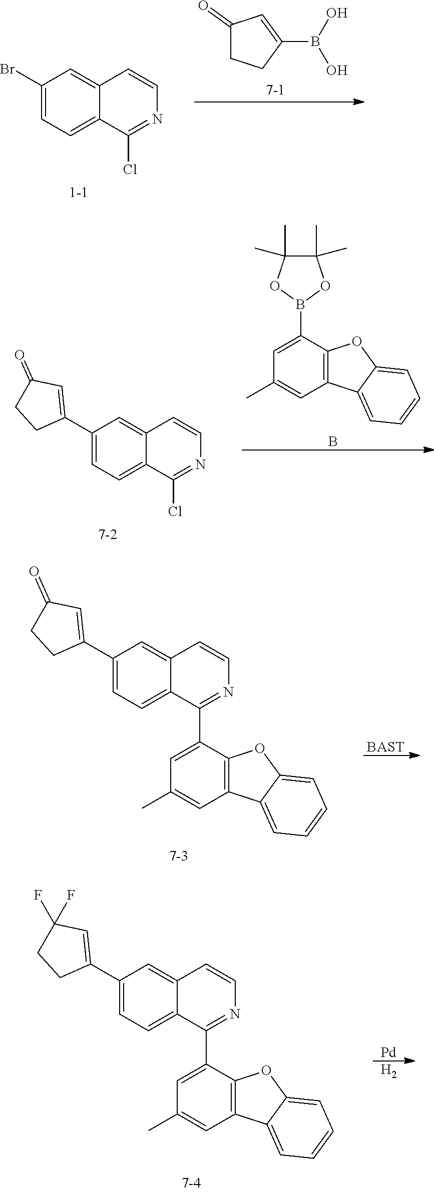

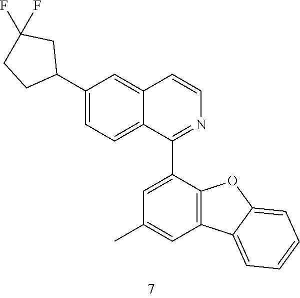 [SMILES: Cc1cc(-c2nccc3cc(C4CCC(F)(F)C4)ccc23)c2oc3ccccc3c2c1]

Synthesis of the Compound 7-2:

The synthesis was performed by reference to the synthesis way and treatment method of the compound 1-3 via changing the corresponding raw materials only.

Synthesis of the Compound 7-3:

The synthesis was performed by reference to the synthesis way and treatment method of the compound 1-4 via changing the corresponding raw materials only.

Synthesis of the Compound 7-4:

The compound 7-3 (25 g, 64.19 mmol, 1.0 eq) and dichloromethane (150 ml) were successively added to a 500 ml single-necked flask; the reaction system was cooled to 0° C. around, and dropwisely added with (bis(2-methoxyethyl)amino)sulfur trifluoride (BAST, 35.51 ml, 192.58 mmol, 3.0 eq), and stirred for 16 h at room temperature after addition; sampling was performed, and basic completion of the reaction of the raw material 7-3 was monitored by TLC. The reaction liquid was added to a saturated sodium carbonate solution (450 ml) and stirred for 0.5 h, standing for liquid separation; the aqueous layer was added with dichloromethane (150 ml) for extraction once; organic phases were combined and washed with deionized water for 3 times (100 ml/times), subjected to liquid separation, concentrated and dried. The coarse product was subjected to column chromatography isolation (EA:Hex=1:10); and the obtained product was dried to obtain 19.28 g of a white compound 7-4 with a yield of 73%. Mass spectrometry: 412.4 (M+H)

Synthesis of the Compound 7:

The synthesis was performed by reference to the synthesis way and treatment method of the compound 1 via changing the corresponding raw materials only. Mass spectrometry: 414.2 (M+H), ¹H NMR (400 MHz, CDCl₃) δ 8.65 (d, J=5.7 Hz, 1H), 7.94 (d, J=7.4 Hz, 1H), 7.86 (s, 1H), 7.72 (d, J=7.9 Hz, 2H), 7.69-7.56 (m, 2H), 7.52 (s, 1H), 7.44-7.25 (m, 3H), 3.26 (d, 1H), 2.44 (m, 1H), 2.32 (s, 3H), 2.03 (m, J=28.1, 24.1 Hz, 4H), 1.76 (m, 1H).

Synthesis of the Shared Intermediate Compound 8:

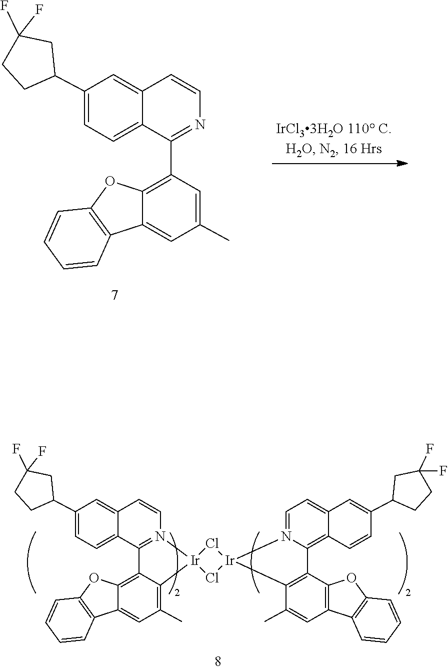

The compound 8 (28.6 g, 68.6%) was obtained by reference to the synthesis of the compound 2 and post-treatment conditions. The obtained compound was directly put into the next step without purification.

Synthesis of CPD 61:

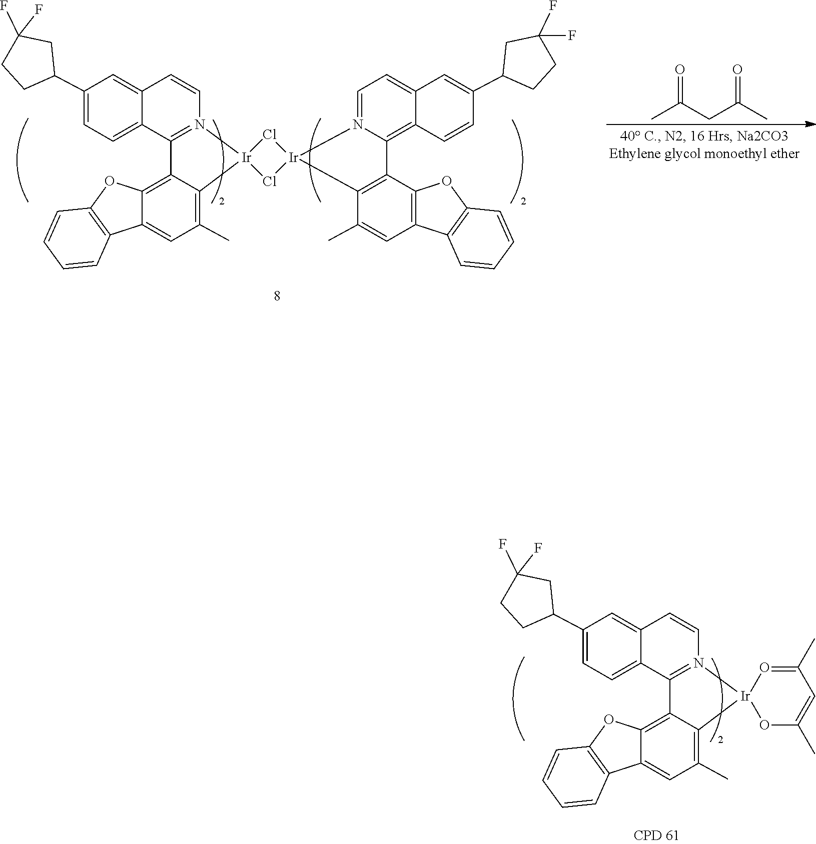

The target compound CPD 61 (2.81 g, 79.1%) was obtained according to the same synthesis and purification method of CPD 7.2.81 g of CPD 61 coarse product were sublimated and purified to obtain a sublimated product CPD 61 (1.84 g, 65.4%). Mass spectrometry: 1117.2 (M+H)

Synthesis of CPD 63:

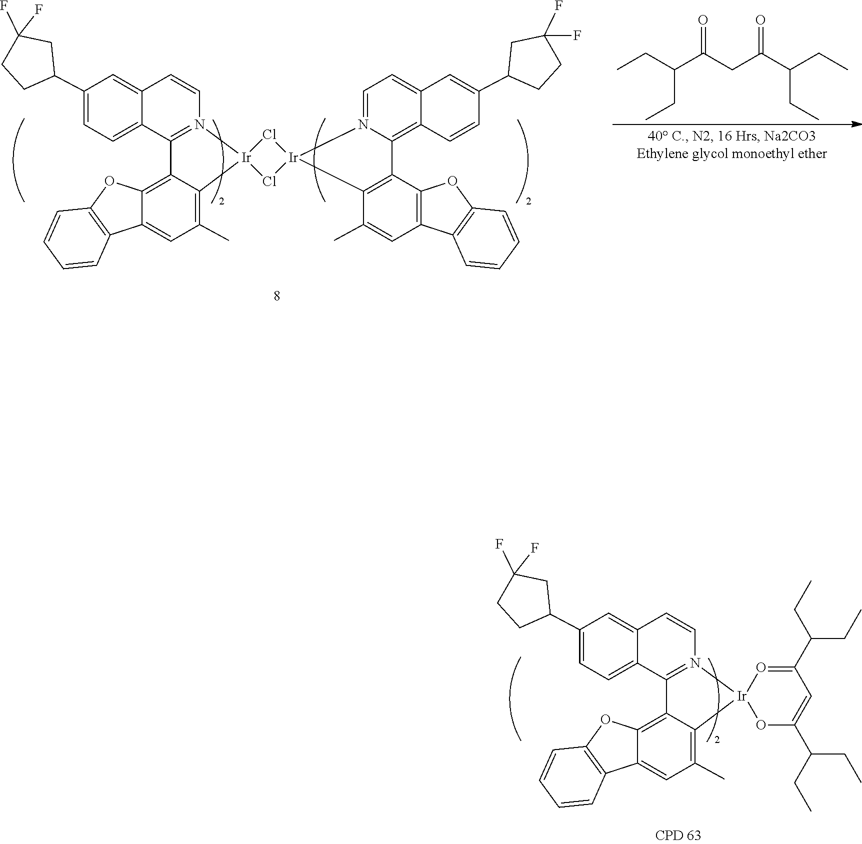

The target compound CPD 63 (2.92 g, 76.7%) was obtained according to the same synthesis and purification method of CPD 9.2.92 g of CPD 63 coarse product were sublimated and purified to obtain a sublimated product CPD 63 (2.04 g, 69.8%). Mass spectrometry: 1233.5 (M+H)

Synthesis of CPD 66:

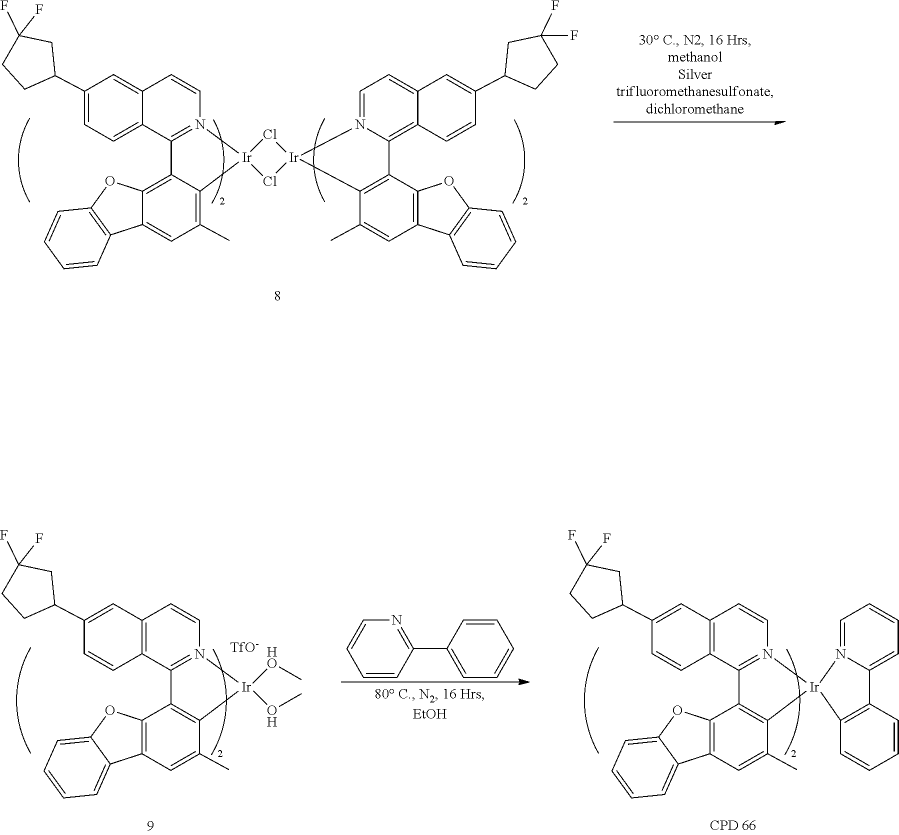

The target compound CPD 66 (3.51 g, 42.1%) was obtained according to the same synthesis and purification method of CPD 12.3.51 g of CPD 66 coarse product were sublimated and purified to obtain a sublimated product CPD 66 (1.97 g, 56.1%). Mass spectrometry: 1172.3 (M+H)

### Example 4 (Synthesis of CPD 67/69/72)

Synthesis of the Shared Intermediate Compound 10:

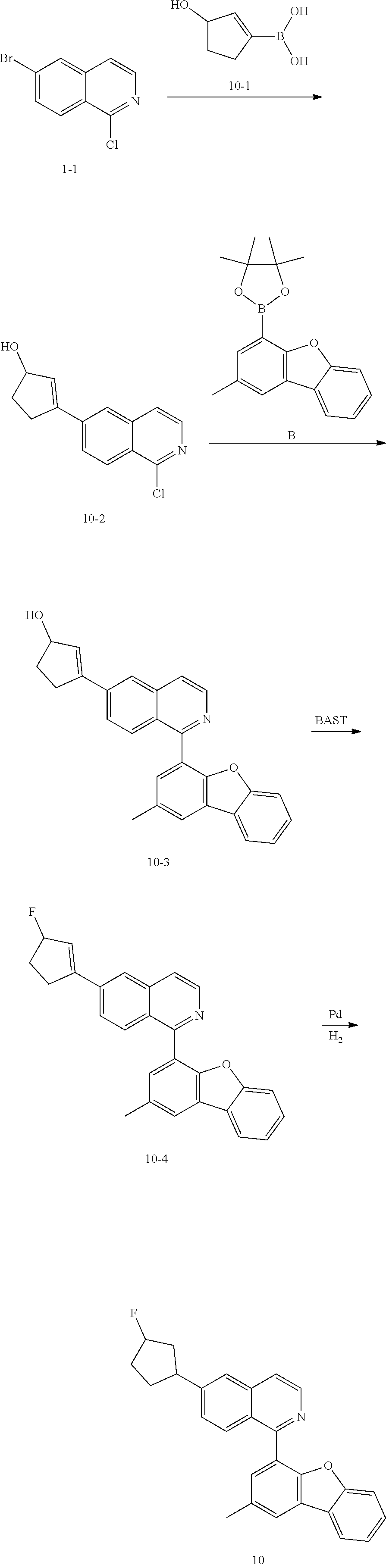

Synthesis of the Compound 10-2:

The synthesis was performed by reference to the synthesis way and treatment method of the compound 1-3 via changing the corresponding raw materials only.

Synthesis of the Compound 10-3:

The synthesis was performed by reference to the synthesis way and treatment method of the compound 1-4 via changing the corresponding raw materials only.

Synthesis of the Compound 10-4:

The synthesis was performed by reference to the synthesis way and treatment method of the compound 7-4 via changing the corresponding raw materials only.

Synthesis of the Compound 10:

The synthesis was performed by reference to the synthesis way and treatment method of the compound 1 via changing the corresponding raw materials only. Mass spectrometry: 396.2 (M+H), ¹H NMR (400 MHz, CDCl₃) δ 8.65 (d, J=5.7 Hz, 1H), 7.94 (d, J=7.4 Hz, 1H), 7.86 (s, 1H), 7.72 (d, J=7.9 Hz, 2H), 7.69-7.56 (m, 2H), 7.52 (s, 1H), 7.44-7.25 (m, 3H). 4.75 (m, 1H), 3.29 (m, 1H), 2.51 (m, 1H), 2.31 (s, 3H), 2.06-1.48 (m, 5H).

Synthesis of the Shared Intermediate Compound 11:

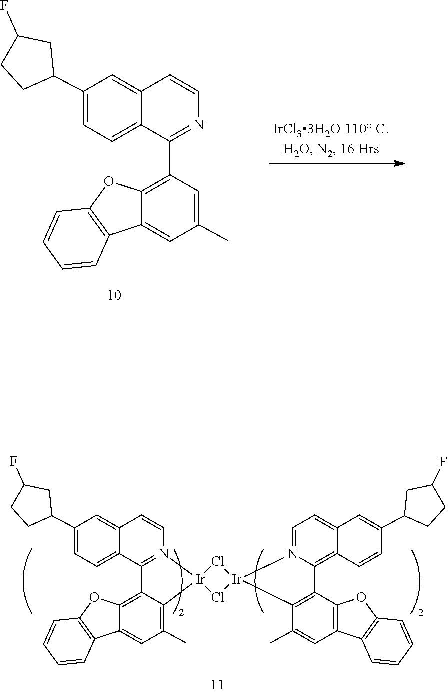

Synthesis of the Compound 11:

The compound 11 (30.32 g, 69.2%) was obtained by reference to the synthesis of the compound 2 and post-treatment conditions. The obtained compound was directly put into the next step without purification.

Synthesis of CPD 67:

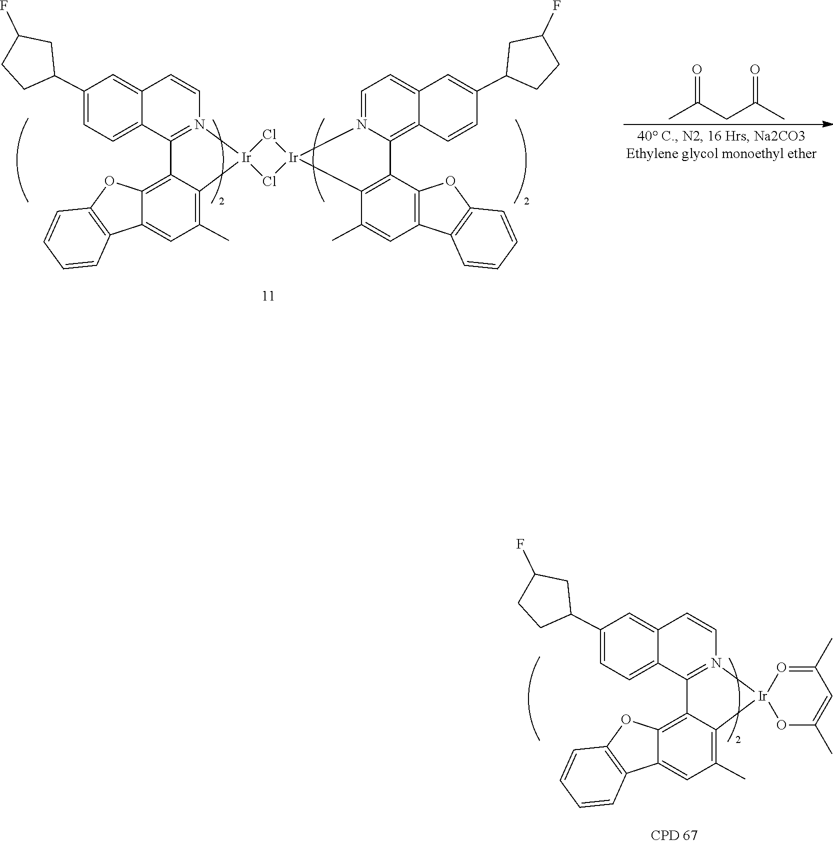

The target compound CPD 7 (3.11 g, 81.2%) was obtained according to the same synthesis and purification method of CPD 67.3.11 g of CPD 67 coarse product were sublimated and purified to obtain a sublimated product CPD 67 (2.33 g, 74.9%). Mass spectrometry: 1081.2 (M+H)

Synthesis of CPD 69:

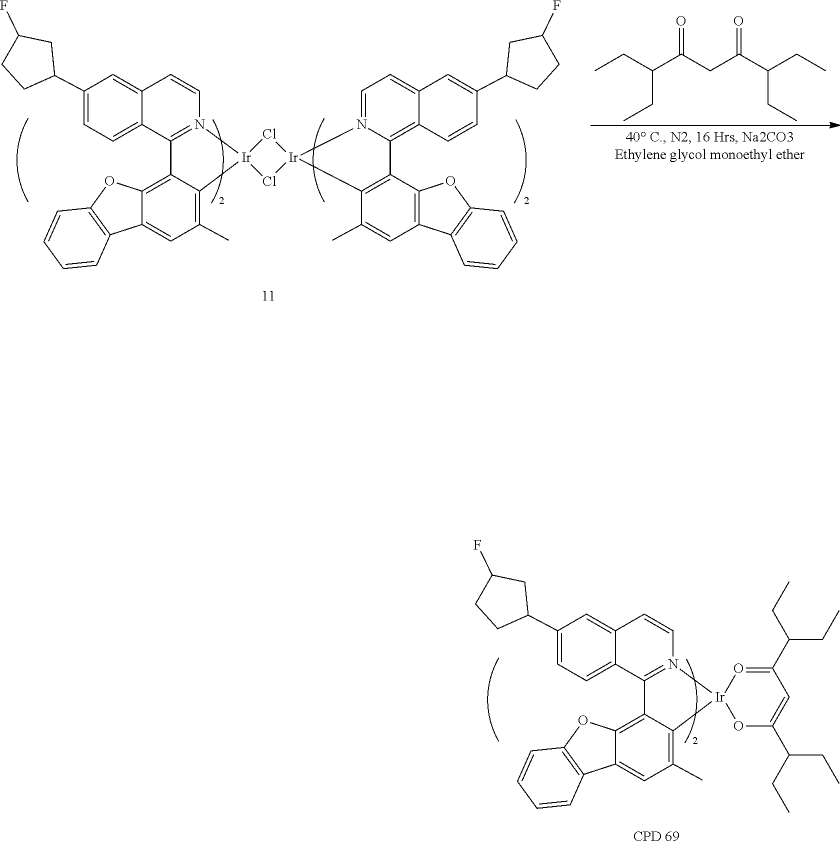

The target compound CPD 69 (2.72 g, 73.2%) was obtained according to the same synthesis and purification method of CPD 9.2.72 g of CPD 69 coarse product were sublimated and purified to obtain a sublimated product CPD 69 (2.12 g, 77.9%). Mass spectrometry: 1193.5 (M+H)

Synthesis of CPD 72:

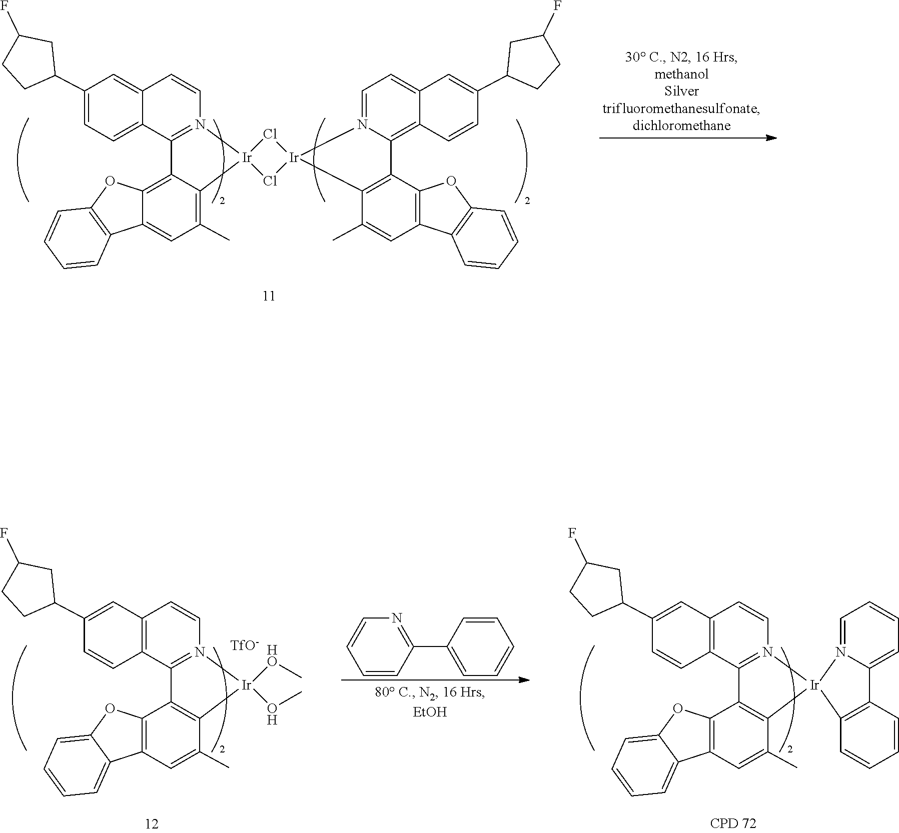

The target compound CPD 72 (4.7 g, 57.6%) was obtained according to the same synthesis and purification method of CPD 12.4.7 g of CPD 72 coarse product were sublimated and purified to obtain a sublimated product CPD 72 (2.83 g, 60.2%). Mass spectrometry: 1136.3 (M+H)

### Example 5 (Synthesis of CPD 133/135/138)

Synthesis of the Shared Intermediate Compound 13:

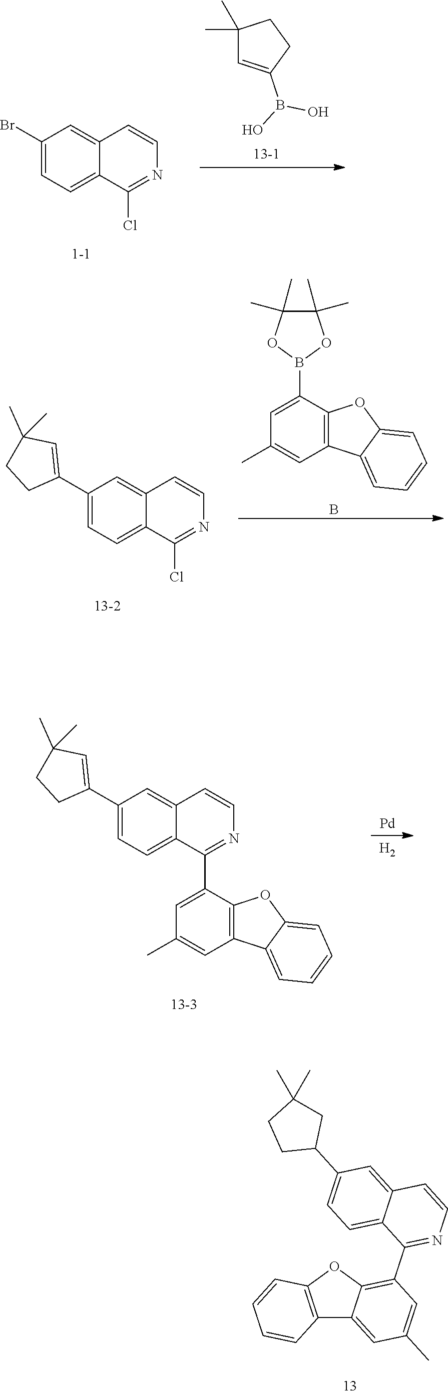

Synthesis of the Compound 13-2:

The synthesis was performed by reference to the synthesis way and treatment method of the compound 1-3 via changing the corresponding raw materials only.

Synthesis of the Compound 13-3: The synthesis was performed by reference to the synthesis way and treatment method of the compound 1-4 via changing the corresponding raw materials only.

Synthesis of the Compound 13:

The synthesis was performed by reference to the synthesis way and treatment method of the compound 1 via changing the corresponding raw materials only. Mass spectrometry: 406.2 (M+H), ¹H NMR (400 MHz, CDCl₃) δ 8.65 (d, J=5.7 Hz, 1H), 7.94 (d, J=7.4 Hz, 1H), 7.86 (s, 1H), 7.72 (d, J=7.9 Hz, 2H), 7.69-7.56 (m, 2H), 7.52 (s, 1H), 7.44-7.25 (m, 3H), 3.04 (d, 1H), 2.31 (s, 3H), 1.99 (d, J=1.6 Hz, 2H), 1.75 (m, 1H), 1.51 (m, 1H), 1.34 (m, 1H), 1.26 (m, 1H), 0.87 (s, 6H).

Synthesis of the Shared Intermediate Compound 14:

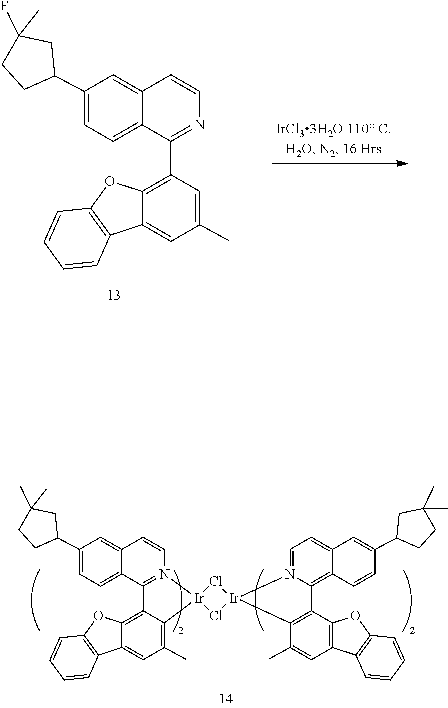

The compound 14 (28.75 g, 65.2%) was obtained by reference to the synthesis of the compound 2 and post-treatment conditions. The obtained compound was directly put into the next step without purification.

Synthesis of CPD 133:

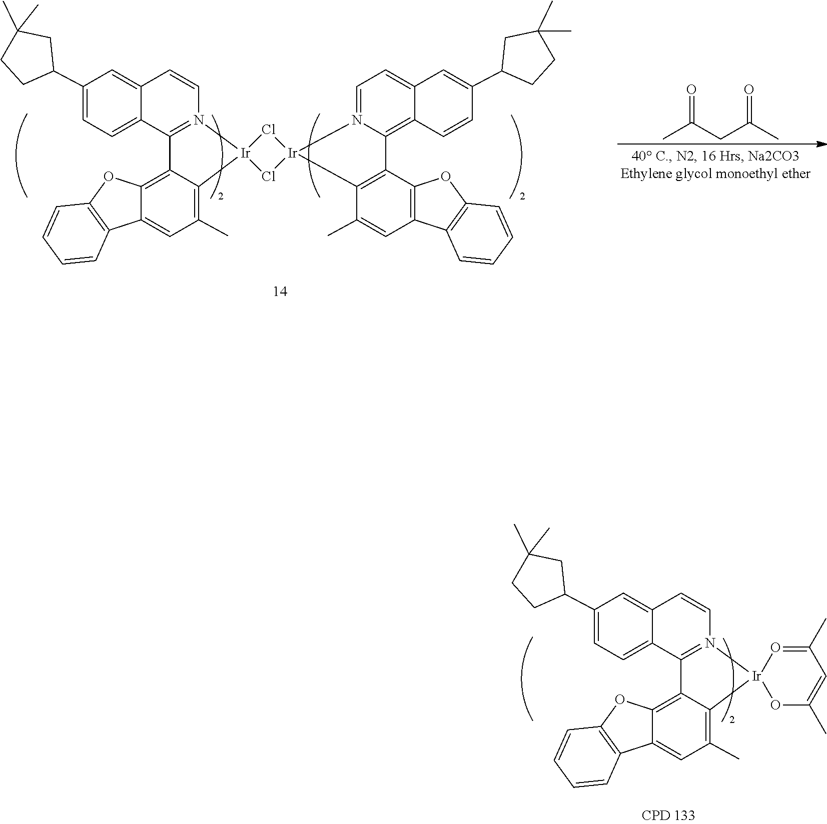

The target compound CPD 133 (2.45 g, 76.2%) was obtained according to the same synthesis and purification method of CPD 7.2.45 g of CPD 133 coarse product were sublimated and purified to obtain a sublimated product CPD 133 (1.85 g, 75.5%). Mass spectrometry: 1101.3 (M+H)

Synthesis of CPD 135:

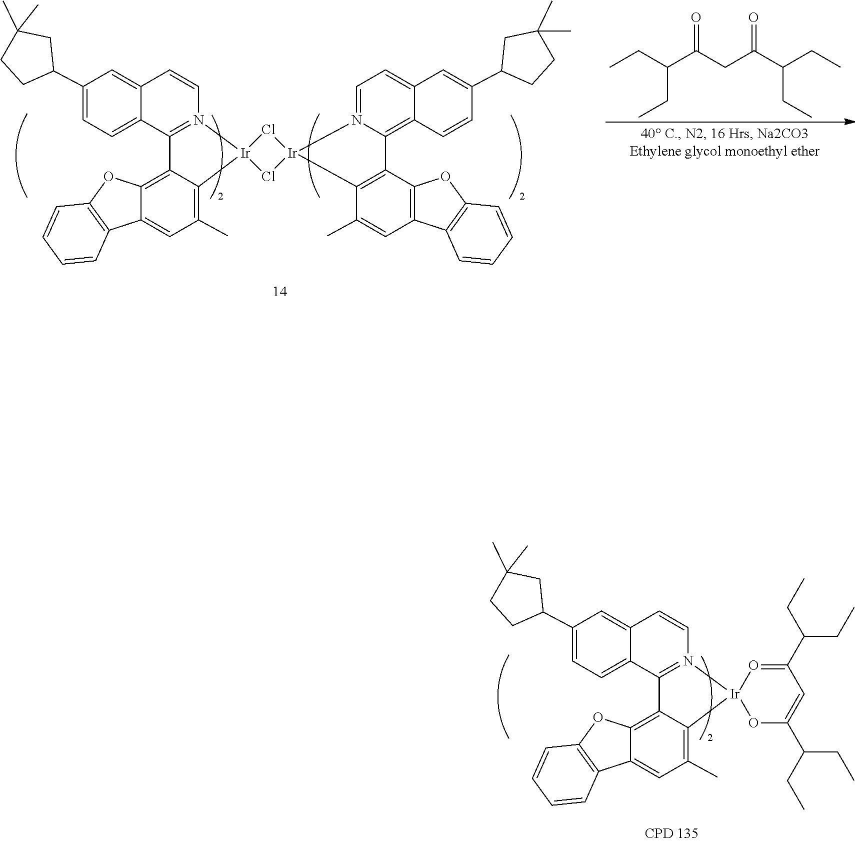

The target compound CPD 135 (2.81 g, 73.3%) was obtained according to the same synthesis and purification method of CPD 9.2.81 g of CPD 135 coarse product were sublimated and purified to obtain a sublimated product CPD 135 (2.01 g, 71.5%). Mass spectrometry: 1213.5 (M+H)

Synthesis of CPD 138:

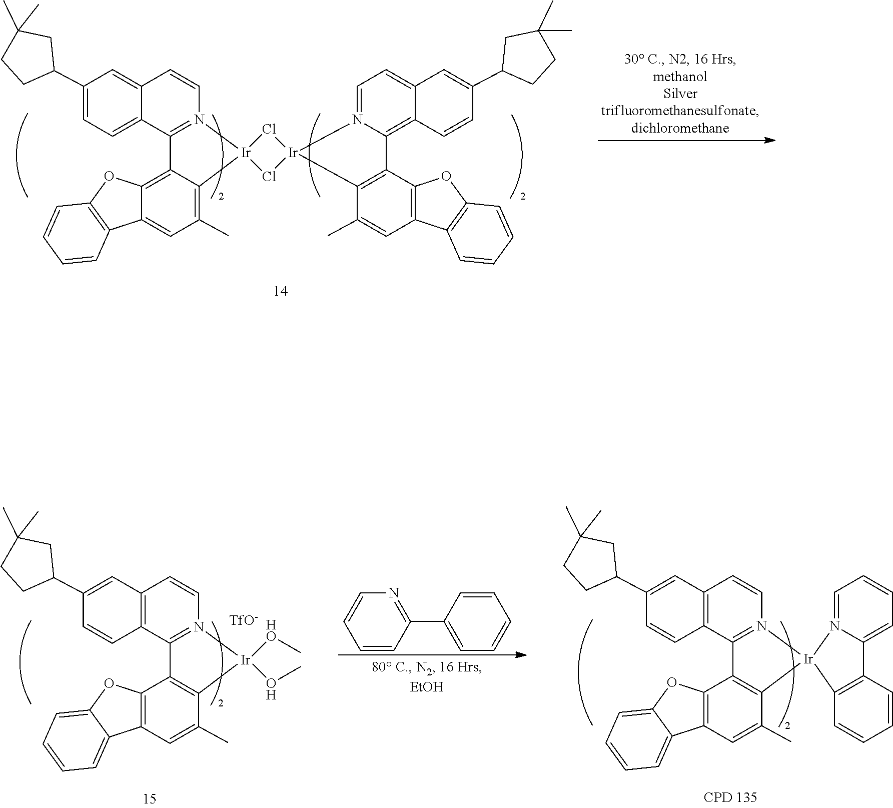

The target compound CPD 138 (3.85 g, 46.7%) was obtained according to the same synthesis and purification method of CPD 12.3.85 g of CPD 138 coarse product were sublimated and purified to obtain a sublimated product CPD 138 (2.11 g, 54.8%). Mass spectrometry: 1156.5 (M+H)

Corresponding materials were selected and might be used to synthesize and sublimate to obtain other compounds according to the similar method.

Application Example: Manufacture of an Organic Light-Emitting Device

50 mm*50 mm*1.0 mm glass substrate having ITO (100 nm) transparent electrodes was subjected to ultrasonic cleaning for 10 min in ethanol, and dried at 150° C., then treated by N₂ Plasma for 30 min. The washed glass substrate was mounted on a substrate support of a vacuum evaporation device; a compound HATCN was evaporated on a face with transparent electrode wires first by covering transparent electrodes to form a thin film having a film thickness of 5 nm; a layer of HTM1 was then evaporated to form a thin film having a film thickness of 60 nm, and a layer of HTM2 was evaporated on the HTM1 film to form a thin film having a film thickness of 10 nm, and then a host material CBP and a doped compound (comparative compounds X, CPD X) were evaporated on the HTM2 film in a co-evaporation mode with a film thickness of 30 nm; and a ratio of the host material to the doped material was 90%:10%. A AlQ3 film (25 nm) and a LiF film (1 nm) were successively evaporated on a light-emitting layer, and finally a layer of metal Al (100 nm) was evaporated as an electrode.

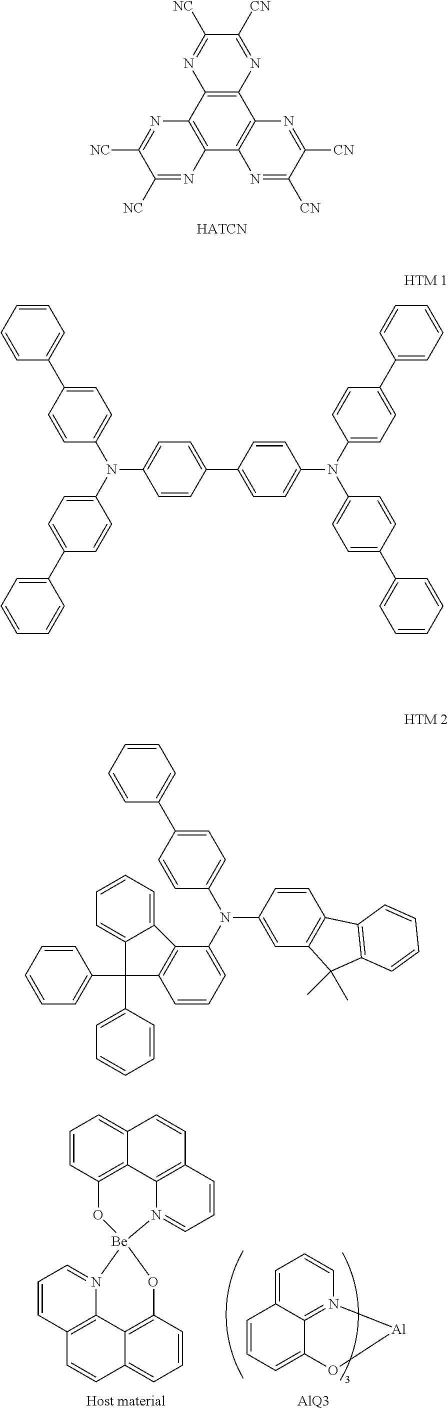

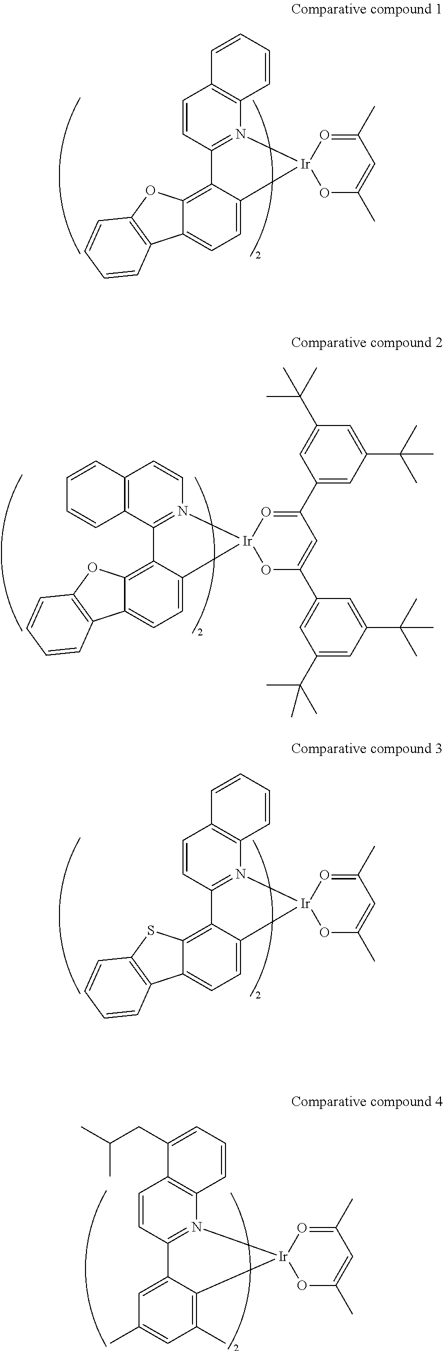

Evaluation: the above device was subjected to device performance test; in each example and comparative example, a constant current supply (Keithley 2400) was used to flow through a light-emitting element with a constant electric current density; a spectroradiometer (CS 2000) was used to test light emission spectrum. Meanwhile, voltage values and time (LT90) when luminance is tested 90% of the initial luminance were measured. Results are as follows:

| | | Starting | Current | Power | Peak | LT90 @ |
|---|---|---|---|---|---|---|
| | Doped | voltage | efficiency | efficiency | wavelength | 3000 |
| | material | V | Cd/A | 1 m/W | nm | nits |
| Example 1 | CPD 7 | 4.18 | 29.3 | 22.0 | 616 | 186 |
| Example 2 | CPD 9 | 4.15 | 32.5 | 24.6 | 617 | 225 |
| Example 3 | CPD 12 | 4.14 | 28.8 | 21.9 | 615 | 213 |
| Example 4 | CPD 31 | 4.16 | 29.6 | 22.4 | 616 | 203 |
| Example 5 | CPD 33 | 4.16 | 33.2 | 25.1 | 618 | 229 |
| Example 6 | CPD 36 | 4.17 | 29.2 | 22.0 | 616 | 220 |
| Example 7 | CPD 61 | 4.25 | 30.2 | 22.3 | 620 | 178 |
| Example 8 | CPD 63 | 4.21 | 31.3 | 23.4 | 621 | 186 |
| Example 9 | CPD 66 | 4.26 | 29.9 | 22.1 | 620 | 192 |
| Example 10 | CPD 67 | 4.22 | 29.1 | 21.7 | 618 | 183 |
| Example 11 | CPD 69 | 4.25 | 30.9 | 22.8 | 619 | 199 |
| Example 12 | CPD 72 | 4.19 | 28.6 | 21.4 | 619 | 189 |
| Example 17 | CPD 135 | 4.17 | 30.4 | 22.9 | 617 | 197 |
| Comparative | Comparative | 4.56 | 21 | 14.46 | 610 | 102 |
| Example 1 | compound 1 | | | | | |
| Comparative | Comparative | 4.41 | 20 | 14.24 | 612 | 116 |
| Example 2 | compound 2 | | | | | |
| Comparative | Comparative | 4.64 | 21 | 14.21 | 611 | 94 |
| Example 3 | compound 3 | | | | | |
| Comparative | Comparative | 4.88 | 18 | 11.58 | 608 | 82 |
| Example 4 | compound 4 | | | | | |

It can be seen from data of the above table that compared with comparative compounds, the organic light-emitting device with the compound of the present invention as a dopant shows more superior performances in driving voltage, luminous efficiency and service life of device.

Comparison in sublimation temperature: sublimation temperature is defined as the corresponding temperature at a vacuum degree of 10⁻⁷′ Torr and a deposition rate of 1 Angstrom per second. Test results are as follows:

| Doped material | Sublimation temperature |
|---|---|
| CPD 9 | 269 |
| CPD 63 | 252 |
| CPD 69 | 251 |
| CPD 135 | 262 |
| Comparative compound 1 | 280 |
| Comparative compound 2 | 288 |
| Comparative compound 3 | 286 |
| Comparative compound 4 | 276 |

It can be seen from the data comparison of the above table that the compound of the present invention has a lower sublimation temperature and thus, beneficial to industrialization application.

The present invention unexpectedly provides a better luminous efficiency and improved service life of device by the special matching of substituents; meanwhile, compared with the prior art, the present invention unexpectedly provides a lower sublimation temperature. The above results indicate that the compound of the present invention has the advantages of a lower sublimation temperature, high photo-stability and electrical stability, high color saturation, high luminous efficiency, long service life of device, and thus, can be applied to an organic light emitting device. The present invention is particularly used as a red luminous dopant, and has the possibility of being applied to the AMOI ED industry.

1. A compound, having a structural formula as shown in Formula I: 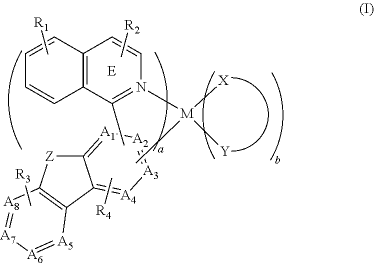
wherein one of A1-A4 is a C—C bond and linked with a ring E; one is a C-M bond and linked with a metal M, one is CR₄, and the other one is CR₀ or N; one of A5-A8 is CR₃, and the other three independently represent CR₀ or N; the M is a metal having an atomic weight greater than 40;
wherein R₀-R₄ are independently selected from hydrogen, deuterium, halogen, substituted or unsubstituted C1-C10 alkyl, substituted or unsubstituted C3-C20 cycloalkyl, substituted or unsubstituted C1-C10 heteroalkyl, substituted or unsubstituted C6-C30 aralkyl, substituted or unsubstituted C1-C10 alkoxy, substituted or unsubstituted C6-C30 aryloxy, amino, substituted or unsubstituted C3-C30 silicyl, substituted or unsubstituted C6-C30 aryl, substituted or unsubstituted C1-C8 heteroaryl, cyano, nitrile, isonitrile or phosphino; and wherein at least one of R₁ and R₂ is substituted or unsubstituted C3-C20 cycloalkyl,
wherein Z is independently selected from O, S, Se, C(R)₂, Si(R)₂, NR, BR and POR; R is independently selected from substituted or unsubstituted C1-C10 alkyl or alkoxy, substituted or unsubstituted C2-C30 cycloalkyl, substituted or unsubstituted C6-C30 aryl, substituted or unsubstituted C1-C18 heteroaryl;
wherein the substitution refers to a substitution by deuterium, F, Cl, Br, C1-C4 alkyl, C1-C4 alkoxy, C3-C6 cycloalkyl, amido substituted by C1-C4 alkyl, cyano, nitrile, isonitrile or phosphino; wherein the substitution refers to a single substitution to a maximum number of substitutions;
wherein X—Y is a monoanionic bidentate ligand, wherein the sum of a and b is equal to a valence state of the metal M.

2. The compound according to claim 1, wherein the X—Y is a type-GO, or CN ligand; the M is one of metals Os, Ir, Pt, Pd, Ru, Rh and Au.

3. The compound according to claim 2, wherein the compound has a structure as shown in Formula II: 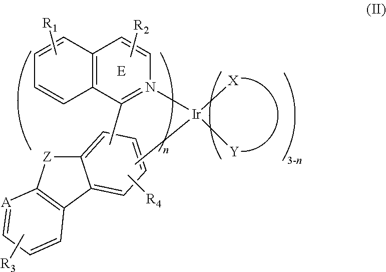
wherein n is a positive integer of 1-2; A is CR₀ or N; R₀-R₄ are independently selected from H, deuterium, substituted or unsubstituted C1-C8 alkyl, heteroalkyl, substituted or unsubstituted C3-C20 cycloalkyl, substituted or unsubstituted C1-C8 aralkyl, substituted or unsubstituted C3-C30 silicyl, C1-C4 alkyl substituted or unsubstituted C1-C8 aryl, or C1-C4 alkyl substituted or unsubstituted C1-C8 heteroaryl; and wherein at least one of R₁ and R₂ is substituted or unsubstituted C3-C20 cycloalkyl; wherein the substitution refers to a substitution by deuterium, F, Cl, Br, C1-C4 alkyl, C1-C4 alkoxy, C3-C6 cycloalkyl, amido substituted by C1-C4 alkyl, cyano, nitrile, isonitrile or phosphino; the substitution refers to a single substitution to a possible maximum substitutions.

4. The compound according to claim 3, wherein the substitution refers to a substitution by D, F, C3-C6 cycloalkyl, or C1-C4 alkyl substituted by D or F partially or completely.

5. The compound according to claim 3, wherein R₄ is not H.

6. The compound according to claim 5, wherein the R₄ substituent is positioned adjacent to a metal Ir—C bond or opposite to a metal Ir—C bond.

7. The compound according to any one of claims 1-6, wherein the Z is O, S, NR, C(R)₂; and the R is independently selected from substituted or unsubstituted C1-C8 alkyl.

8. The compound according to claim 7, wherein the ligand X—Y is different from a left ligand.

9. The compound according to claim 8, wherein the X—Y is a 1,3-dione compound.

10. The compound according to claim 3, which is one of the following compounds:

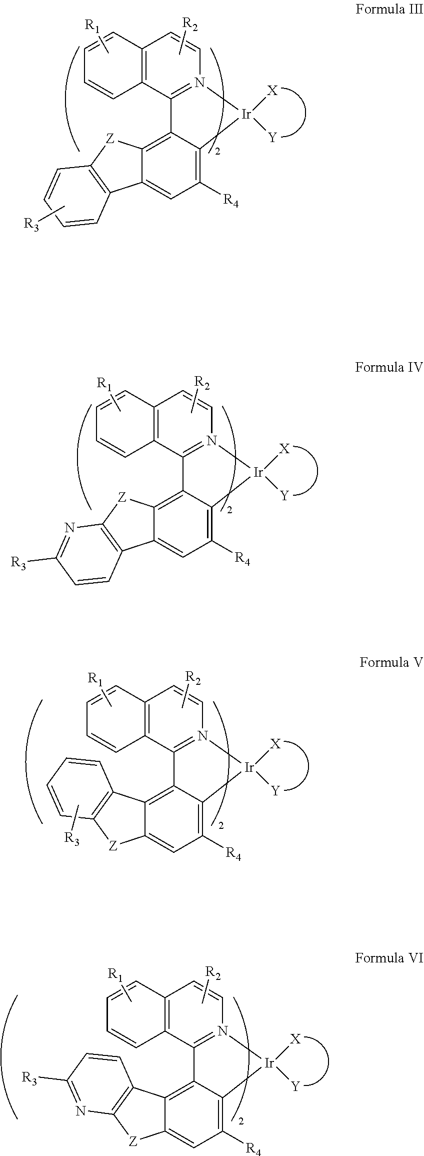

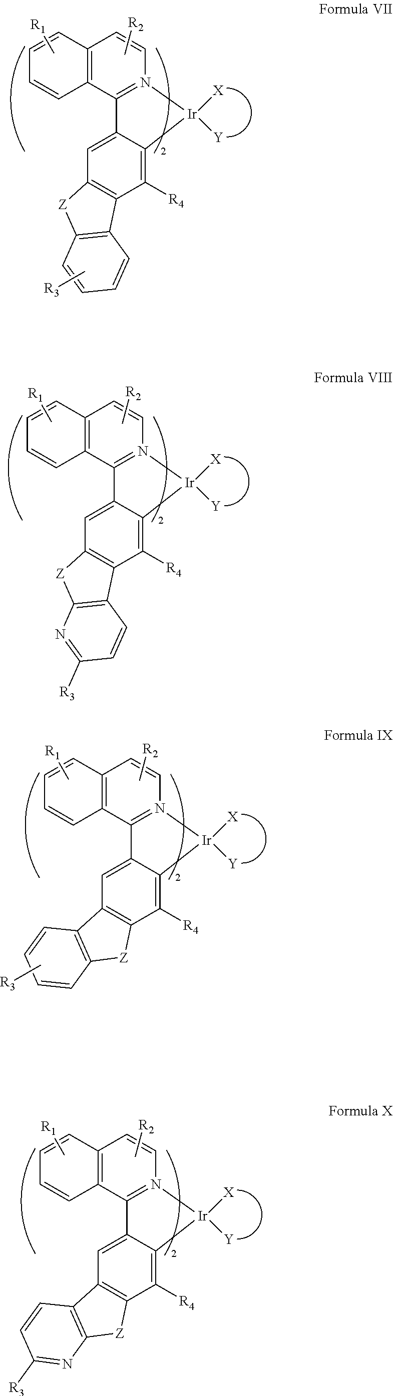

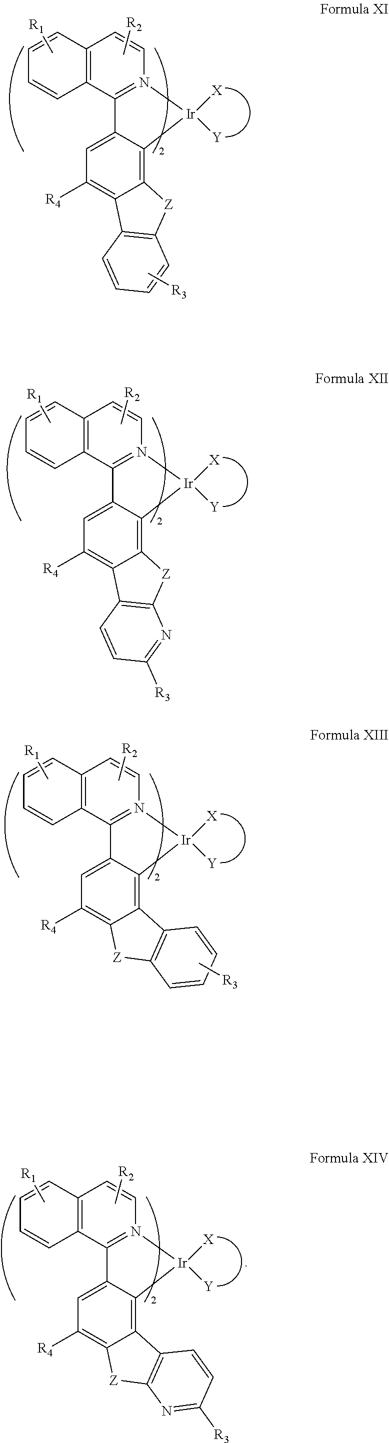

11. The compound according to claim 10, wherein Z is O, S, C(R)₂; R₁-R₄ are independently selected from H, deuterium, substituted or unsubstituted C1-C4 alkyl, substituted or unsubstituted C3-C20 cycloalkyl, substituted or unsubstituted C1-C8 aralkyl, C1-C4 alkyl substituted or unsubstituted C1-C8 aryl, or C1-C4 alkyl substituted or unsubstituted C1-C8 heteroaryl; and wherein at least one of R₁ and R₂ is substituted or unsubstituted C3-C20 cycloalkyl; wherein the substitution refers to a substitution by deuterium, F, Cl, Br, C1-C4 alkyl, C1-C4 alkoxy, C3-C6 cycloalkyl, amido substituted by C1-C4 alkyl, cyano, nitrile, isonitrile or phosphino; the substitution refers to a single substitution to a possible maximum substitutions.

12. The compound according to claim 11, wherein R₃_R₄ are independently selected from hydrogen, deuterium, substituted or unsubstituted C1-C4 alkyl, substituted or unsubstituted C3-C20 cycloalkyl, phenyl substituted C1-C4 alkyl, C1-C4 alkyl substituted phenyl; and wherein the substitution refers to a substitution by deuterium, F, Cl, Br, C1-C4 alkyl, C1-C4 alkoxy, C3-C6 cycloalkyl, amido substituted by C1-C4 alkyl, cyano, nitrile, isonitrile or phosphino.

13. The compound according to claim 3, having one of the following structural formulas,

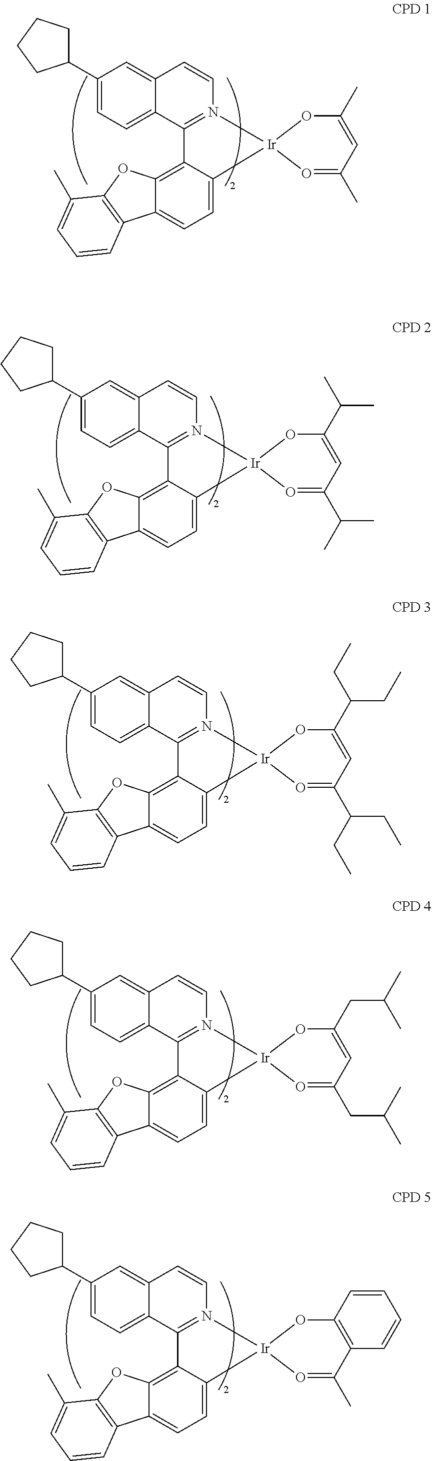

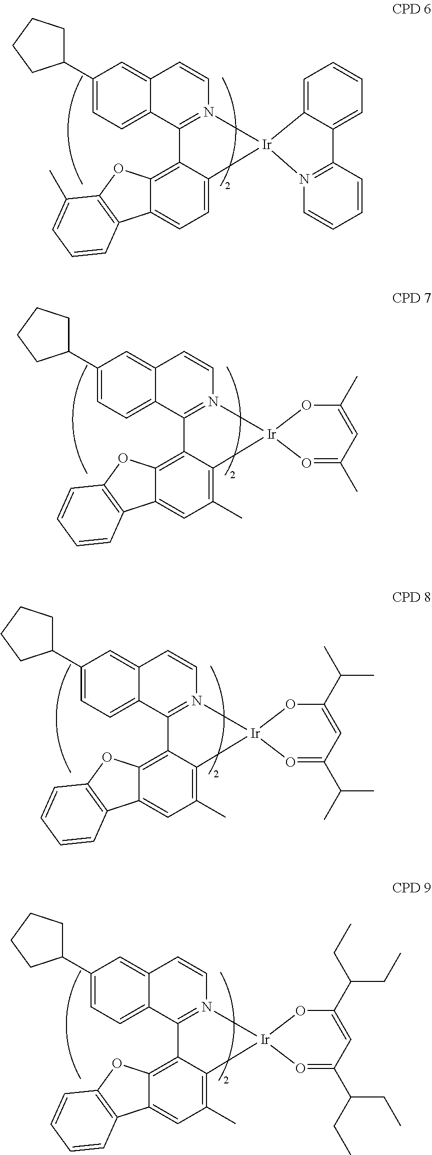

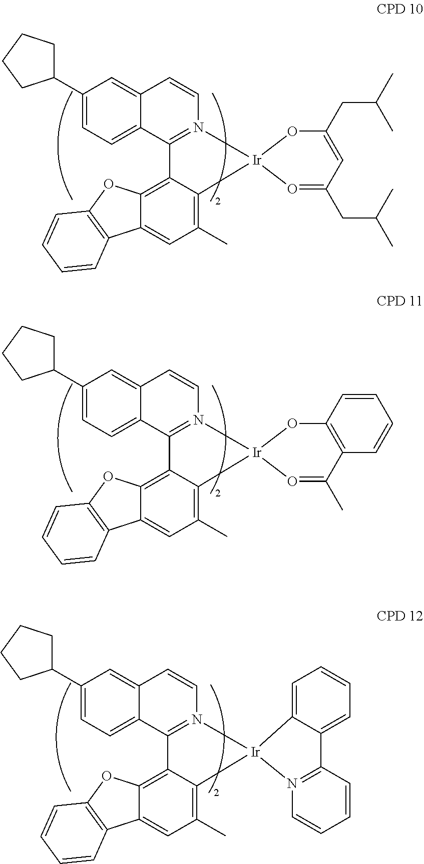

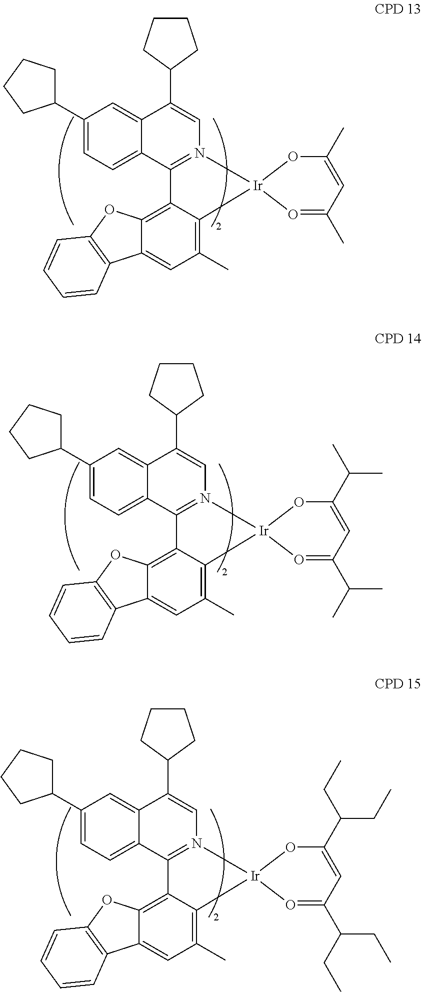

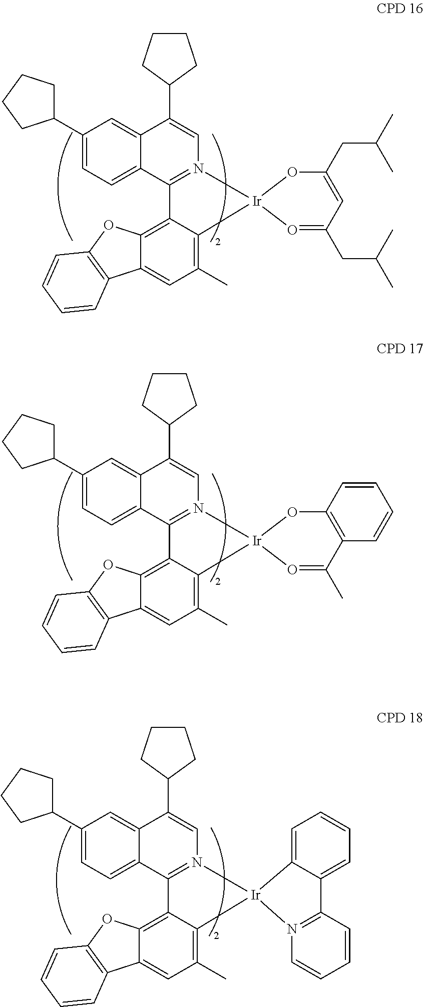

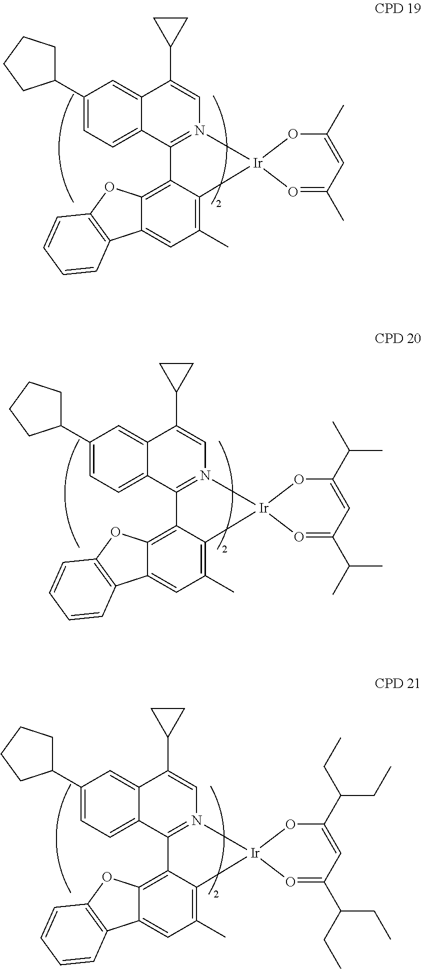

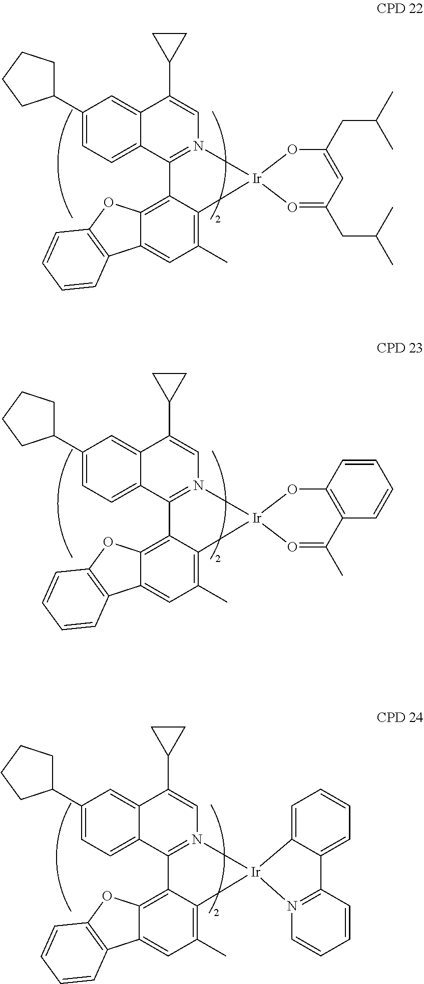

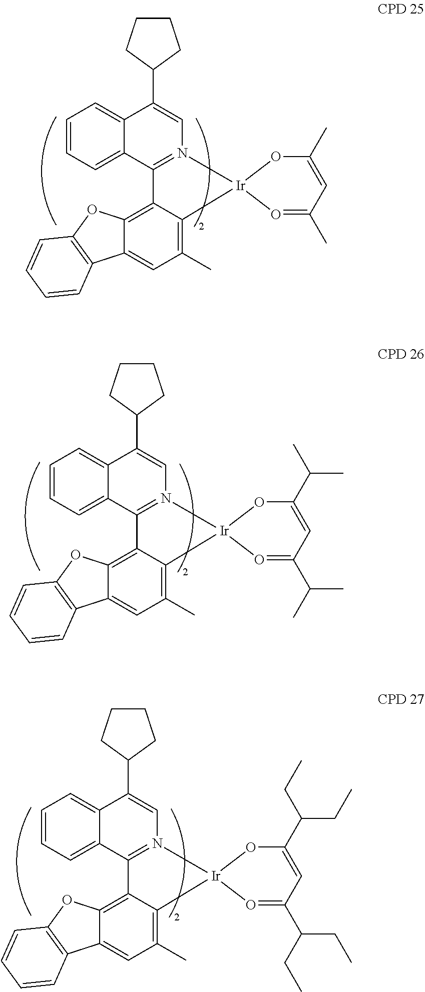

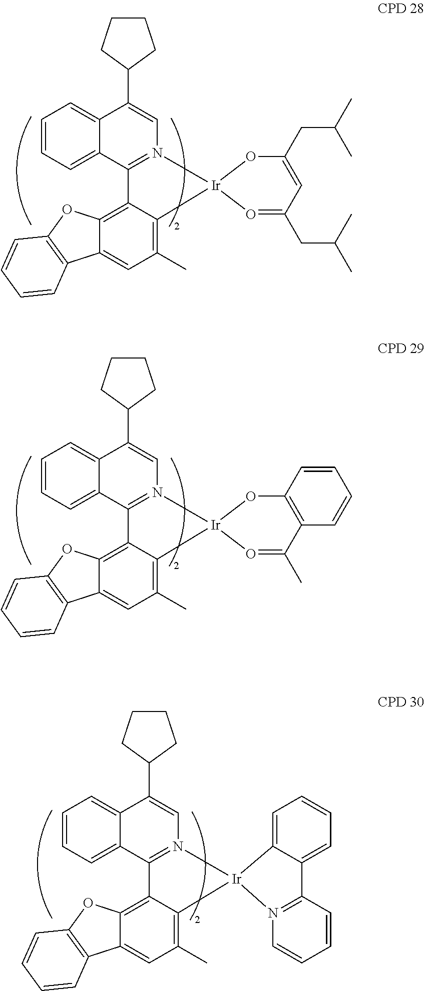

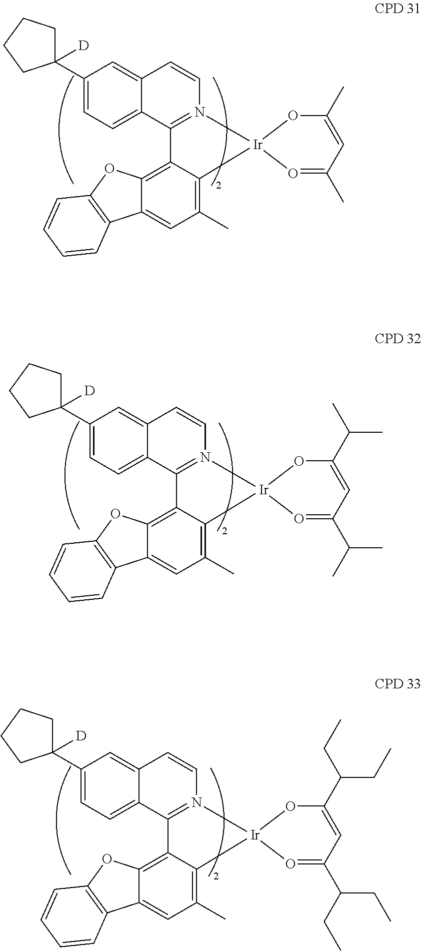

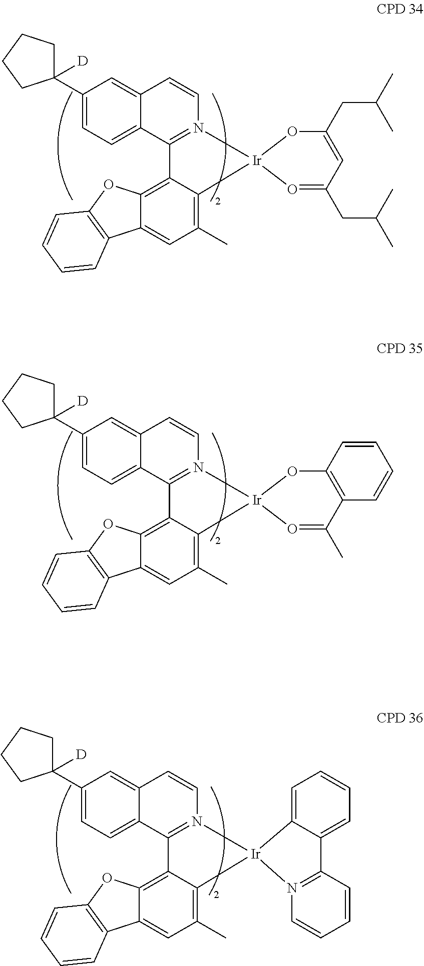

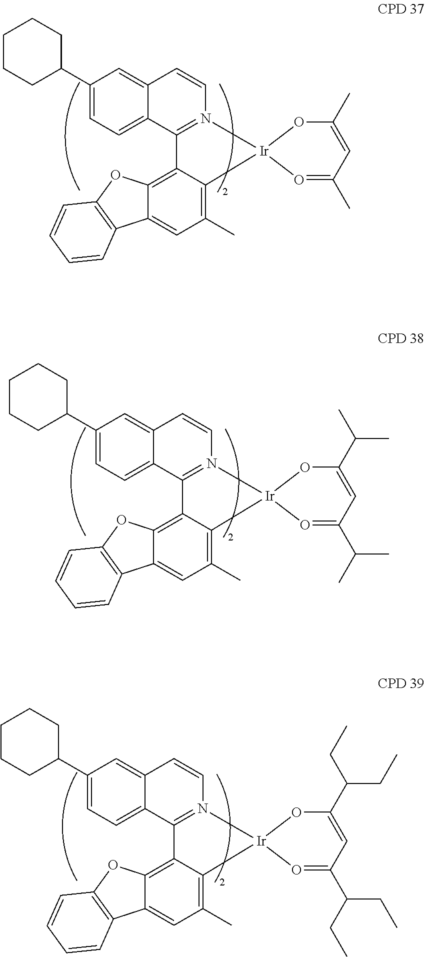

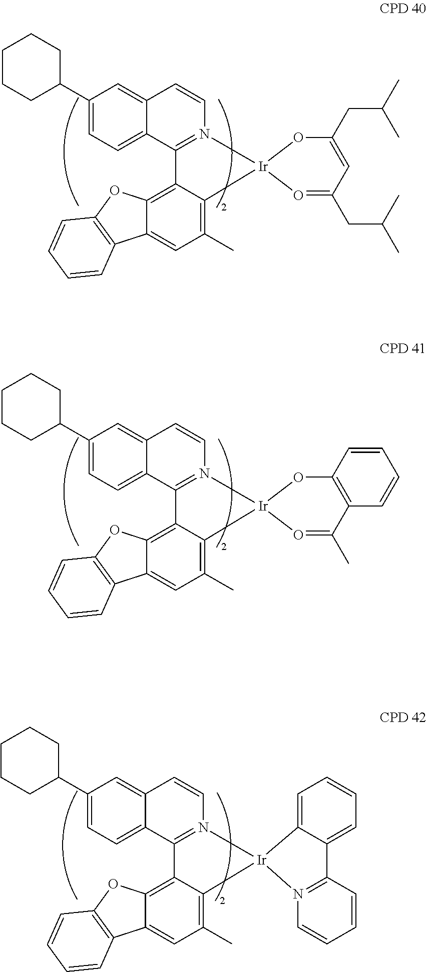

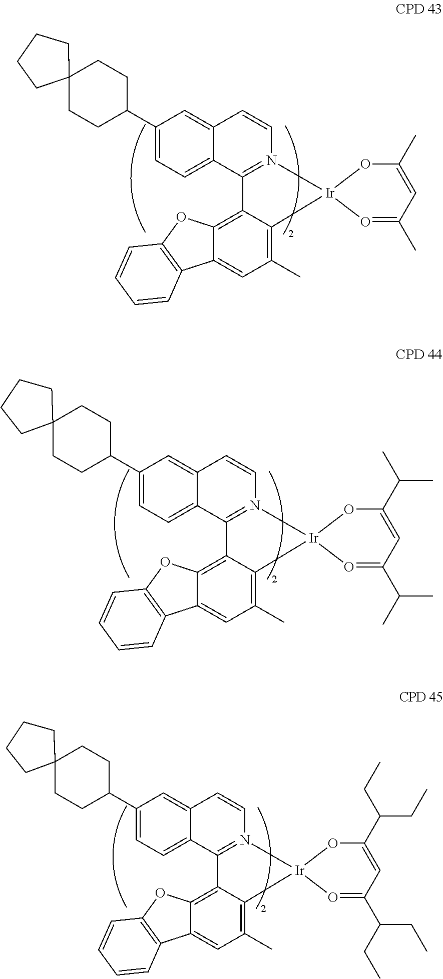

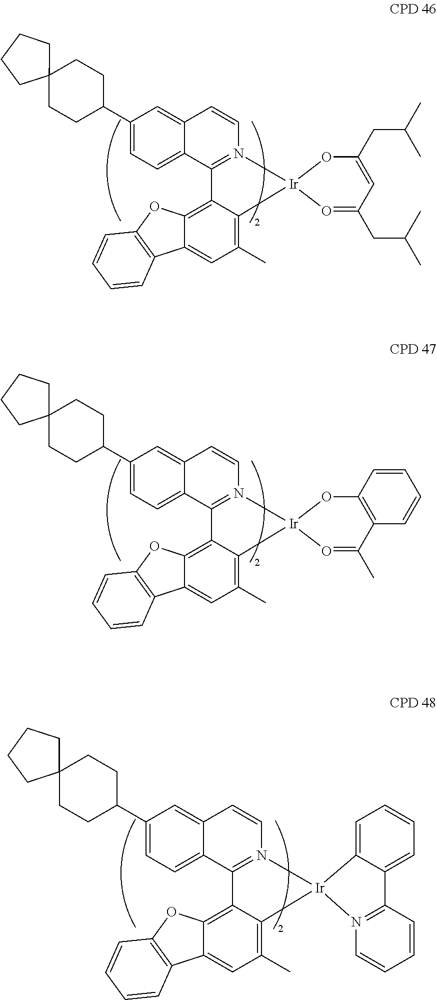

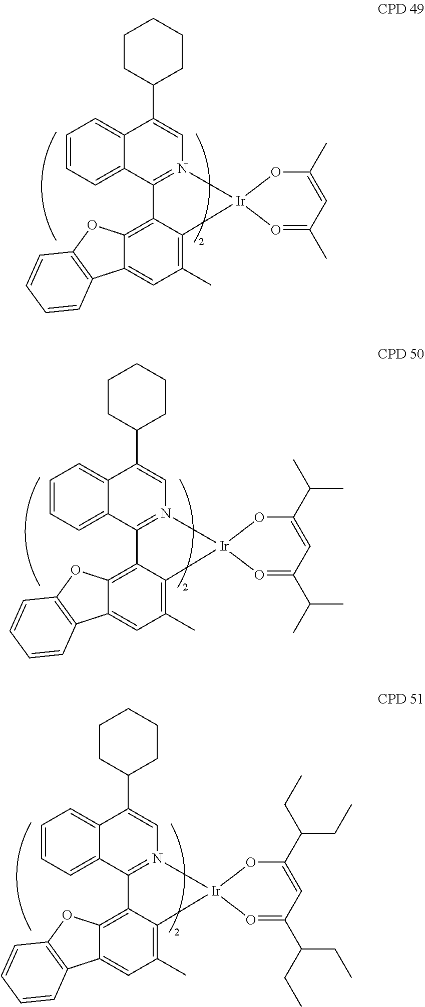

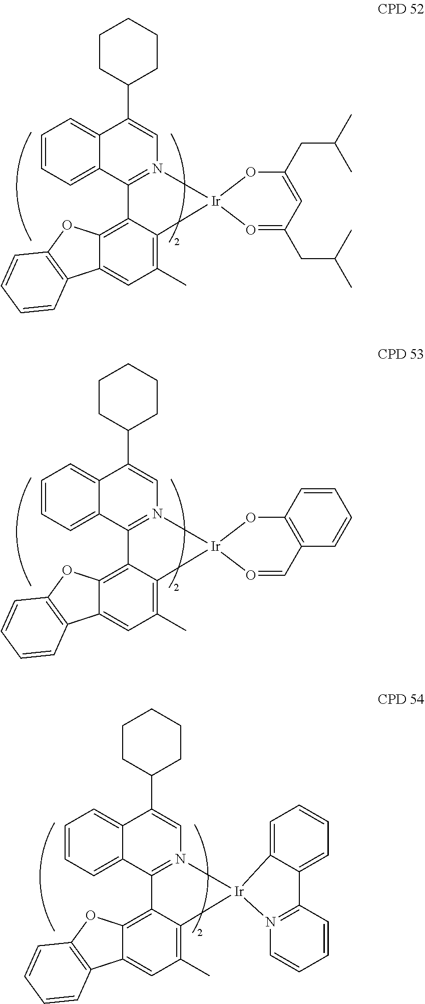

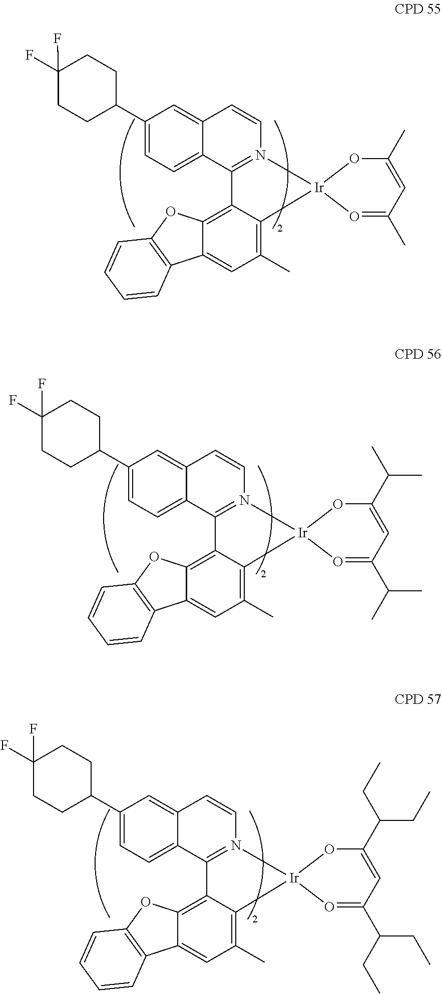

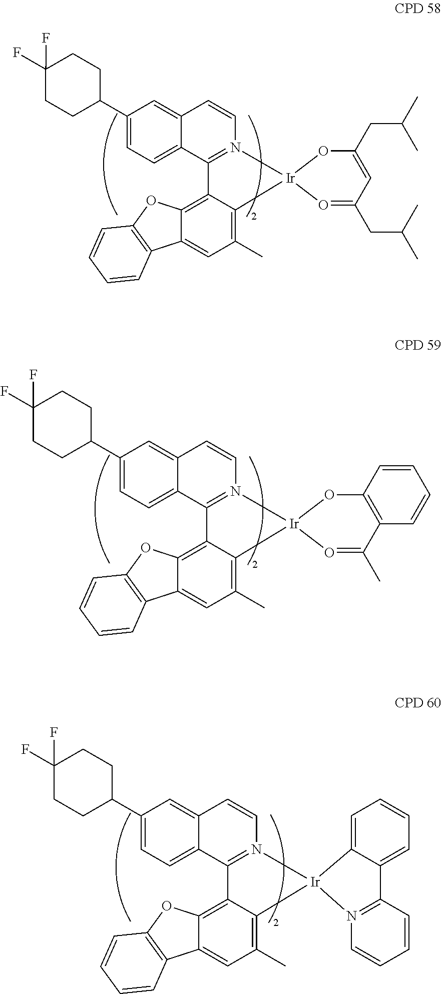

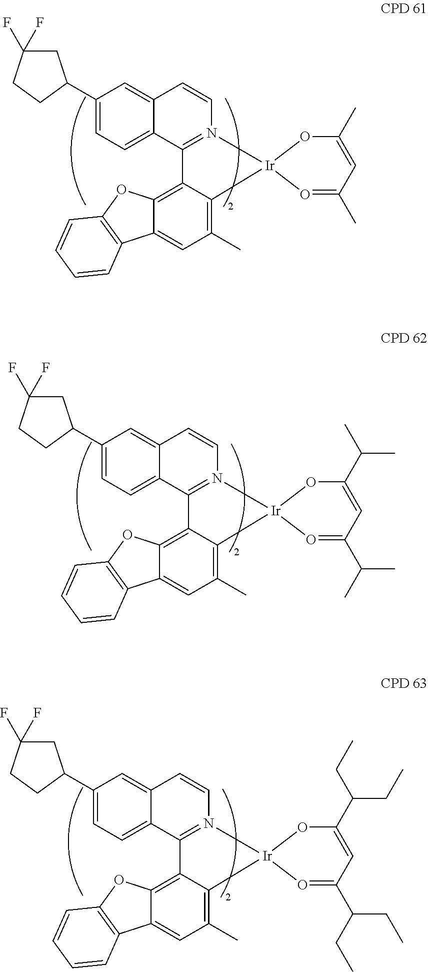

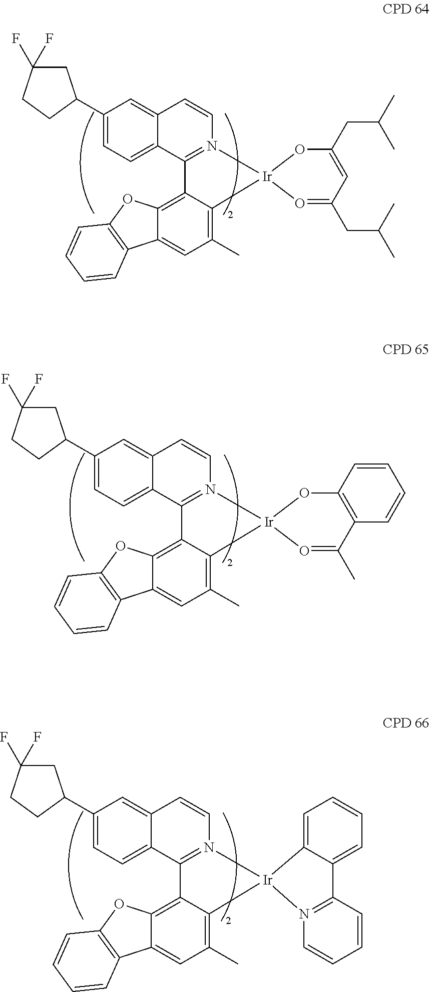

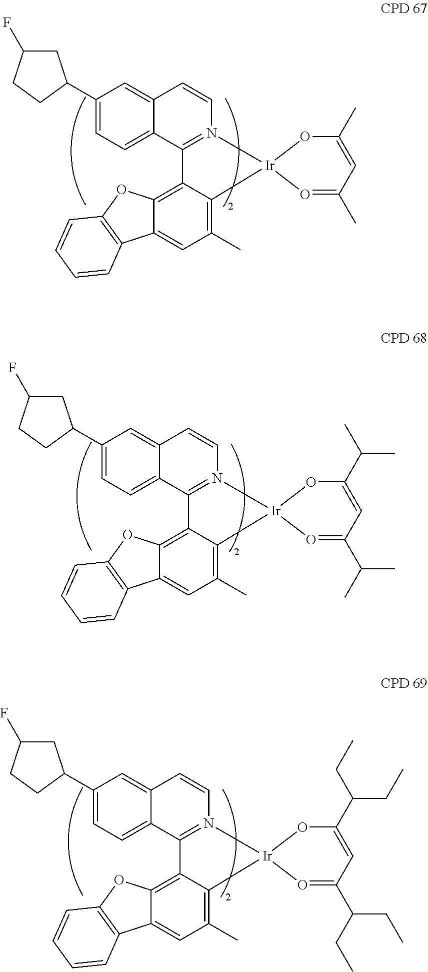

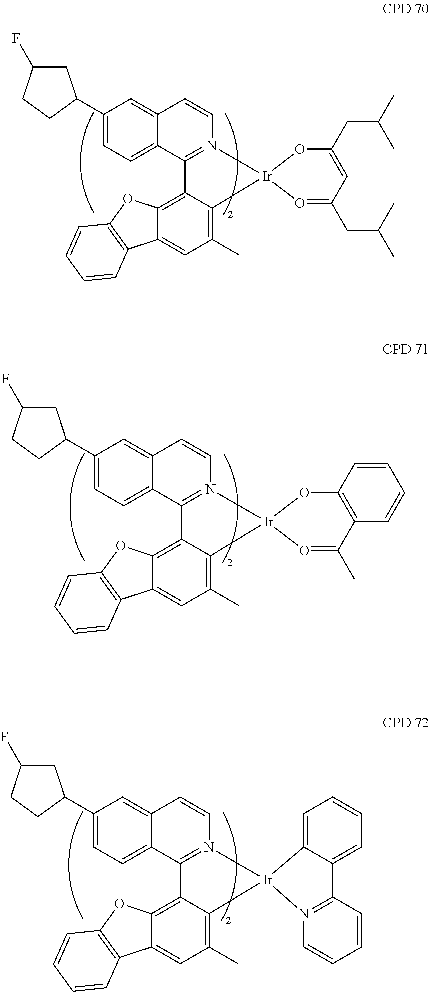

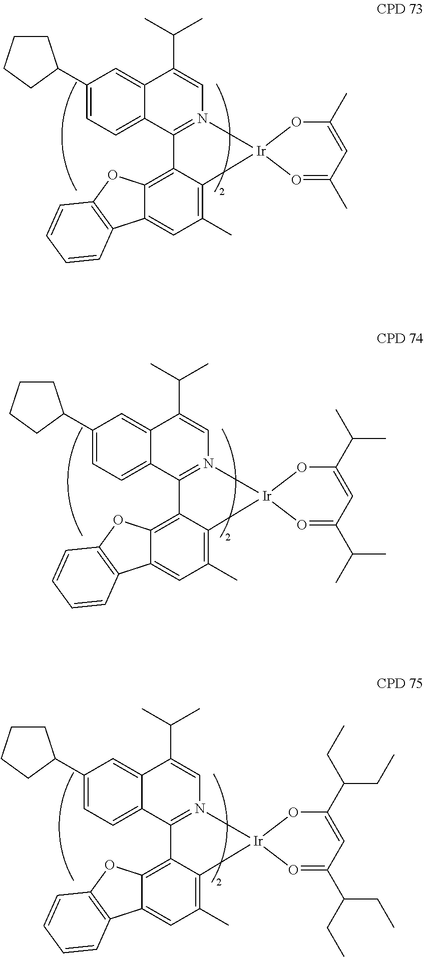

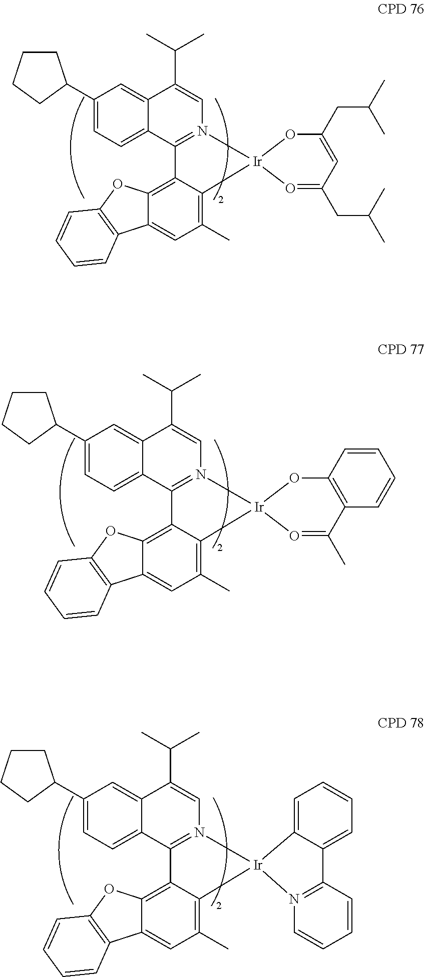

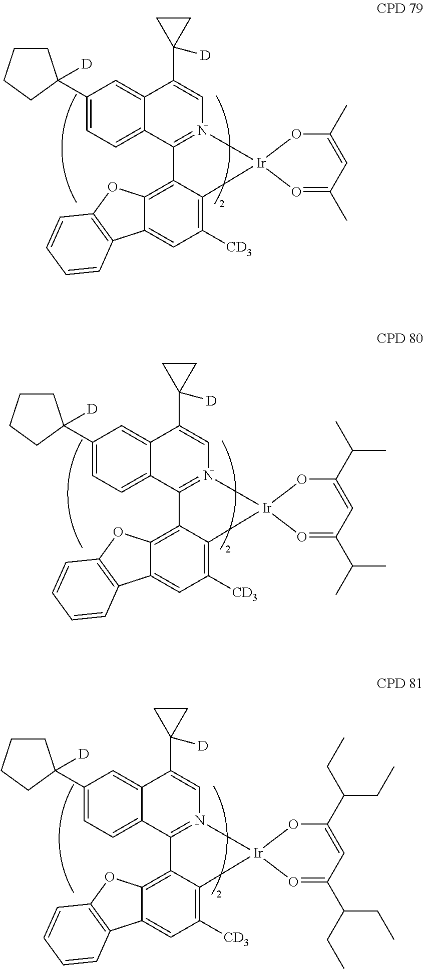

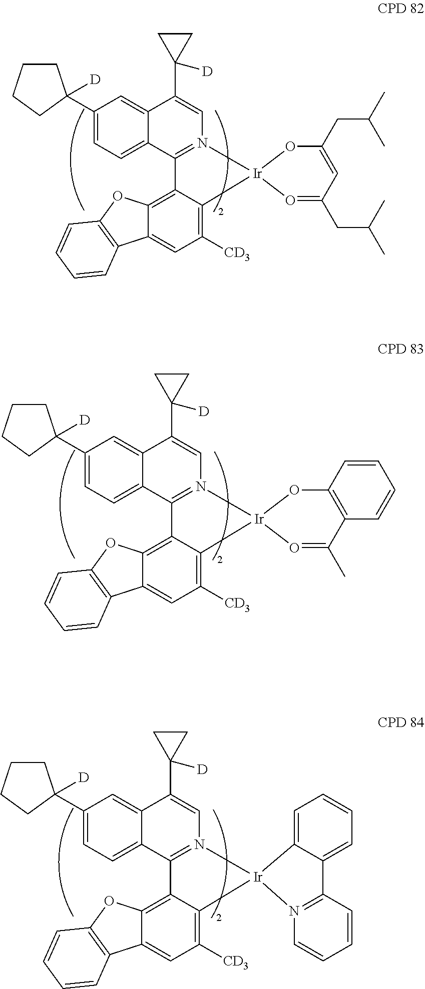

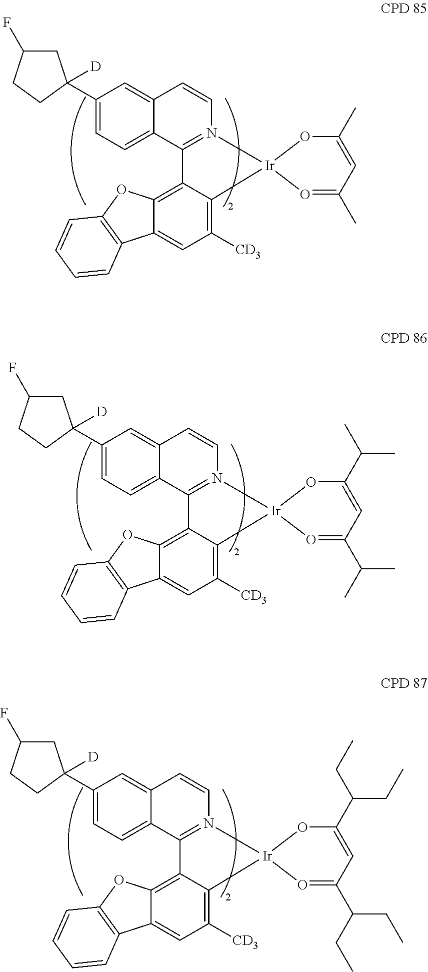

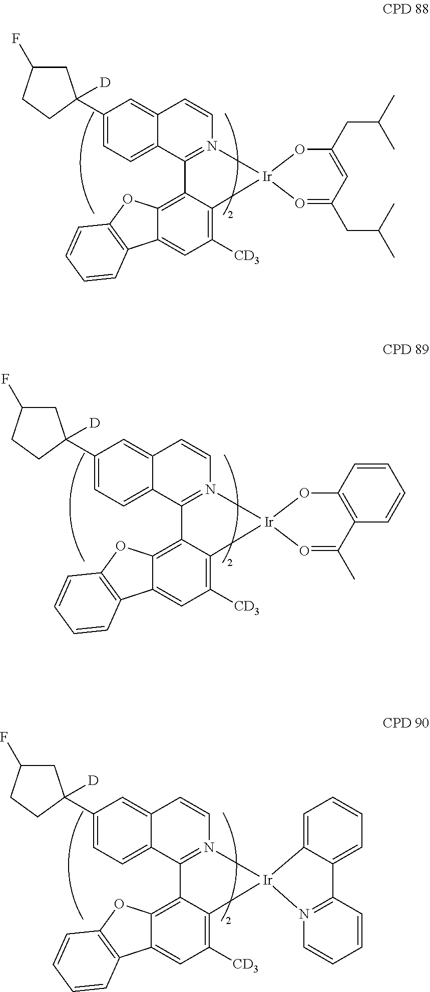

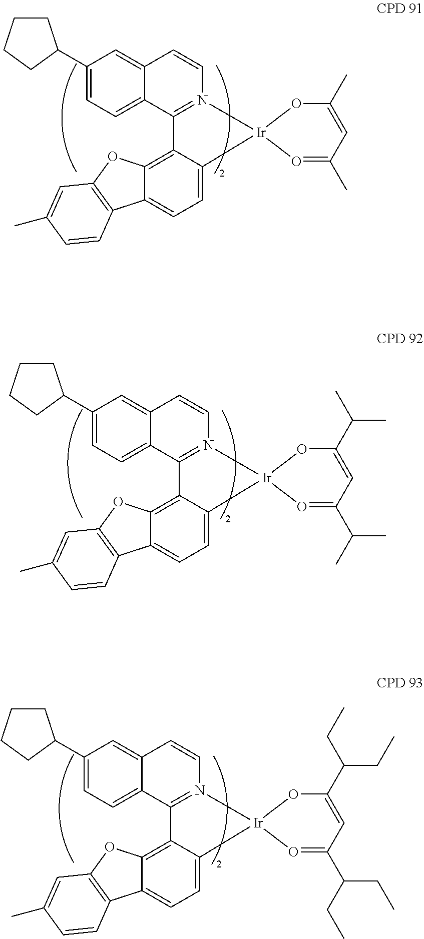

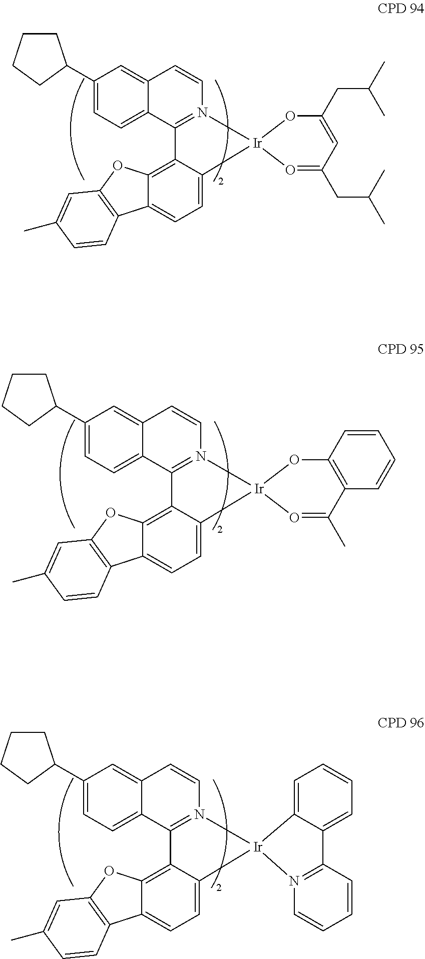

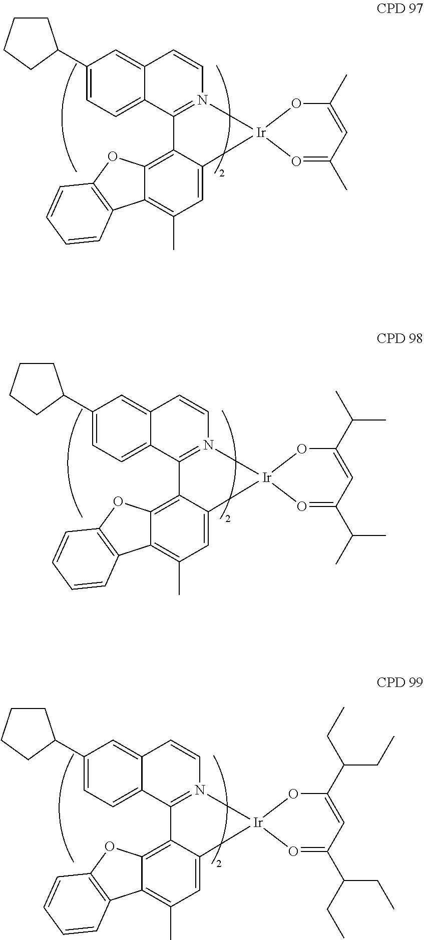

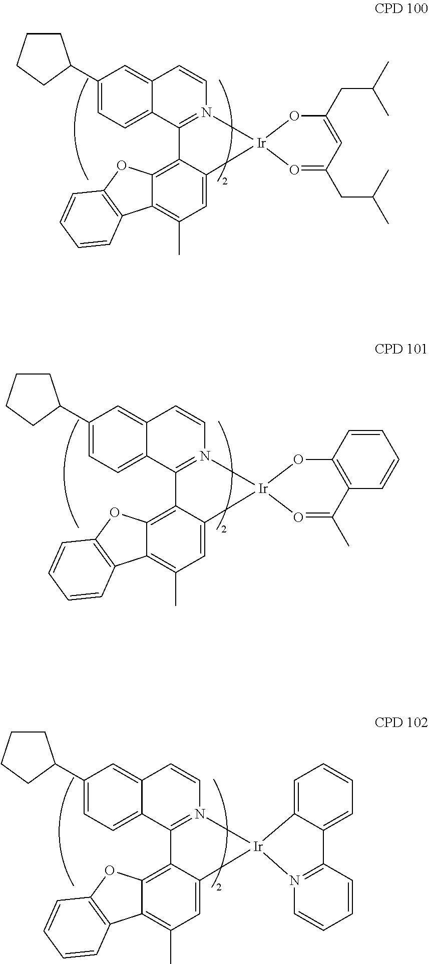

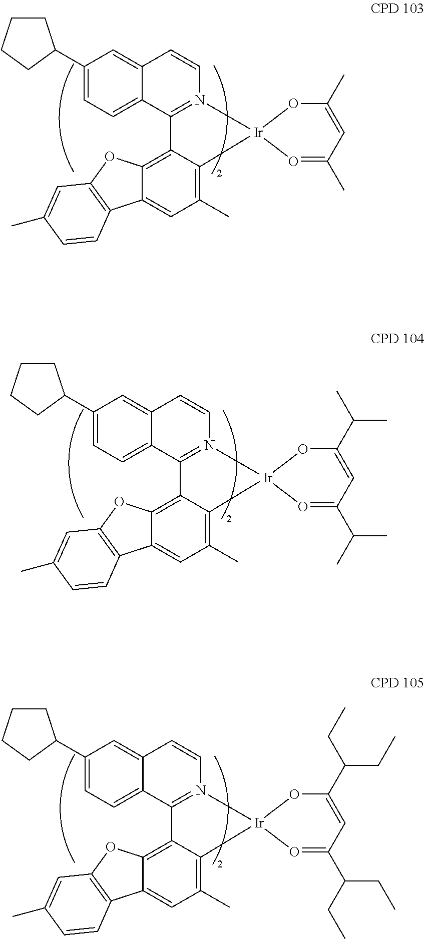

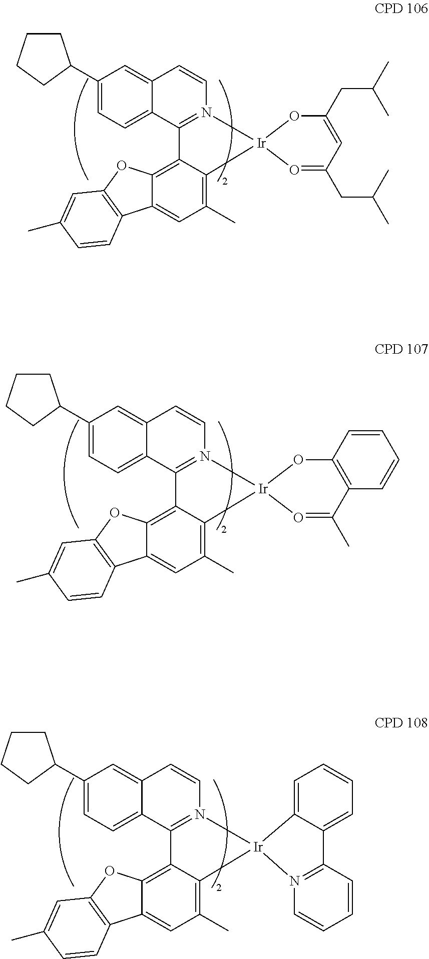

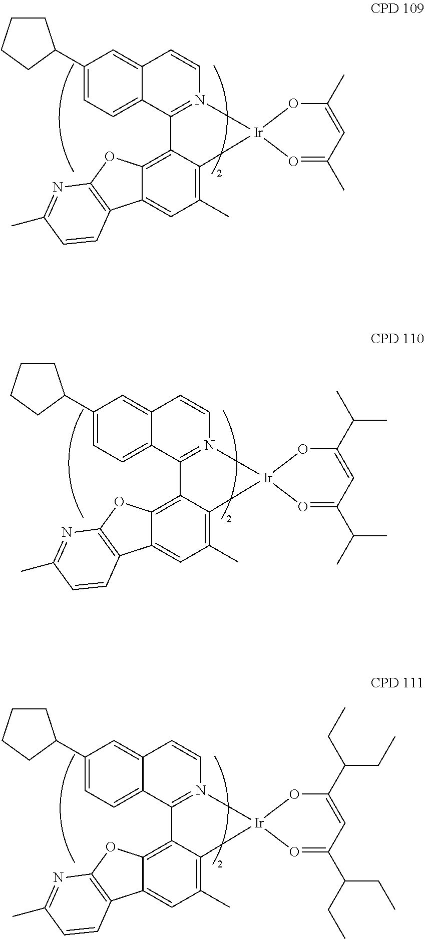

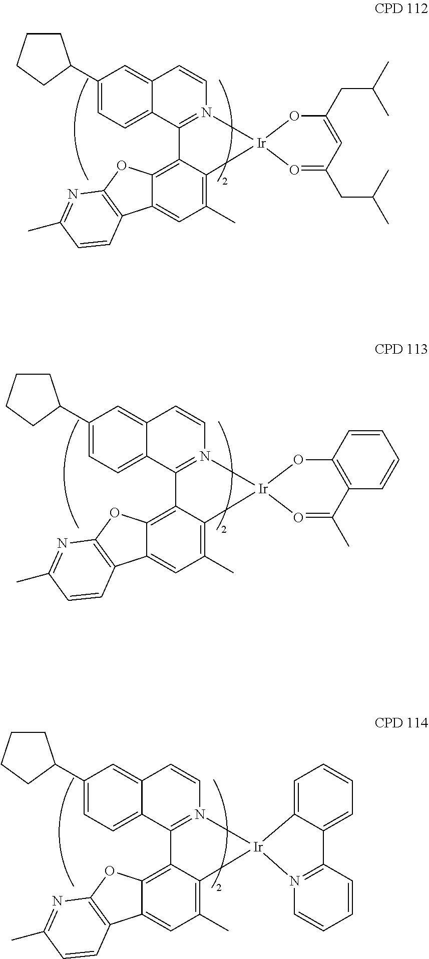

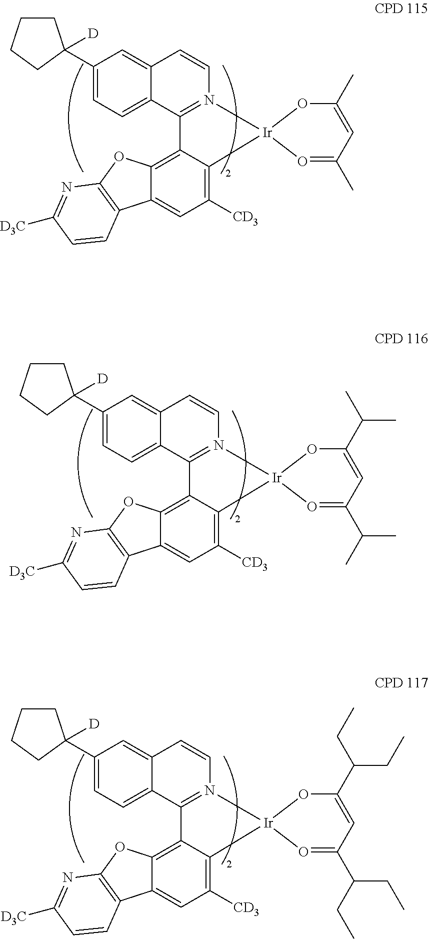

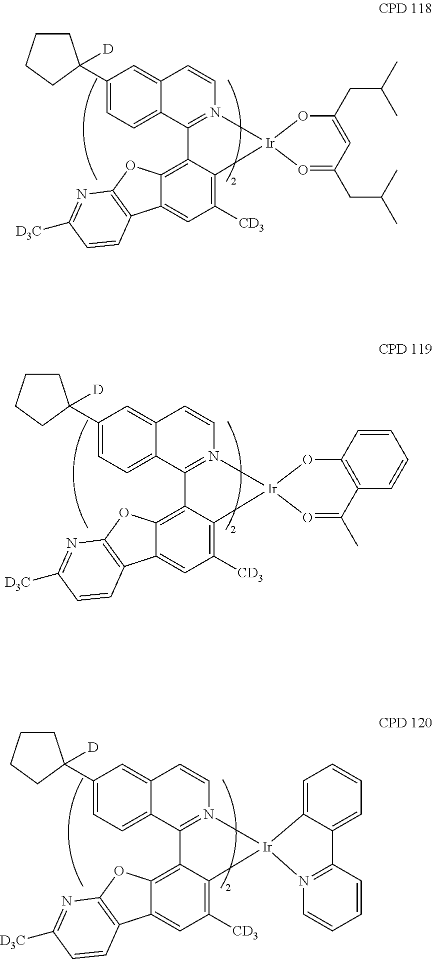

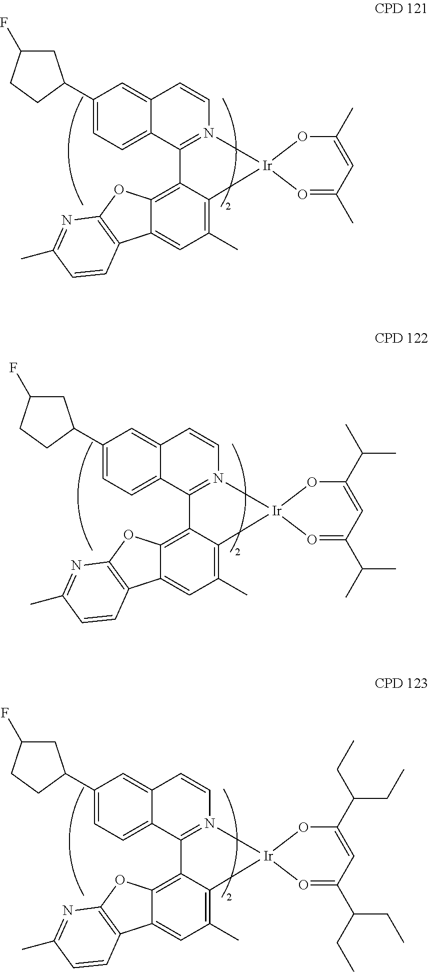

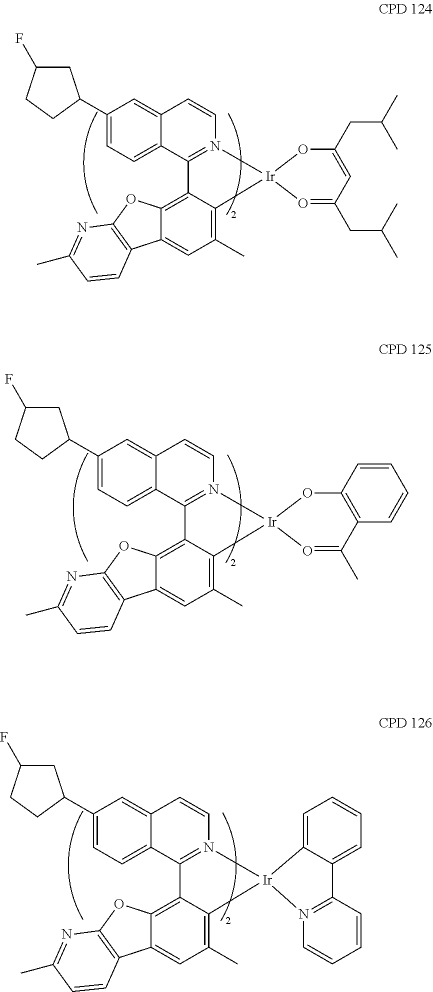

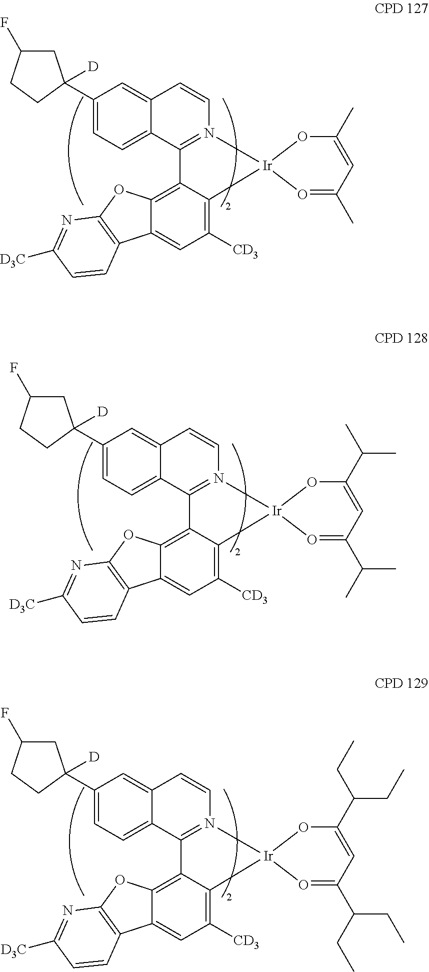

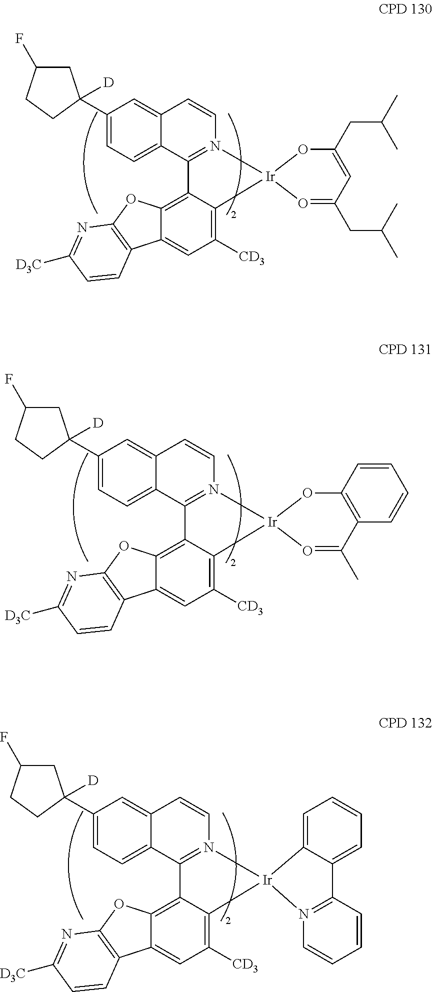

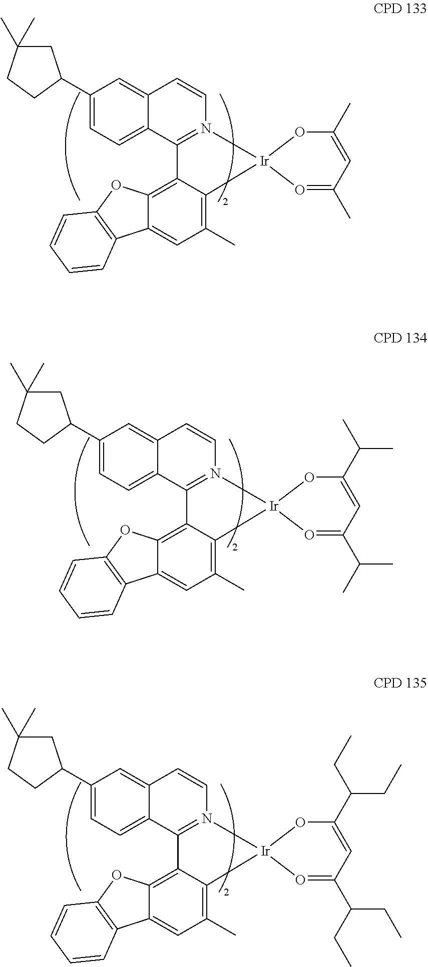

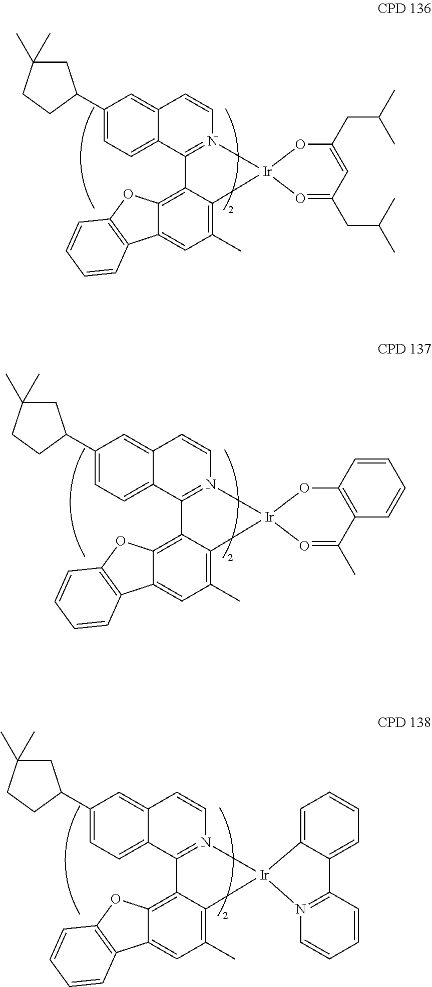

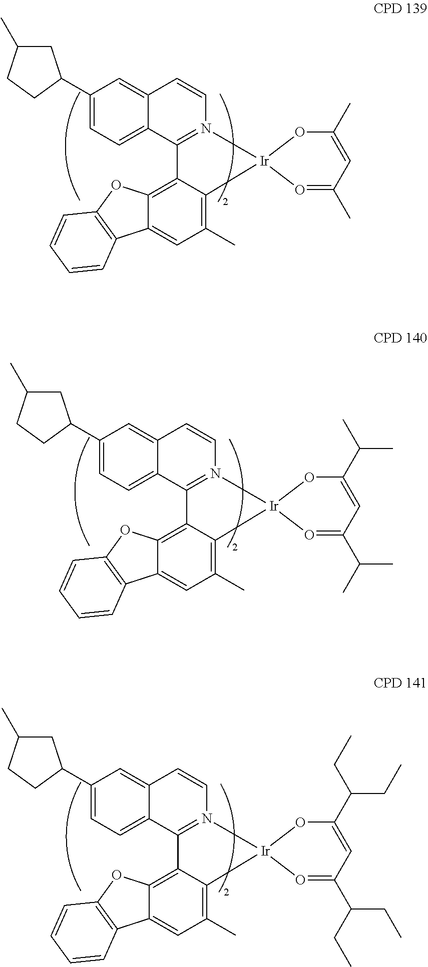

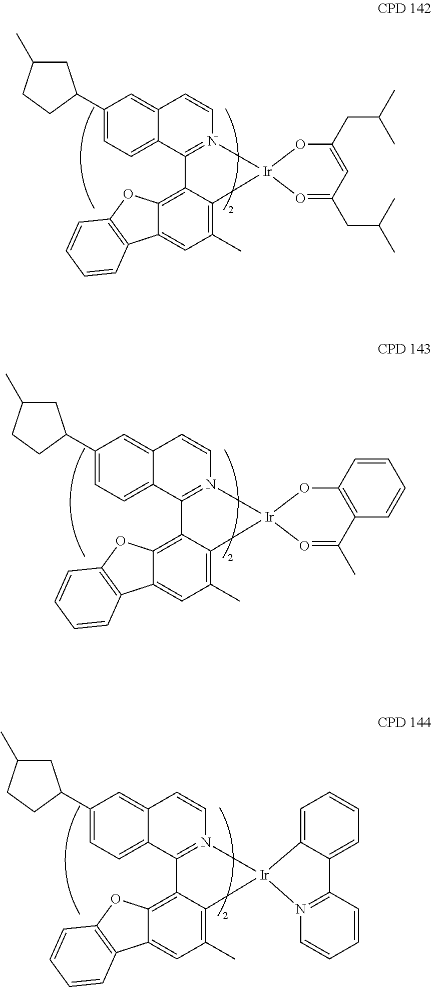

14. An application of the compound of any one of claims 1-13 in an organic light-emitting device.

15. The application according to claim 14, wherein the compound of any one of claims 1-13 serves as a doping material of a phosphorescent host material in a light-emitting layer.
